(19) United States
(12) Patent Application Publication
(10) Pub. No.: US 2025/0275306 A1
(43) Pub. Date: Aug. 28, 2025

(54) LIGHT EMITTING ELEMENT AND DISPLAY DEVICE INCLUDING THE SAME

(71) Applicant: Samsung Display Co., LTD., Yongin-si (KR)

(72) Inventors: Ji Wook MOON, Yongin-si (KR); Jong Moo HUH, Yongin-si (KR); Min Woo KIM, Yongin-si (KR); Dong Jun LEE, Yongin-si (KR); Ju Yon LEE, Yongin-si (KR)

(73) Assignee: Samsung Display Co., LTD., Yongin-si (KR)

(21) Appl. No.: 18/923,048

(22) Filed: Oct. 22, 2024

(30) Foreign Application Priority Data
Feb. 22, 2024 (KR) 10-2024-0025938

(51) Int. Cl. H01L 33/38; H01L 25/16

(52) U.S. Cl. CPC H10H 20/8314; H01L 25/167

(57) ABSTRACT

A light emitting element includes a light emitting stack including a first semiconductor layer, a second semiconductor layer disposed on the first semiconductor layer, and an active layer disposed between the first semiconductor layer and the second semiconductor layer, a first bonding electrode electrically connected to a lower surface of the first semiconductor layer and including a first protrusion protruding in at least one of a first direction and a direction opposite to the first direction so as to not overlap the light emitting stack in a plan view, a (2-1)-th bonding electrode electrically connected to the second semiconductor layer, and a (2-2)-th bonding electrode electrically connected to the second semiconductor layer and spaced apart from the (2-1)-th bonding electrode in a second direction intersecting the first direction, and the first bonding electrode may be disposed between the (2-1)-th bonding electrode and the (2-2)-th bonding electrode.

### CROSS-REFERENCE TO RELATED APPLICATIONS

This application claims priority under 35 U.S.C. 119 from Korean Patent Application No. 10-2024-0025938 filed on Feb. 22, 2024 in the Korean Intellectual Property Office, the entire contents of which are incorporated herein by reference.

### BACKGROUND

### 1. Technical Field

The disclosure relates to a light emitting element and a display device including the same.

### 2. Description of the Related Art

A display device includes multiple pixels, and each of the pixels may emit light. The display device may display an image by combining the light emitted from the pixels.

Much research is being conducted to improve light emission efficiency of each of the pixels included in the display device.

### SUMMARY

An object of the disclosure is to provide a display device including a pixel with improved light emission efficiency.

According to embodiments of the disclosure, a light emitting element may include a light emitting stack including a first semiconductor layer, a second semiconductor layer disposed on the first semiconductor layer, and an active layer disposed between the first semiconductor layer and the second semiconductor layer, a first bonding electrode electrically connected to a lower surface of the first semiconductor layer and including a first protrusion protruding in at least one of a first direction and a direction opposite to the first direction so as to not overlap the light emitting stack in a plan view, a (2-1)-th bonding electrode electrically connected to the second semiconductor layer, and a (2-2)-th bonding electrode electrically connected to the second semiconductor layer and spaced apart from the (2-1)-th bonding electrode in a second direction intersecting the first direction, and the first bonding electrode may be disposed between the (2-1)-th bonding electrode and the (2-2)-th bonding electrode.

In an embodiment, first and second exposed surfaces that do not overlap the first semiconductor layer and the active layer in a plan view may be defined on a face surface of the second semiconductor layer facing an outer peripheral surface of the active layer, the (2-1)-th bonding electrode may be electrically connected to the first exposed surface, and the (2-2)-th bonding electrode may be electrically connected to the second exposed surface.

In an embodiment, the first exposed surface may be adjacent to a side surface of the second semiconductor layer, and the second exposed surface may be adjacent to another side surface opposite to the side surface of the second semiconductor layer in the second direction.

In an embodiment, the (2-1)-th bonding electrode may include a (2-1)-th protrusion protruding in a direction opposite to the second direction so as to not overlap the light emitting stack in a plan view.

In an embodiment, the (2-2)-th bonding electrode may include a (2-2)-th protrusion protruding in the second direction so as not to overlap the light emitting stack in a plan view.

In an embodiment, the light emitting element may further include a reflective layer surrounding at least a portion of a side surface of the light emitting stack.

In an embodiment, the reflective layer may contact each of the (2-1)-th bonding electrode and the (2-2)-th bonding electrode.

In an embodiment, the reflective layer may include a conductive material.

In an embodiment, the reflective layer and the first bonding electrode may be spaced apart from each other.

In an embodiment, the light emitting element may further include an insulating layer surrounding at least a portion of an outer peripheral surface of the light emitting stack.

In an embodiment, the insulating layer may be disposed between the (2-1)-th bonding electrode and the first semiconductor layer, between the (2-1)-th bonding electrode and the active layer, between the (2-2)-th bonding electrode and the first semiconductor layer, and between the (2-2)-th bonding electrode and the active layer.

In an embodiment, the first bonding electrode may include a (1-1)-th bonding electrode and a (1-2)-th bonding electrode spaced apart from the (1-1)-th bonding electrode in the second direction.

According to embodiments of the disclosure, a light emitting element may include alight emitting stack including a first semiconductor layer, a second semiconductor layer disposed on the first semiconductor layer, and an active layer disposed between the first semiconductor layer and the second semiconductor layer, a (1-1)-th bonding electrode electrically connected to a lower surface of the first semiconductor layer, a (1-2)-th bonding electrode electrically connected to the lower surface of the first semiconductor layer and spaced apart from the (1-1)-th bonding electrode in a first direction, and a second bonding electrode electrically connected to the second semiconductor layer and including a protrusion protruding in at least one of a second direction intersecting the first direction and a direction opposite to the second direction so as to not overlap the light emitting stack in a plan view, the second bonding electrode may be disposed between the (1-1)-th bonding electrode and the (1-2)-th bonding electrode.

In an embodiment, the (1-1)-th bonding electrode may be adjacent to a side surface of the first semiconductor layer, and the (1-2)-th bonding electrode may be adjacent to another side surface opposite to the side surface of the first semiconductor layer in the first direction.

In an embodiment, the (1-1)-th bonding electrode may include a (1-1)-th protrusion protruding in a direction opposite to the first direction so as not to overlap the light emitting stack in a plan view.

In an embodiment, the (1-2)-th bonding electrode may include a (1-2)-th protrusion protruding in the first direction so as not to overlap the light emitting stack in a plan view.

In an embodiment, the second bonding electrode may include a (2-1)-th bonding electrode and a (2-2)-th bonding electrode spaced apart from the (2-1)-th bonding electrode in the first direction.

In an embodiment, first and second exposed surfaces that do not overlap the first semiconductor layer and the active layer in a plan view may be defined on a face surface of the second semiconductor layer facing an outer peripheral surface of the active layer, the (2-1)-th bonding electrode may be electrically connected to the first exposed surface, and the (2-2)-th bonding electrode may be electrically connected to the second exposed surface.

In an embodiment, the light emitting element may further include a reflective layer surrounding at least a portion of a side surface of the light emitting stack.

In an embodiment, the light emitting element may further include an insulating layer surrounding at least a portion of an outer peripheral surface of the light emitting stack.

According to embodiments of the disclosure, a display device may include an electrode layer including an anode electrode including a first contact portion, and a cathode electrode including a (2-1)-th contact portion and a (2-2)-th contact portion, a pixel circuit layer disposed under the electrode layer and including a sub-pixel circuit electrically connected to the anode electrode, and a light emitting element disposed on the electrode layer. The light emitting element may include a light emitting stack including a first semiconductor layer, a second semiconductor layer disposed on the first semiconductor layer, and an active layer disposed between the first semiconductor layer and the second semiconductor layer, a first bonding electrode disposed on the first contact portion and electrically connected to a lower surface of the first semiconductor layer, the first bonding electrode may include a first protrusion protruding in at least one of a first direction and a direction opposite to the first direction so as to not overlap the light emitting stack in a plan view, a (2-1)-th bonding electrode electrically connected to the second semiconductor layer and disposed on the (2-1)-th contact portion, and a (2-2)-th bonding electrode electrically connected to the second semiconductor layer, spaced apart from the (2-1)-th bonding electrode in a second direction intersecting the first direction, and disposed on the (2-2)-th contact portion, the first bonding electrode may be disposed between the (2-1)-th bonding electrode and the (2-2)-th bonding electrode.

In an embodiment, the first bonding electrode may be electrically connected to the first contact portion through a first bridge electrode electrically connected to each of the first protrusion and the first contact portion.

In an embodiment, the (2-1)-th bonding electrode may include a (2-1)-th protrusion protruding in a direction opposite to the second direction so as to not overlap the light emitting stack in a plan view, and the (2-1)-th bonding electrode may be electrically connected to the (2-1)-th contact portion through a (2-1)-th bridge electrode electrically connected to each of the (2-1)-th protrusion and the (2-1)-th contact portion.

In an embodiment, the (2-2)-th bonding electrode may include a (2-2)-th protrusion protruding in the second direction so as to not overlap the light emitting stack in a plan view, and the (2-2)-th bonding electrode may be electrically connected to the (2-2)-th contact portion through a (2-2)-th bridge electrode electrically connected to each of the (2-2)-th protrusion and the (2-2)-th contact portion.

In an embodiment, the first bonding electrode may overlap a portion of the first contact portion in a plan view, the (2-1)-th bonding electrode may overlap a portion of the (2-1)-th contact portion in a plan view, and the (2-2)-th bonding electrode may overlap a portion of the (2-2)-th contact portion in a plan view.

In a light emitting element according to embodiments of the disclosure, a distance between bonding electrodes electrically connected to different semiconductor layers may be relatively small. Accordingly, a current distribution in the light emitting element may become more uniform, and light emission efficiency of the light emitting element may be improved.

A display device according to embodiments of the disclosure may include the light emitting element. Accordingly, display quality of the display device may be improved.

### BRIEF DESCRIPTION OF THE DRAWINGS

The above and other features of the disclosure will become more apparent by describing in further detail embodiments thereof with reference to the accompanying drawings, in which:

FIG. 1 is a schematic block diagram illustrating a display device according to embodiments of the disclosure;

FIG. 2 is a schematic block diagram illustrating one sub-pixel among sub-pixels included in the display device of FIG. 1;

FIG. 3 is a plan view illustrating a display panel configuring the display device of FIG. 1;

FIG. 4 is a schematic cross-sectional view illustrating an embodiment of the display panel of FIG. 3;

FIG. 5 is a schematic cross-sectional view illustrating an embodiment of the display panel of FIG. 3;

FIGS. 6 to 8 are schematic diagrams illustrating a light emitting element according to a first embodiment of the disclosure;

FIGS. 9 to 11 are schematic diagrams illustrating a sub-pixel including the light emitting element according to the first embodiment of the disclosure;

FIGS. 12 to 14 are schematic diagrams illustrating a light emitting element according to a second embodiment of the disclosure;

FIGS. 15 to 17 are schematic diagrams illustrating a sub-pixel including the light emitting element according to the second embodiment of the disclosure;

FIGS. 18 to 20 are schematic diagrams illustrating a light emitting element according to a third embodiment of the disclosure;

FIGS. 21 to 23 are schematic diagrams illustrating a sub-pixel including the light emitting element according to the third embodiment of the disclosure;

FIGS. 24 to 26 are diagrams illustrating a light emitting element according to a fourth embodiment of the disclosure;

FIGS. 27 to 29 are schematic diagrams illustrating a sub-pixel including the light emitting element according to the fourth embodiment of the disclosure;

FIGS. 30 to 33 are schematic diagrams illustrating a light emitting element according to a fifth embodiment of the disclosure;

FIGS. 34 to 37 are schematic diagrams illustrating a sub-pixel including the light emitting element according to the fifth embodiment of the disclosure;

FIG. 38 is a schematic block diagram illustrating a display system according to an embodiment; and

FIGS. 39 to 42 are perspective views illustrating application examples of the display system of FIG. 38.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the inventive concepts. Further, the blocks, parts, and/or modules of some embodiments may be physically combined into more complex blocks, parts, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

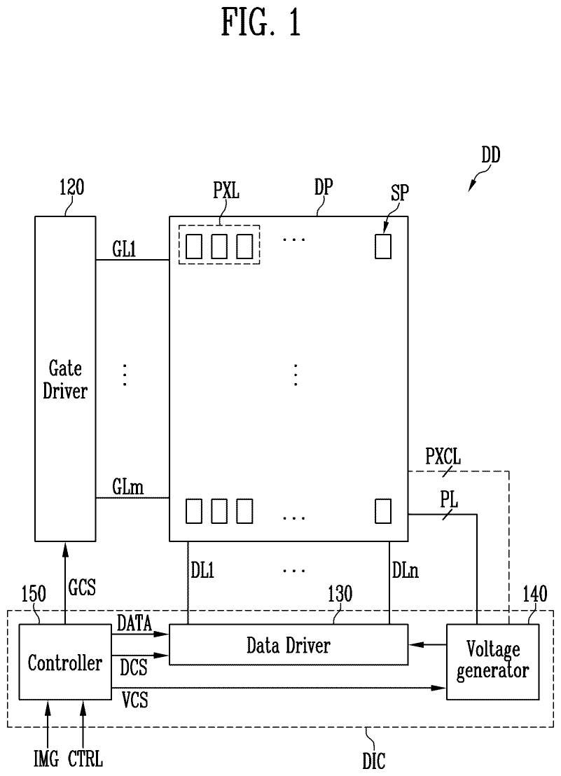

FIG. 1 is a schematic block diagram illustrating a display device according to embodiments of the disclosure.

Referring to FIG. 1, the display device DD may include a display panel DP, a gate driver 120, a data driver 130, a voltage generator 140, and a controller 150.

The display panel DP includes sub-pixels SP. The sub-pixels SP may be electrically connected to the gate driver 120 through first to m-th gate lines GL1 to GLm. The sub-pixels SP may be electrically connected to the data driver 130 through first to n-th data lines DL1 to DLn.

The sub-pixels SP may generate of light of two or more colors. For example, each of the sub-pixels SP may generate light such as red, green, blue, cyan, magenta, or yellow.

Two or more sub-pixels among the sub-pixels SP may configure one pixel PXL. For example, the pixel PXL may include three sub-pixels as shown in FIG. 1. The pixel PXL may emit light of various colors and various luminances according to a combination of light emitted from the sub-pixels included in the pixel PXL.

The gate driver 120 may be electrically connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal, and the like.

The gate driver 120 may be disposed on a side of the display panel DP. However, embodiments are not limited thereto. For example, the gate driver 120 may be divided into two or more physically and/or logically divided drivers, and such drivers may be disposed on a side of the display panel DP and another side of the display panel DP opposite the side. As described above, the gate driver 120 may be disposed around the display panel DP in various shapes according to embodiments.

The data driver 130 may be electrically connected to the sub-pixels SP arranged in a column direction through the first to n-th data lines DL1 to DLn. The data driver 130 receives image data DATA and a data control signal DCS from the controller 150. The data driver 130 may operate in response to the data control signal DCS. In embodiments, the data control signal DCS may include a source start signal, a source shift clock, a source output enable signal, and the like.

The data driver 130 may receive voltages from the voltage generator 140. The data driver 130 may apply data signals having grayscale voltages corresponding to the image data DATA to the first to n-th data lines DL1 to DLn using the received voltages. In case that the gate signal is applied to each of the first to m-th gate lines GL1 to GLm, the data signals corresponding to the image data DATA may be applied to the data lines DL1 to DLn. Accordingly, the sub-pixels SP may generate light corresponding to the data signals, and the display panel DP may display an image.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate multiple voltages and provide the generated voltages to components of the display device DD, such as the gate driver 120, the data driver 130, and the controller 150. The voltage generator 140 may generate the voltages by receiving an input voltage from an outside of the display device DD and regulating the received voltage.

The voltage generator 140 may generate a first power voltage and a second power voltage. The generated first and second power voltages may be provided to the sub-pixels SP through power lines PL. In an embodiment, at least one of the first and second power voltages may be provided from the outside of the display device DD.

The voltage generator 140 may provide various voltages and/or signals. For example, the voltage generator 140 may provide at least one initialization voltage applied to the sub-pixels SP. For example, during a sensing operation for sensing electrical characteristics of transistors and/or light emitting elements of the sub-pixels SP, a reference voltage may be applied to the first to n-th data lines DL1 to DLn, and the voltage generator 140 may generate the reference voltage and transmit the reference voltage to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide the pixel control signals to the sub-pixels SP through pixel control lines PXCL. In FIG. 1, the pixel control lines PXCL may be electrically connected between the voltage generator 140 and the display panel DP, but embodiments are not limited thereto. For example, the pixel control lines PXCL may be electrically connected between the gate driver 120 and the display panel DP. The pixel control signals may be transmitted from the voltage generator 140 to the pixel control lines PXCL through the gate driver 120.

The controller 150 controls overall operations of the display device DD. The controller 150 receives input image data IMG and a control signal CTRL corresponding thereto from the outside. The controller 150 may provide the gate control signal GCS, the data control signal DCS, and the voltage control signal VCS in response to the control signal CTRL.

The controller 150 may convert the input image data IMG so that the input image data IMG may be suitable for the display device DD or the display panel DP and output the image data DATA. In embodiments, the controller 150 may output the image data DATA by aligning the input image data IMG so that the input image data IMG may be suitable for the sub-pixels SP of a row portion.

Two or more components of the data driver 130, the voltage generator 140, and the controller 150 may be mounted on an integrated circuit. As shown in FIG. 1, the data driver 130, the voltage generator 140, and the controller 150 may be included in a driver integrated circuit DIC. The data driver 130, the voltage generator 140, and the controller 150 may be functionally divided components in a driver integrated circuit DIC. In other embodiments, at least one of the data driver 130, the voltage generator 140, and the controller 150 may be provided as a component distinguished from the driver integrated circuit DIC.

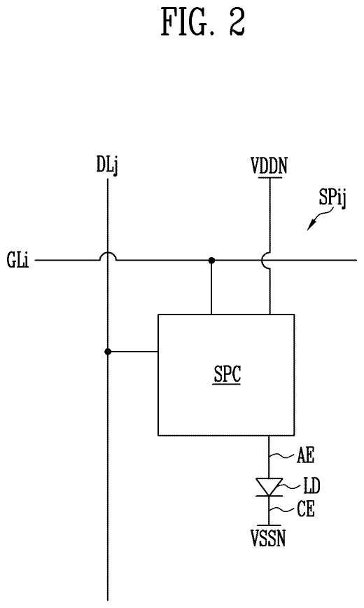

FIG. 2 is a schematic block diagram illustrating one sub-pixel among the sub-pixels included in the display device of FIG. 1. In FIG. 2, among the sub-pixels SP of FIG. 1, a sub-pixel SPij arranged in an i-th row (i may be an integer greater than or equal to 1 and less than or equal to m) and a j-th column (j may be an integer greater than or equal to 1 and less than or equal to n) is shown as an example.

Referring to FIG. 2, the sub-pixel SPij may include a sub-pixel circuit SPC and a light emitting element LD.

The light emitting element LD may be electrically connected between a first power voltage node VDDN and a second power voltage node VSSN. The first power voltage node VDDN may be electrically connected to one of the power lines PL of FIG. 1 and may receive the first power voltage. The second power voltage node VSSN may be electrically connected to another one of the power lines PL of FIG. 1 and may receive the second power voltage. The first power voltage may have a voltage level higher than that of the second power voltage.

The light emitting element LD may be electrically connected between an anode electrode AE and a cathode electrode CE. The anode electrode AE may be electrically connected to the first power voltage node VDDN through the sub-pixel circuit SPC. For example, the anode electrode AE may be electrically connected to the first power voltage node VDDN through at least one transistor included in the sub-pixel circuit SPC. The cathode electrode CE may be electrically connected to the second power voltage node VSSN. The light emitting element LD may be configured to emit light according to a current flowing from the anode electrode AE to the cathode electrode CE.

The sub-pixel circuit SPC may be electrically connected to an i-th gate line GLi among the first to m-th gate lines GL1 to GLm of FIG. 1, and a j-th data line DLj among the first to n-th data lines DL1 to DLn of FIG. 1. In response to a gate signal received through the i-th gate line GLi, the sub-pixel circuit SPC may control the light emitting element LD to emit light according to a data signal received through the j-th data line DLj. In embodiments, the sub-pixel circuit SPC may be further electrically connected to the pixel control lines PXCL of FIG. 1. The sub-pixel circuit SPC may control the light emitting element LD in further response to the pixel control signals received through the pixel control lines PXCL.

For such operations, the sub-pixel circuit SPC may include circuit elements, for example, transistors and at least one capacitor.

The transistors of the sub-pixel circuit SPC may include P-type transistors and/or N-type transistors. In embodiments, the transistors of the sub-pixel circuit SPC may include a metal oxide semiconductor field effect transistor (MOSFET). In embodiments, the transistors of the sub-pixel circuit SPC may include an amorphous silicon semiconductor, a monocrystalline silicon semiconductor, a polycrystalline silicon semiconductor, an oxide semiconductor, and the like.

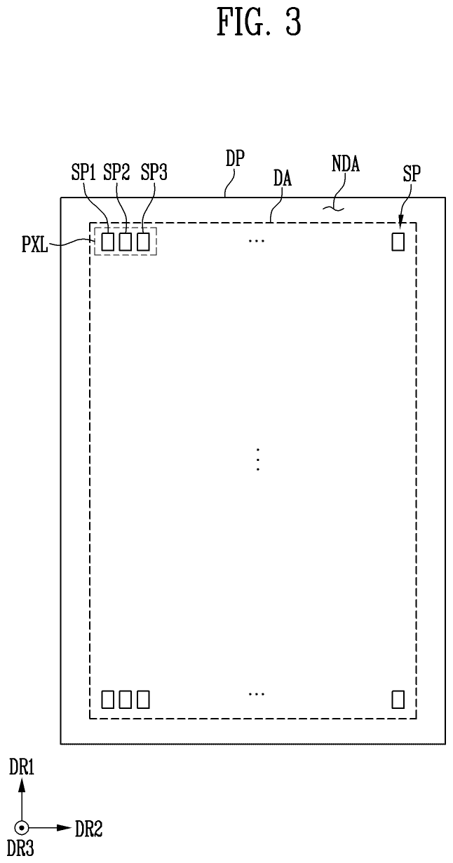

FIG. 3 is a plan view illustrating the display panel configuring the display device of FIG. 1.

Referring to FIG. 3, the display panel DP may include a display area DA and a non-display area NDA. The display panel DP displays an image through the display area DA. The non-display area NDA may be disposed around the display area DA.

The display panel DP includes the sub-pixels SP disposed in the display area DA. The sub-pixels SP may be arranged in a first direction DR1 and a second direction DR2 intersecting the first direction DR1. For example, the sub-pixels SP may be arranged in a matrix form in the first direction DR1 and the second direction DR2. As an example, the sub-pixels SP may be arranged in a zigzag form in the first direction DR1 and the second direction DR2. An arrangement of the sub-pixels SP may vary according to embodiments. The first direction DR1 may be a column direction, and the second direction DR2 may be a row direction.

Two or more sub-pixels among the sub-pixels SP may configure one pixel PXL. In FIG. 3, the pixel PXL includes three sub-pixels SP1, SP2, and SP3, but embodiments are not limited thereto. For example, the pixel PXL may include two sub-pixels. Hereinafter, for convenience of description, it may be assumed that the pixel PXL includes the first to third sub-pixels SP1, SP2, and SP3.

Each of the first to third sub-pixels SP1, SP2, and SP3 may generate light of one of various colors such as red, green, blue, cyan, magenta, and yellow. Hereinafter, for clear and concise description, it may be assumed that the first sub-pixel SP1 may be configured to generate light of a red color, the second sub-pixel SP2 may be configured to generate light of a green color, and the third sub-pixel SP3 may be configured to generate light of a blue color.

Each of the first to third sub-pixels SP1, SP2, and SP3 may include at least one light emitting element configured to generate light. In embodiments, the light emitting elements of the first to third sub-pixels SP1, SP2, and SP3 may generate light of the same color. For example, the light emitting elements of the first to third sub-pixels SP1, SP2, and SP3 may generate the light of the blue color. In other embodiments, the light emitting elements of the first to third sub-pixels SP1, SP2, and SP3 may generate light of different colors. For example, the light emitting elements of the first to third sub-pixels SP1, SP2, and SP3 may generate light of a red color, a green color, and a blue color, respectively.

As the display panel DP, a light emitting diode display panel (LED display panel) using a micro scale or nano scale of light emitting diode as a light emitting element, and a display panel capable of self-emission such as an organic light emitting display panel (OLED panel) using an organic light emitting diode as a light emitting element may be used.

A component for controlling the sub-pixels SP may be disposed in the non-display area NDA. Lines electrically connected to the sub-pixels SP, for example, the first to m-th gate lines GL1 to GLm of FIG. 1, the first to n-th data lines DL1 to DLn, the power lines PL, and the pixel control lines PXCL may be disposed in the non-display area NDA.

At least one of the gate driver 120, the data driver 130, the voltage generator 140, and the controller 150 of FIG. 1 may be disposed in the non-display area NDA of the display panel DP. In embodiments, the gate driver 120 may be disposed in the non-display area NDA. The data driver 130, the voltage generator 140, and the controller 150 may be implemented as a driver integrated circuit DIC of FIG. 1, separate from the display panel DP, and the driver integrated circuit DIC may be electrically connected to the lines disposed in the non-display area NDA. In other embodiments, the gate driver 120 may be implemented as an integrated circuit separate from the display panel DP, together with the data driver 130, the voltage generator 140, and the controller 150.

In embodiments, the display area DA may have various shapes. The display area DA may have a closed loop shape including sides of a straight line and/or a curved line. For example, the display area DA may have shapes of a polygon, a circle, a semicircle, an ellipse, and the like.

In embodiments, the display panel DP may have an approximately flat display surface. In other embodiments, the display panel DP may have a display surface that may be at least partially round. In embodiments, the display panel DP may be bendable, foldable, or rollable. In such cases, the display panel DP and/or a substrate of the display panel DP may include materials having a flexible property.

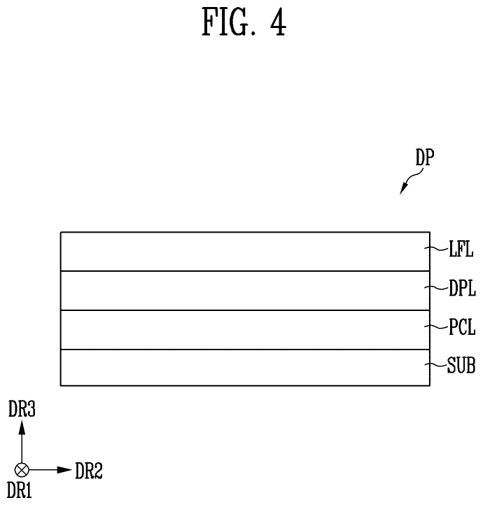

FIG. 4 is a schematic cross-sectional view illustrating an embodiment of the display panel of FIG. 3.

Referring to FIG. 4, the display panel DP may include a substrate SUB, and a pixel circuit layer PCL, a display element layer DPL, and a light functional layer LFL sequentially stacked on each other on the substrate SUB in a third direction DR3 intersecting the first and second directions DR1 and DR2.

The substrate SUB may be formed of an insulating material such as glass or resin. For example, the substrate SUB may include a glass substrate. As an example, the substrate SUB may include a polyimide (PI) substrate. As still an example, the substrate SUB may include a silicon wafer substrate formed using a semiconductor process.

In embodiments, the substrate SUB may be formed of a flexible material that may be bent or folded, and may have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers, semiconductor patterns, and conductive patterns disposed between the insulating layers. The conductive patterns of the pixel circuit layer PCL may function as circuit elements, lines, and the like.

The circuit elements of the pixel circuit layer PCL may include the sub-pixel circuit SPC of FIG. 2 of each of the sub-pixels SP of FIG. 3. In other words, the circuit elements of the pixel circuit layer PCL may be provided as transistors and at least one capacitor of the sub-pixel circuit SPC.

The lines of the pixel circuit layer PCL may include lines electrically connected to the sub-pixels SP. The lines of the pixel circuit layer PCL may include various signal lines and/or voltage lines desirable to drive the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include light functional patterns having color conversion particles and/or scattering particles. For example, the color conversion particles may include quantum dots. The quantum dots may change a wavelength (or color) of light emitted from the display element layer DPL. The light functional layer LFL may further include light scattering patterns having the scattering particles. In embodiments, the light functional patterns and the light scattering patterns may be omitted.

The light functional layer LFL may further include a color filter layer including color filters. The color filter may selectively transmit light of a specific wavelength (or a specific color). In embodiments, the color filter layer may be omitted.

A window for protecting an exposure surface (or an upper surface) of the display panel DP may be provided on the light functional layer LFL. The window may protect the display panel DP from external shock. The window may be coupled to the light functional layer LFL through an optically transparent adhesive (or cohesive) member. The window may have a multi-layer structure selected from a glass substrate, a plastic film, and a plastic substrate. The multi-layer structure may be formed through a continuous process or an adhesion process using an adhesive layer. All or a portion of the window may be flexible.

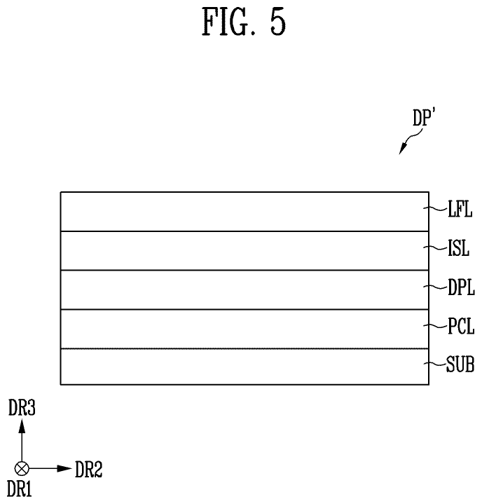

FIG. 5 is a schematic cross-sectional view illustrating an embodiment of the display panel of FIG. 3.

Referring to FIG. 5, the display panel DP′ may include the substrate SUB, the pixel circuit layer PCL, the display element layer DPL, an input sensing layer ISL, and the light functional layer LFL. The substrate SUB, the pixel circuit layer PCL, the display element layer DPL, and the light functional layer LFL may be configured equally (or similarly) to the substrate SUB, the pixel circuit layer PCL, the display element layer DPL, and the light functional layer LFL described with reference to FIG. 4. Therefore, a description of an overlapping content may be omitted.

The input sensing layer ISL may sense a user's input on an upper surface (or a display surface) of the display panel DP′. The input sensing layer ISL may include components suitable for sensing an external object such as a user's hand, or a pen. For example, the input sensing layer ISL may include touch electrodes.

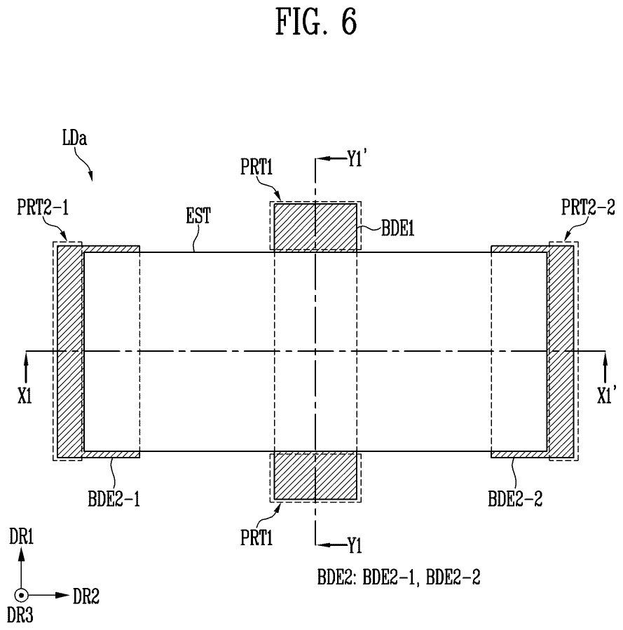

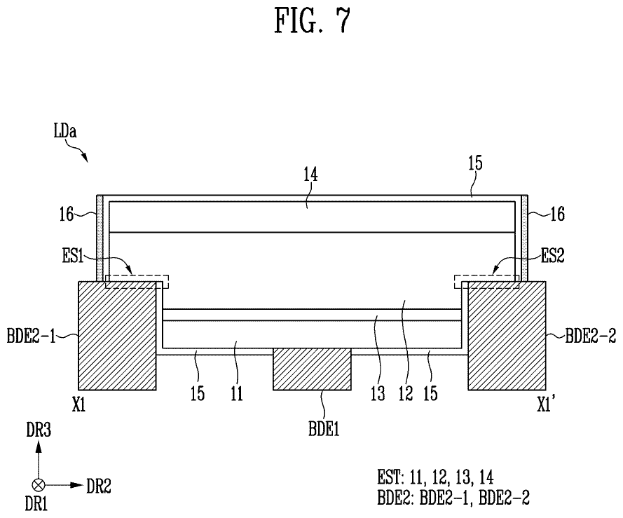

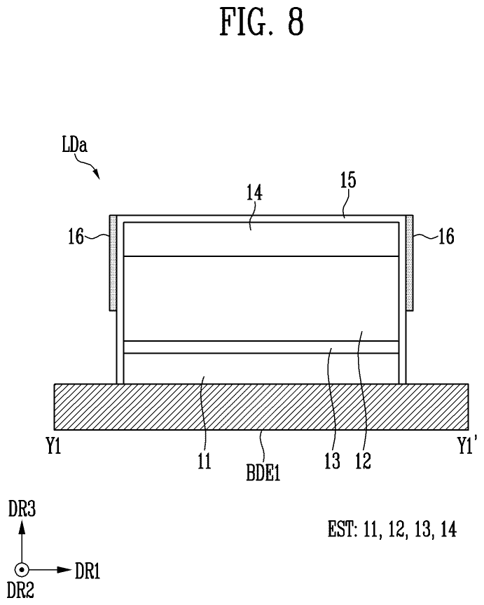

FIGS. 6 to 8 are schematic diagrams illustrating a light emitting element according to a first embodiment of the disclosure. FIG. 6 is a plan view illustrating the light emitting element according to the first embodiment of the disclosure, FIG. 7 is a schematic cross-sectional view taken along line X1-X1′ of FIG. 6, and FIG. 8 is a schematic cross-sectional view taken along line Y1-Y1′ of FIG. 6.

Referring to FIGS. 6 to 8, the light emitting element LDa may include a light emitting stack EST, a first bonding electrode BDE1, and a second bonding electrode BDE2.

The light emitting stack EST may include a first semiconductor layer 11, a second semiconductor layer 12 disposed on the first semiconductor layer 11, and an active layer 13 disposed between the first semiconductor layer 11 and the second semiconductor layer 12. In embodiments, the light emitting stack EST may further include an auxiliary layer 14 disposed on the second semiconductor layer 12.

The first semiconductor layer 11 provides a hole to the active layer 13. The first semiconductor layer 11 may include at least one p-type semiconductor layer. For example, the first semiconductor layer 11 may include at least one semiconductor material among gallium nitride (GaN), aluminum gallium nitride (AlGaN), indium gallium nitride (InGaN), aluminum nitride (AlN), and indium nitride (InN), and may be a p-type semiconductor layer doped with a p-type dopant such as magnesium (Mg), zinc (Zn), calcium (Ca), strontium (Sr), and barium (Ba). However, a material configuring the first semiconductor layer 11 is not limited thereto, and various other materials may configure the first semiconductor layer 11. In an embodiment, the first semiconductor layer 11 may include a gallium nitride (GaN) semiconductor material doped with the p-type dopant.

The second semiconductor layer 12 provides an electron to the active layer 13. The second semiconductor layer 12 may include at least one n-type semiconductor layer. For example, the second semiconductor layer 12 may include at least one semiconductor material among gallium nitride (GaN), aluminum gallium nitride (AlGaN), indium gallium nitride (InGaN), aluminum nitride (AlN), and indium nitride (InN), and may be an n-type semiconductor layer doped with an n-type dopant such as silicon (Si), germanium (Ge), and tin (Sn). However, a material configuring the second semiconductor layer 12 is not limited thereto, and various other materials may configure the second semiconductor layer 12. In an embodiment, the second semiconductor layer 12 may include a gallium nitride (GaN) semiconductor material doped with the n-type dopant. According to an embodiment, the second semiconductor layer 12 may configure the n-type semiconductor layer together with the auxiliary layer 14.

The active layer 13 may be disposed between the first semiconductor layer 11 and the second semiconductor layer 12 and may provide an area where the electron and the hole may be recombined. As the electron and the hole recombine in the active layer 13, the electron and the hole may transit to a lower energy level, and thus light having a wavelength corresponding thereto may be generated. The active layer 13 may be formed as a single or multiple quantum well structure. In case that the active layer 13 is formed as a multiple quantum well structure, a unit including a barrier layer, a strain reinforcing layer, and a well layer may be repeatedly stacked on each other to form the active layer 13. However, embodiments of the active layer 13 are not limited thereto.

The auxiliary layer 14 may include a gallium nitride (GaN) semiconductor material in which an impurity may not be substantially doped or an impurity may be doped with a relatively low concentration, and may configure the n-type semiconductor layer together with the second semiconductor layer 12.

The first bonding electrode BDE1 may be electrically connected to a lower surface of the first semiconductor layer 11. The first bonding electrode BDE1 may not physically contact the second semiconductor layer 12 and the active layer 13. In embodiments, the first bonding electrode BDE1 may include a eutectic metal.

The first bonding electrode BDE1 may be electrically connected to the anode electrode AE of FIG. 2. For example, the first bonding electrode BDE1 may be electrically connected to the anode electrode AE, or may be electrically connected to at least one electrode (or conductive layer) contacting the anode electrode AE.

The second bonding electrode BDE2 may include a (2-1)-th bonding electrode BDE2-1 and a (2-2)-th bonding electrode BDE2-2.

The (2-1)-th bonding electrode BDE2-1 may be electrically connected to the second semiconductor layer 12. The (2-2)-th bonding electrode BDE2-2 may be electrically connected to the second semiconductor layer 12. The (2-2)-th bonding electrode BDE2-2 may be spaced apart from the (2-1)-th bonding electrode BDE2-1 in the second direction DR2. The (2-1)-th bonding electrode BDE2-1 may not physically contact the first semiconductor layer 11, the active layer 13, the first bonding electrode BDE1, and the (2-2)-th bonding electrode BDE2-2. The (2-2)-th bonding electrode BDE2-2 may not physically contact the first semiconductor layer 11, the active layer 13, the first bonding electrode BDE1, and the (2-1)-th bonding electrode BDE2-1. In embodiments, the (2-1)-th bonding electrode BDE2-1 and the (2-2)-th bonding electrode BDE2-2 may include a eutectic metal.

The (2-1)-th bonding electrode BDE2-1 and the (2-2)-th bonding electrode BDE2-2 may be electrically connected to the cathode electrode CE of FIG. 2. For example, each of the (2-1)-th bonding electrode BDE2-1 and the (2-2)-th bonding electrode BDE2-2 may be electrically connected to the cathode electrode CE, or may be electrically connected to at least one electrode (or conductive layer) contacting the cathode electrode CE.

The first bonding electrode BDE1 may be disposed between the (2-1)-th bonding electrode BDE2-1 and the (2-2)-th bonding electrode BDE2-2. Accordingly, a separation distance between the first bonding electrode BDE1 and the (2-1)-th bonding electrode BDE2-1, and a separation distance between the first bonding electrode BDE1 and the (2-2)-th bonding electrode BDE2-2 may become relatively small. Therefore, a current distribution in the light emitting element LDa may become more uniform, and thus light emission efficiency of the light emitting element LDa may be improved.

In an embodiment, a first exposed surface ES1 and a second exposed surface ES2 that do not overlap the first semiconductor layer 11 and the active layer 13 in a plan view may be defined on a face surface of the second semiconductor layer 12 facing an outer peripheral surface of the active layer 13. For example, the first exposed surface ES1 and the second exposed surface ES2 may be surfaces where the second semiconductor layer 12 may be exposed as a portion of the first semiconductor layer 11 and the active layer 13 may be removed. The first exposed surface ES1 may be adjacent to a side surface of the second semiconductor layer 12, and the second exposed surface ES2 may be adjacent to another surface opposite to the one surface of the second semiconductor layer 12 in the second direction DR2. The (2-1)-th bonding electrode BDE2-1 may be electrically connected to the first exposed surface ES1, and the (2-2)-th bonding electrode BDE2-2 may be electrically connected to the second exposed surface ES2.

In an embodiment, the first bonding electrode BDE1 may include a first protrusion PRT1 protruding in at least one of the first direction DR1 and a direction opposite to the first direction DR1 so as to not overlap the light emitting stack EST in a plan view. For example, as shown in FIG. 6, the first bonding electrode BDE1 may include the first protrusion PRT1 protruding in the first direction DR1 and the direction opposite to the first direction DR1 compared to the light emitting stack EST. However, embodiments of the first protrusion PRT1 are not limited to that shown in FIG. 6. For example, the first bonding electrode BDE1 may include a first protrusion protruding only in the first direction DR1 compared to the light emitting stack EST, or may include a first protrusion protruding only in the direction opposite to the first direction DR1 compared to the light emitting stack EST.

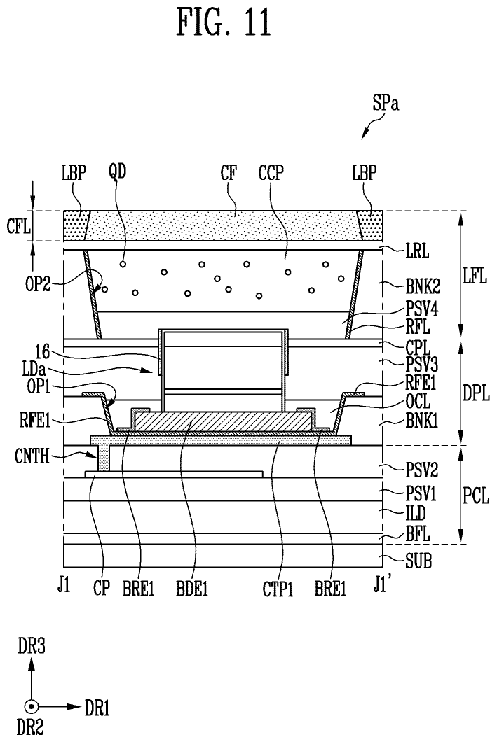

According to embodiments, a connection defect between the first bonding electrode BDE1 and the anode electrode AE may occur. For example, the first bonding electrode BDE1 and the anode electrode AE may not be electrically connected to each other due to a foreign material disposed between the first bonding electrode BDE1 and the anode electrode AE. In the disclosure, the first protrusion PRT1 of the first bonding electrode BDE1 may serve to secure a connection path between the first bonding electrode BDE1 and the anode electrode AE in case that a connection defect with the anode electrode AE described above occurs. This is described in detail later with reference to FIG. 11.

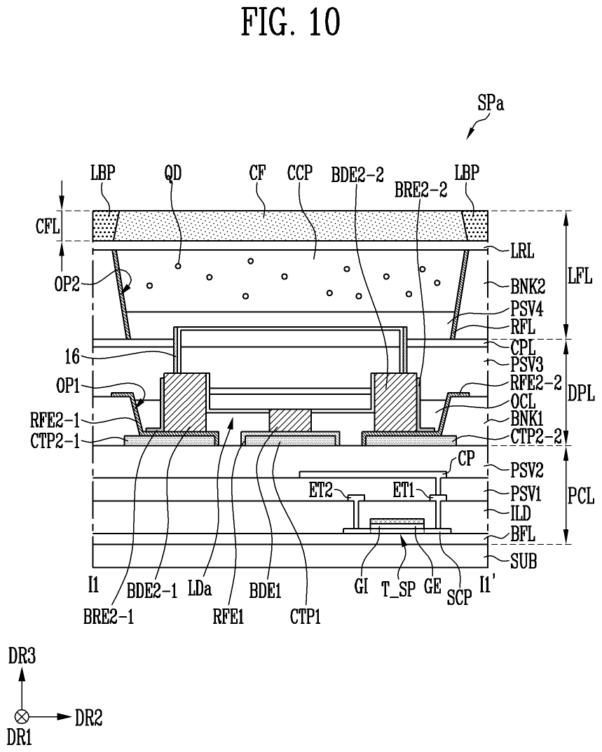

In an embodiment, the (2-1)-th bonding electrode BDE2-1 may include a (2-1)-th protrusion PRT2-1 protruding in a direction opposite to the second direction DR2 so as to not overlap the light emitting stack EST in a plan view. The (2-1)-th protrusion PRT2-1 of the (2-1)-th bonding electrode BDE2-1 may serve to secure a connection path between the (2-1)-th bonding electrode BDE2-1 and the cathode electrode CE in case that a connection defect with the cathode electrode CE of FIG. 2 occurs. For example, in case that the (2-1)-th bonding electrode BDE2-1 and the cathode electrode CE are not electrically connected to each other due to a foreign material disposed between the (2-1)-th bonding electrode BDE2-1 and the cathode electrode CE, the connection path between the (2-1)-th bonding electrode BDE2-1 and the cathode electrode CE may be secured through the (2-1)-th protrusion PRT2-1. This is described in detail later with reference to FIG. 10.

In an embodiment, the (2-2)-th bonding electrode BDE2-2 may include a (2-2)-th protrusion PRT2-2 protruding in the second direction DR2 so as not to overlap the light emitting stack EST in a plan view. The (2-2)-th protrusion PRT2-2 of the (2-2)-th bonding electrode BDE2-2 may serve to secure a connection path between the (2-2)-th bonding electrode BDE2-2 and the cathode electrode CE in case that a connection defect with the cathode electrode CE occurs. This is described in detail later with reference to FIG. 10.

In an embodiment, the light emitting element LDa may further include an insulating layer 15 surrounding at least a portion of an outer peripheral surface of the light emitting stack EST. For example, the insulating layer 15 may entirely surround the outer peripheral surface of the light emitting stack EST except for an area where the light emitting stack EST and the first and second bonding electrodes BDE1 and BDE2 may be electrically connected.

The insulating layer 15 may serve to prevent an electrical short circuit that may occur in case that the active layer 13 contacts another conductive material except for the first and second semiconductor layers 11 and 12. The insulating layer 15 may be disposed between the (2-1)-th bonding electrode BDE2-1 and the first semiconductor layer 11, and between the (2-1)-th bonding electrode BDE2-1 and the active layer 13, to serve to prevent an electrical short circuit that may occur in case that the (2-1)-th bonding electrode BDE2-1 contacts the first semiconductor layer 11 and the active layer 13. The insulating layer 15 may be disposed between the (2-2)-th bonding electrode BDE2-2 and the first semiconductor layer 11, and between the (2-2)-th bonding electrode BDE2-2 and the active layer 13, to serve to prevent an electrical short circuit that may occur in case that the (2-2)-th bonding electrode BDE2-2 contacts the first semiconductor layer 11 and the active layer 13. The insulating layer 15 may include a transparent insulating material. A portion of the first and second bonding electrodes BDE1 and BDE2 may not be covered by the insulating layer 15 and may be exposed.

Even though the light emitting element LDa further includes the insulating layer 15, each of the first protrusion PRT1 of the first bonding electrode BDE1, the (2-1)-th protrusion PRT2-1 of the (2-1)-th bonding electrode BDE2-1, and the (2-2)-th protrusion PRT2-2 of the (2-2)-th bonding electrode BDE2-2 may further protrude compared to the insulating layer 15 in a plan view.

In an embodiment, the light emitting element LDa may further include a reflective layer 16 surrounding at least a portion of a side surface of the light emitting stack EST. For example, the reflective layer 16 may surround a side surface of the auxiliary layer 14 and a portion of a side surface of the second semiconductor layer 12 on the second bonding electrode BDE2.

The reflective layer 16 may serve to improve front surface light emission efficiency of light generated in the active layer 13. For example, the insulating layer 15 may be disposed between the reflective layer 16 and the light emitting stack EST, and the reflective layer 16 may include a material having a refractive index different from that of the insulating layer 15. Accordingly, total reflection of light may be induced at an interface between the reflective layer 16 and the insulating layer 15, and thus the light generated in the active layer 13 may proceed in a front surface direction (for example, the third direction DR3 and a direction intersecting the third direction DR3) of the display panel DP of FIG. 3. As an example, the reflective layer 16 may include a material suitable for reflecting incident light. For example, the reflective layer 16 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them.

In an embodiment, the reflective layer 16 may contact each of the (2-1)-th bonding electrode BDE2-1 and the (2-2)-th bonding electrode BDE2-2. For example, as shown in FIG. 7, the reflective layer 16 may contact each of the (2-1)-th protrusion PRT2-1 of FIG. 6 of the (2-1)-th bonding electrode BDE2-1 and the (2-2)-th protrusion PRT2-2 of FIG. 6 of the (2-2)-th bonding electrode BDE2-2. The reflective layer 16 may be configured to include a conductive material. Accordingly, the (2-1)-th bonding electrode BDE2-1 and the (2-2)-th bonding electrode BDE2-2 may be electrically connected to each other by the reflective layer 16. Accordingly, even though a connection defect occurs between one of the (2-1)-th bonding electrode BDE2-1 and the (2-2)-th bonding electrode BDE2-2 and the cathode electrode CE, in case that one of the (2-1)-th bonding electrode BDE2-1 and the (2-2)-th bonding electrode BDE2-2 is normally electrically connected to the cathode electrode CE, both of the (2-1)-th bonding electrode BDE2-1 and the (2-2)-th bonding electrode BDE2-2 may be electrically connected to the cathode electrode CE through the reflective layer 16. For example, the reflective layer 16 may further serve to secure reliability of the (2-1)-th bonding electrode BDE2-1 and the (2-2)-th bonding electrode BDE2-2.

In the embodiment described above, the reflective layer 16 may be spaced apart from the first bonding electrode BDE1. For example, in case that the reflective layer 16 electrically connects the (2-1)-th bonding electrode BDE2-1 and the (2-2)-th bonding electrode BDE2-2 to each other, the first bonding electrode BDE1 may be spaced apart from the reflective layer 16. Accordingly, an electrical short circuit that the first bonding electrode BDE1 may be electrically connected to the (2-1)-th bonding electrode BDE2-1 and the (2-2)-th bonding electrode BDE2-2 through the reflective layer 16 may not occur.

Even though the light emitting element LDa further includes the reflective layer 16, each of the first protrusion PRT1 of the first bonding electrode BDE1, the (2-1)-th protrusion PRT2-1 of the (2-1)-th bonding electrode BDE2-1, and the (2-2)-th protrusion PRT2-2 of the (2-2)-th bonding electrode BDE2-2 may further protrude compared to the reflective layer 16 in a plan view.

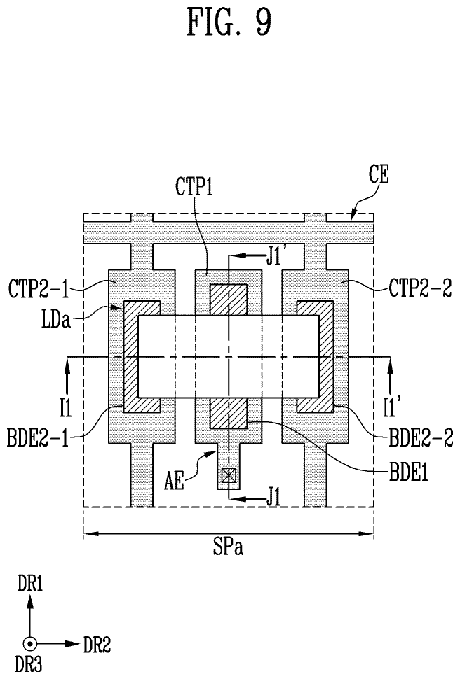

FIGS. 9 to 11 are schematic diagrams illustrating a sub-pixel including the light emitting element according to the first embodiment of the disclosure. FIG. 9 is a plan view illustrating the sub-pixel including the light emitting element according to the first embodiment of the disclosure, FIG. 10 is a schematic cross-sectional view taken along line I1-I1′ of FIG. 9, and FIG. 11 is a schematic cross-sectional view taken along line J1-J1′ of FIG. 9.

Referring to FIG. 9, the sub-pixel SPa may be provided. The sub-pixel SPa may be a sub-pixel among the first to third sub-pixels SP1, SP2, and SP3 described with reference to FIG. 3.

The sub-pixel SPa may include the anode electrode AE and the cathode electrode CE. The anode electrode AE may be electrically connected to the sub-pixel circuit SPC of FIG. 2 of the sub-pixel SPa. The cathode electrode CE may be spaced apart from the anode electrode AE. The cathode electrode CE may be disposed at the same height as the anode electrode AE. The anode electrode AE and the cathode electrode CE may define an electrode layer, and the anode electrode AE and the cathode electrode CE may be implemented as patterns of the electrode layer. In embodiments, the cathode electrode CE may extend in the first direction DR1 and may be used as a common electrode for the pixel PXL and other pixels adjacent to the pixel PXL. The cathode electrode CE may extend in the second direction DR2 and may be used as a common electrode for all of the sub-pixels SPa shown in FIG. 3.

The anode electrode AE may include a first contact portion CTP1. The cathode electrode CE may include a (2-1)-th contact portion CTP2-1 and a (2-2)-th contact portion CTP2-2. The (2-1)-th contact portion CTP2-1 and the (2-2)-th contact portion CTP2-2 may be electrically connected to each other.

The light emitting element LDa described with reference to FIGS. 6 to 8 may be disposed on the anode electrode AE and the cathode electrode CE. The first bonding electrode BDE1 of the light emitting element LDa may be disposed on the first contact portion CTP1 of the anode electrode AE. The (2-1)-th bonding electrode BDE2-1 of the light emitting element LDa may be disposed on the (2-1)-th contact portion CTP2-1 of the cathode electrode CE. The (2-2)-th bonding electrode BDE2-2 of the light emitting element LDa may be disposed on the (2-2)-th contact portion CTP2-2 of the cathode electrode CE.

The light emitting element LDa may be electrically connected to the anode electrode AE and the cathode electrode CE. The first bonding electrode BDE1 of the light emitting element LDa may be electrically connected to the anode electrode AE. The (2-1)-th bonding electrode BDE2-1 and the (2-2)-th bonding electrode BDE2-2 of the light emitting element LDa may be electrically connected to the cathode electrode CE.

Referring to FIGS. 9 to 11, the pixel circuit layer PCL, the display element layer DPL, and the light functional layer LFL may be sequentially disposed on the substrate SUB.

The pixel circuit layer PCL may include insulating layers, semiconductor patterns, and conductive patterns stacked on each other on the substrate SUB. The insulating layers may include a buffer layer BFL, at least one interlayer insulating layer ILD, and at least one passivation layer PSV1 and PSV2. The semiconductor patterns and the conductive patterns may be positioned between the insulating layers. The conductive patterns may include at least one of copper (Cu), molybdenum (Mo), tungsten (W), aluminum neodymium (AlNd), titanium (Ti), aluminum (Al), and silver (Ag).

As described with reference to FIG. 2, the sub-pixel circuit SPC of the sub-pixel SP may include transistors and at least one capacitor. The semiconductor patterns and the conductive patterns of the pixel circuit layer PCL may function as the transistors and the capacitors of the sub-pixel circuit SPC. The conductive patterns of the pixel circuit layer PCL may further functions as the lines, for example, the first to m-th gate lines GL1 to GLm, the first to n-th data lines DL1 to DLn, the power lines PL, and the pixel control lines PXCL of FIG. 1.

The buffer layer BFL may be disposed on one surface of the substrate SUB. The buffer layer BFL may serve to prevent an impurity from diffusing into the circuit elements and the lines included in the pixel circuit layer PCL. The buffer layer BFL may include an inorganic insulating layer including an inorganic material. In embodiments, the buffer layer BFL may include at least one of metal oxides such as silicon nitride, silicon oxide, silicon oxynitride, and aluminum oxide. The buffer layer BFL may be provided as a single layer or multiple layers. In case that the buffer layer BFL is provided as the multiple layers, each layer may be formed of a same material or may be formed of different materials.

In embodiments, at least one barrier layer may be disposed between the substrate SUB and the buffer layer BFL. Each of the barrier layers may include polyimide.

A transistor T_SP may be disposed on the buffer layer BFL. The transistor T_SP may be one of the transistors of the sub-pixel circuit SPC included in the sub-pixel SP. For example, the transistor T_SP may be a transistor electrically connected to the anode electrode AE among the transistors of the sub-pixel circuit SPC.

The transistor T_SP may include a semiconductor pattern SCP, a gate electrode GE, a first terminal ET1, and a second terminal ET2. The first terminal ET1 may be one of a source electrode and a drain electrode, and the second terminal ET2 may be another of the source electrode and the drain electrode. For example, the first terminal ET1 may be the source electrode, and the second terminal ET2 may be the drain electrode.

The semiconductor pattern SCP may be disposed on the buffer layer BFL. The semiconductor pattern SCP may include a first contact area contacting the first terminal ET1 and a second contact area contacting the second terminal ET2. An area between the first contact area and the second contact area may be a channel area. The channel area may overlap the gate electrode GE of the transistor T_SP. The channel area may be a semiconductor pattern for example not doped with an impurity and may be an intrinsic semiconductor. The first contact area and the second contact area may be a semiconductor pattern doped with an impurity. As the impurity, for example, a p-type impurity may be used, but embodiments are not limited thereto.

The semiconductor pattern SCP may include one of various types of semiconductors, for example, an amorphous silicon semiconductor, a monocrystalline silicon semiconductor, a polycrystalline silicon semiconductor, a low temperature poly silicon semiconductor, and an oxide semiconductor.

The interlayer insulating layers ILD sequentially stacked on each other may be disposed on the semiconductor pattern SCP. The interlayer insulating layers ILD may be inorganic insulating layers including an inorganic material. For example, each of the interlayer insulating layers ILD may include at least one of metal oxides such as silicon nitride, silicon oxide, silicon oxynitride, and aluminum oxide. However, the interlayer insulating layers ILD are not limited thereto. For example, one of the interlayer insulating layers ILD may include an organic insulating layer including an organic material.

The interlayer insulating layers ILD may electrically separate conductive patterns and/or semiconductor patterns disposed between the interlayer insulating layers ILD from each other. For example, the interlayer insulating layers ILD may include a gate insulating layer GI disposed on the semiconductor pattern SCP. The gate insulating layer GI may be disposed between the semiconductor pattern SCP and the gate electrode GE so that the gate electrode GE may be spaced apart from the semiconductor pattern SCP. In embodiments, the gate insulating layer GI may be provided entirely on the semiconductor pattern SCP and the buffer layer BFL to cover the semiconductor pattern SCP and the buffer layer BFL. As the number of layers required to form the conductive patterns and/or the semiconductor patterns increases, the number of interlayer insulating layers ILD may increase.

The gate electrode GE may be disposed on the gate insulating layer GI. The gate electrode GE may overlap the channel area of the semiconductor pattern SCP. In embodiments, the gate electrode GE may be provided as a single layer including at least one material among copper (Cu), molybdenum (Mo), tungsten (W), aluminum neodymium (AlNd), titanium (Ti), aluminum (Al), and silver (Ag). In embodiments, the gate electrode GE may be provided as multiple layers including at least one material among molybdenum (Mo), titanium (Ti), copper (Cu), aluminum (Al), and silver (Ag), which may be low-resistance materials.

The first and second terminals ET1 and ET2 may be disposed on the interlayer insulating layers ILD. The first and second terminals ET1 and ET2 may contact the semiconductor pattern SCP through contact holes passing through the interlayer insulating layers ILD. The first and second terminals ET1 and ET2 may respectively contact the first and second contact areas of the semiconductor pattern SCP. Each of the first and second terminals ET1 and ET2 may include at least one material among copper (Cu), molybdenum (Mo), tungsten (W), aluminum neodymium (AlNd), titanium (Ti), aluminum (Al), and silver (Ag).

Although the first and second terminals ET1 and ET2 are shown as separate electrodes electrically connected to the semiconductor pattern SCP, embodiments are not limited thereto. In embodiments, the first terminal ET1 may be a first contact area adjacent to a side of the channel area of the semiconductor pattern SCP, and the second terminal ET2 may be a second contact area adjacent to another side of the channel area. The first terminal ET1 may be electrically connected to the light emitting element LD through a connection means such as a bridge electrode disposed on at least one of the interlayer insulating layers ILD.

In embodiments, the transistor T_SP may be configured of a low-temperature polysilicon transistor. However, embodiments are not limited thereto. For example, the transistor T_SP may be configured of an oxide semiconductor transistor. In embodiments, the sub-pixel circuit SPC of the sub-pixel SP may include different types of transistors. For example, the transistor T_SP may be configured of a low-temperature polysilicon transistor, and another transistor of the sub-pixel SP may be configured of an oxide semiconductor transistor. The oxide semiconductor of the corresponding oxide semiconductor transistor may be disposed on one of the interlayer insulating layers ILD rather than the insulating layer on which the semiconductor pattern SCP of the transistor T_SP may be disposed.

In embodiments, a case where the transistor T_SP is a transistor of a top gate structure is described as an example, but embodiments are not limited thereto. For example, the transistor T_SP may be a transistor of a bottom gate structure. A structure of the transistor T_SP may be variously changed.

At least some of the various lines of the display panel DP and/or the display device DD may be further disposed on the interlayer insulating layers ILD.

The first passivation layer PSV1 may be disposed on the interlayer insulating layers ILD and the first and second terminals ET1 and ET2. A passivation layer may be referred to as a protective layer or a via layer. The first passivation layer PSV1 may protect components disposed under the first passivation layer PSV1 and may provide an approximately flat upper surface.

A connection electrode CP may be disposed on the first passivation layer PSV1. The connection electrode CP may be electrically connected to the first terminal ET1 of the transistor T_SP by passing through the first passivation layer PSV1. The connection electrode CP may include at least one material among copper (Cu), molybdenum (Mo), tungsten (W), aluminum neodymium (AlNd), titanium (Ti), aluminum (Al), and silver (Ag).

At least some of the various lines of the display panel DP and/or the display device DD may be further disposed on the first passivation layer PSV1.

The second passivation layer PSV2 may be disposed on the connection electrode CP and the first passivation layer PSV1. The second passivation layer PSV2 may protect components disposed under the second passivation layer PSV2 and may provide an approximately flat upper surface.

Each of the first and second passivation layers PSV1 and PSV2 may include an inorganic insulating layer including an inorganic material and/or an organic insulating layer including an organic material. The inorganic insulating layer may include, for example, at least one of metal oxides such as silicon oxide, silicon nitride, silicon oxynitride, and aluminum oxide. The organic insulating layer may include, for example, at least one of acrylic resin, epoxy resin, phenol resin, polyamide resin, polyimide resin, unsaturated polyester resin, poly-phenylene ether resin, poly-phenylene sulfide resin, and benzocyclobutene resin.

The display element layer DPL may be disposed on the second passivation layer PSV2. The display element layer DPL may include the anode electrode AE, the cathode electrode CE, a first bank BNK1, a first reflective electrode RFE1, a (2-1)-th reflective electrode RFE2-1, a (2-2)-th reflective electrode RFE2-2, the light emitting element LDa, an overcoat layer OCL, a third passivation layer PSV3, and a capping layer CPL.

The electrode layer including the anode electrode AE and the cathode electrode CE may be disposed on the pixel circuit layer PCL. The anode electrode AE may include a first contact portion CTP1, and the cathode electrode CE may include a (2-1)-th contact portion CTP2-1 and a (2-2)-th contact portion CTP2-2.

The anode electrode AE may be electrically connected to the connection electrode CP through a contact hole CNTH passing through the second passivation layer PSV2. As described above, the anode electrode AE may be electrically connected to the transistor T_SP.

The (2-1)-th contact portion CTP2-1 may be spaced apart from the first contact portion CTP1 in the direction opposite to the second direction DR2. The (2-2)-th contact portion CTP2-2 may be spaced apart from the first contact portion CTP1 in the second direction DR2. The cathode electrode CE may be electrically connected to the second power voltage node VSSN of FIG. 2. Accordingly, the second power voltage applied to the second power voltage node VSSN may be transmitted to the (2-1)-th contact portion CTP2-1 and the (2-2)-th contact portion CTP2-2.

The first bank BNK1 may be disposed on the anode electrode AE and the cathode electrode CE. The first bank BNK1 may have a first opening OP1 exposing portions of the anode electrode AE and the cathode electrode CE. The light emitting element LDa may be disposed in the first opening OP1 of the first bank BNK1. As described above, the first bank BNK1 may be provided as a pixel defining layer that defines an area where the light emitting element LDa may be positioned.

The first bank BNK1 may be configured to include a light blocking material and may serve to prevent light mixing between adjacent sub-pixels. In embodiments, the first bank BNK1 may include an organic material. For example, the first bank BNK1 may include an organic insulating material such as acryl resin, epoxy resin, phenol resin, polyamide resin, polyimide resin, or a combination thereof.

The first reflective electrode RFE1 may be disposed on an exposed portion of the first contact portion CTP1 and a side surface of the first bank BNK1 adjacent thereto. The (2-1)-th reflective electrode RFE2-1 may be disposed on an exposed portion of the (2-1)-th contact portion CTP2-1 and a side surface of the first bank BNK1 adjacent thereto. The (2-2)-th reflective electrode RFE2-2 may be disposed on an exposed portion of the (2-2)-th contact portion CTP2-2 and a side surface of the first bank BNK1 adjacent thereto. The first reflective electrode RFE1, the (2-1)-th reflective electrode RFE2-1, and the (2-2)-th reflective electrode RFE2-2 may include conductive materials suitable for reflecting light. Accordingly, light emission efficiency of the light emitting element LDa may be improved. In embodiments, the first reflective electrode RFE1, the (2-1)-th reflective electrode RFE2-1, and the (2-2)-th reflective electrode RFE2-2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them. However, embodiments are not limited thereto.

The light emitting element LDa may be electrically connected to the first contact portion CTP1 of the anode electrode AE through the first reflective electrode RFE1. For example, the first bonding electrode BDE1 of the light emitting element LDa may be electrically connected to the first reflective electrode RFE1, and thus the first bonding electrode BDE1 may be electrically connected to the first contact portion CTP1 of the anode electrode AE through the first reflective electrode RFE1.

The light emitting element LDa may be electrically connected to the (2-1)-th contact portion CTP2-1 of the cathode electrode CE through the (2-1)-th reflective electrode RFE2-1. For example, the (2-1)-th bonding electrode BDE2-1 of the light emitting element LDa may be electrically connected to the (2-1)-th reflective electrode RFE2-1, and thus the (2-1)-th bonding electrode BDE2-1 may be electrically connected to the (2-1)-th contact portion CTP2-1 of the cathode electrode CE through the (2-1)-th reflective electrode RFE2-1.

The light emitting element LDa may be electrically connected to the (2-2)-th contact portion CTP2-2 of the cathode electrode CE through the (2-2)-th reflective electrode RFE2-2. For example, the (2-2)-th bonding electrode BDE2-2 of the light emitting element LDa may be electrically connected to the (2-2)-th reflective electrode RFE2-2, and thus the (2-2)-th bonding electrode BDE2-2 may be electrically connected to the (2-2)-th contact portion CTP2-2 of the cathode electrode CE through the (2-2)-th reflective electrode RFE2-2.

The overcoat layer OCL may be disposed in the first opening OP1 where the first reflective electrode RFE1, the (2-1)-th reflective electrode RFE2-1, the (2-2)-th reflective electrode RFE2-2, and the light emitting element LDa are disposed. The overcoat layer OCL may fix the light emitting element LDa so that the light emitting element LDa electrically connected to the first reflective electrode RFE1, the (2-1)-th reflective electrode RFE2-1, and the (2-2)-th reflective electrode RFE2-2 does not move. The overcoat layer OCL may protect components disposed under the overcoat layer OCL from a foreign material such as dust and moisture. For example, the overcoat layer OCL may include at least one of an inorganic insulating layer and an organic insulating layer. For example, the overcoat layer OCL may include epoxy, but embodiments are not limited thereto.

The third passivation layer PSV3 may be disposed on the first bank BNK1 and the overcoat layer OCL. The third passivation layer PSV3 may protect components disposed under the third passivation layer PSV3 and may provide an approximately flat upper surface. The third passivation layer PSV3 and one of the first and second passivation layers PSV1 and PSV2 may include a same material, but embodiments are not limited thereto.

In embodiments, the third passivation layer PSV3 may not be disposed on an upper surface of the light emitting element LDa. The light emitting element LDa may protrude into the light functional layer LFL. The light emitting element LDa may be positioned at least partially in a second opening OP2 of a second bank BNK2. For example, a height of the upper surface of the light emitting element LDa from the substrate SUB may be higher than the lowest end of the light reflective layer RFL. Accordingly, light emitted from the light emitting element LDa may be provided to the light functional layer LFL at a relatively high rate.

The capping layer CPL may be disposed on the third passivation layer PSV3. The capping layer CPL may protect components under the capping layer CPL, such as the light emitting element LDa, from external water and moisture. In embodiments, the capping layer CPL may not be disposed on the upper surface of the light emitting element LDa. In other embodiments, the capping layer CPL may entirely cover the light emitting element LDa. The capping layer CPL may include at least one of metal oxides such as silicon nitride, silicon oxide, silicon oxynitride, and aluminum oxide. However, a material of the capping layer CPL is not limited thereto.

The light functional layer LFL may be disposed on the capping layer CPL. The light functional layer LFL may include the second bank BNK2, a light reflective layer RFL, a fourth passivation layer PSV4, a light functional pattern CCP, a low refractive layer LRL, and a color filter layer CFL.

The second bank BNK2 may be disposed on the capping layer CPL. The second bank BNK2 may overlap the first bank BNK1. The second bank BNK2 may have the second opening OP2 overlapping the first opening OP1.

The second bank BNK2 may be configured to include a light blocking material, thereby preventing light mixing between adjacent sub-pixels. In embodiments, the second bank BNK2 may include an organic material. For example, the second bank BNK2 may include an organic insulating material such as acryl resin, epoxy resin, phenol resin, polyamide resin, polyimide resin, or a combination thereof.

The light reflective layer RFL may be disposed on side surfaces of the second bank BNK2 adjacent to the second opening OP2. The light reflective layer RFL may be configured to reflect incident light, and thus light output efficiency may be improved. The light reflective layer RFL may include a material suitable for reflecting light. The light reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them. However, embodiments are not limited thereto.

On the capping layer CPL, the fourth passivation layer PSV4 may be disposed in the second opening OP2. The fourth passivation layer PSV4 may protect components disposed under the fourth passivation layer PSV4 and may provide an approximately flat upper surface. The fourth passivation layer PSV4 and one of the first to third passivation layers PSV1, PSV2, and PSV3 may include a same material, but embodiments are not limited thereto.

On the fourth passivation layer PSV4, the light functional pattern CCP may be disposed in the second opening OP2.

The light functional pattern CCP may include color conversion particles and/or scattering particles. The color conversion particles may change a wavelength of incident light and convert the incident light into light of a different color. The color conversion particles may scatter incident light. In embodiments, the color conversion particles may be quantum dots. The scattering particles may scatter incident light.

In an embodiment, the sub-pixel SPa may be a red sub-pixel. In case that the light emitting element LDa emits blue color light, the light functional pattern CCP may include color conversion particles QD configured to convert blue color light into red color light. In case that the light emitting element LDa emits red color light, the light functional pattern CCP may include scattering particles.

In an embodiment, the sub-pixel SPa may be a green sub-pixel. In case that the light emitting element LDa emits blue color light, the light functional pattern CCP may include color conversion particles QD configured to convert blue color light into green color light. In case that the light emitting element LDa emits green color light, the light functional pattern CCP may include scattering particles.

In still an embodiment, the sub-pixel SPa may be a blue sub-pixel. In case that the light emitting element LDa emits blue color light, the light functional pattern CCP may include scattering particles.

As described above, according to a color of light emitted from the light emitting element LDa, particles included in the light functional pattern CCP may be variously changed.

The low refractive layer LRL may be disposed on the second bank BNK2, the light reflective layer RFL, and the light functional pattern CCP. The low refractive layer LRL may have a refractive index lower than that of the light functional pattern CCP. The low refractive layer LRL may be configured to refract or totally reflect light according to an incidence angle of the light. For example, the low refractive layer LRL may provide light passing through the light functional pattern CCP back to the light functional pattern CCP. Accordingly, light conversion efficiency or light scattering efficiency of the light functional pattern CCP may be improved.

The color filter layer CFL may be disposed on the low refractive layer LRL. The color filter layer CFL may include a color filter CF and light blocking patterns LBP. The color filter CF may overlap the light functional pattern CCP. The color filter CF may selectively transmit light of a desired wavelength range. In case that the sub-pixel SPa is a red sub-pixel, the color filter CF may include a red color filter. For example, in case that the sub-pixel SPa is a green sub-pixel, the color filter CF may include a green color filter. The light blocking patterns LBP may include at least one of various types of light blocking materials.

Referring to FIGS. 6 to 9 and FIG. 11 again, in order to secure reliability of an electrical connection between the first bonding electrode BDE1 and the first contact portion CTP1, a first bridge electrode BRE1 may be further disposed.

In an embodiment, the first bonding electrode BDE1 may be normally electrically connected to the first reflective electrode RFE1 electrically contacting the first contact portion CTP1. For example, in a process of disposing the light emitting element LDa on the pixel circuit layer PCL, the first bonding electrode BDE1 may be electrically connected to the first contact portion CTP1. The first bridge electrode BRE1 may be omitted.

In an embodiment, the first bonding electrode BDE1 may not be normally electrically connected to the first reflective electrode RFE1 electrically contacting the first contact portion CTP1. For example, in the process of disposing the light emitting element LDa on the pixel circuit layer PCL, the first bonding electrode BDE1 may not be electrically connected to the first contact portion CTP1. In case that a connection defect is sensed through a light emission inspection process or the like subsequent to the above-described process, the first bridge electrode BRE1 for electrically connecting the first bonding electrode BDE1 and the first contact portion CTP1 may be disposed.

The first bridge electrode BRE1 may be disposed along an outer peripheral surface of the first protrusion PRT1 of the first bonding electrode BDE1. The first bridge electrode BRE1 may extend from the outer peripheral surface of the first protrusion PRT1 and may contact the first reflective electrode RFE1 electrically contacting the first contact portion CTP1. Accordingly, the first bonding electrode BDE1 may be electrically connected to the first contact portion CTP1 through the first bridge electrode BRE1.

In embodiments, the planar area of the first contact portion CTP1 may be sufficiently larger than the planar area of the first bonding electrode BDE1, and the first bonding electrode BDE1 may completely overlap a portion of the first contact portion CTP1 in a plan view. Accordingly, a space in which the first bridge electrode BRE1 may be disposed may be sufficiently secured.

Referring to FIGS. 6 to 10 again, in order to secure reliability of an electrical connection between the (2-1)-th bonding electrode BDE2-1 and the (2-1)-th contact portion CTP2-1, a (2-1)-th bridge electrode BRE2-1 may be further disposed.

In an embodiment, the (2-1)-th bonding electrode BDE2-1 may be normally electrically connected to the (2-1)-th reflective electrode RFE2-1 electrically contacting the (2-1)-th contact portion CTP2-1. For example, in the process of disposing the light emitting element LDa on the pixel circuit layer PCL, the (2-1)-th bonding electrode BDE2-1 may be electrically connected to the (2-1)-th contact portion CTP2-1. The (2-1)-th bridge electrode BRE2-1 may be omitted.

In an embodiment, the (2-1)-th bonding electrode BDE2-1 may not be normally electrically connected to the (2-1)-th reflective electrode RFE2-1 electrically contacting the (2-1)-th contact portion CTP2-1. For example, in the process of disposing the light emitting element LDa on the pixel circuit layer PCL, the (2-1)-th bonding electrode BDE2-1 may not be electrically connected to the (2-1)-th contact portion CTP2-1. In case that a connection defect is sensed through a light emission inspection process or the like subsequent to the above-described process, the (2-1)-th bridge electrode BRE2-1 for electrically connecting the (2-1)-th bonding electrode BDE2-1 and the (2-1)-th contact portion CTP2-1 may be disposed.

The (2-1)-th bridge electrode BRE2-1 may be disposed along a side surface of the (2-1)-th protrusion PRT2-1 of the (2-1)-th bonding electrode BDE2-1. The (2-1)-th bridge electrode BRE2-1 may extend from the side surface of the (2-1)-th protrusion PRT2-1 and may contact the (2-1)-th reflective electrode RFE2-1 electrically contacting the (2-1)-th contact portion CTP2-1. Accordingly, the (2-1)-th bonding electrode BDE2 may be electrically connected to the (2-1)-th contact portion CTP2-1 through the (2-1)-th bridge electrode BRE2-1.

In embodiments, the planar area of the (2-1)-th contact portion CTP2-1 may be sufficiently larger than the planar area of the (2-1)-th bonding electrode BDE2-1, and the (2-1)-th bonding electrode BDE2-1 may completely overlap a portion of the (2-1)-th contact portion CTP2-1 in a plan view. Accordingly, a space in which the (2-1)-th bridge electrode BRE2-1 may be disposed may be sufficiently secured.

Referring to FIGS. 6 to 10 again, in order to secure reliability of an electrical connection between the (2-2)-th bonding electrode BDE2-2 and the (2-2)-th contact portion CTP2-2, a (2-2)-th bridge electrode BRE2-2 may be further disposed.

In an embodiment, the (2-2)-th bonding electrode BDE2-2 may be normally electrically connected to the (2-2)-th reflective electrode RFE2-2 electrically contacting the (2-2)-th contact portion CTP2-2. For example, in the process of disposing the light emitting element LDa on the pixel circuit layer PCL, the (2-2)-th bonding electrode BDE2-2 may be electrically connected to the (2-2)-th contact portion CTP2-2. The (2-2)-th bridge electrode BRE2-2 may be omitted.

In an embodiment, the (2-2)-th bonding electrode BDE2-2 may not be normally electrically connected to the (2-2)-th reflective electrode RFE2-2 electrically contacting the (2-2)-th contact portion CTP2-2. For example, in the process of disposing the light emitting element LDa on the pixel circuit layer PCL, the (2-2)-th bonding electrode BDE2-2 may not be electrically connected to the (2-2)-th contact portion CTP2-2. In case that a connection defect is sensed through a light emission inspection process or the like subsequent to the above-described process, the (2-2)-th bridge electrode BRE2-2 for electrically connecting the (2-2)-th bonding electrode BDE2-2 and the (2-2)-th contact portion CTP2-2 may be disposed.

The (2-2)-th bridge electrode BRE2-2 may be disposed along a side surface of the (2-2)-th protrusion PRT2-2 of the (2-2)-th bonding electrode BDE2-2. The (2-2)-th bridge electrode BRE2-2 may extend from the side surface of the (2-2)-th protrusion PRT2-2 and may contact the (2-2)-th reflective electrode RFE2-2 electrically contacting the (2-2)-th contact portion CTP2-2. Accordingly, the (2-2)-th bonding electrode BDE2-2 may be electrically connected to the (2-2)-th contact portion CTP2-2 through the (2-2)-th bridge electrode BRE2-2.

In embodiments, the planar area of the (2-2)-th contact portion CTP2-2 may be sufficiently larger than the planar area of the (2-2)-th bonding electrode BDE2-2, and the (2-2)-th bonding electrode BDE2-2 may completely overlap a portion of the (2-2)-th contact portion CTP2-2 in a plan view. Accordingly, a space in which the (2-2)-th bridge electrode BRE2-2 may be disposed may be sufficiently secured.

As described above with reference to FIGS. 6 to 11, the light emitting element LDa of the disclosure may have a relatively small distance between bonding electrodes electrically connected to different semiconductor layers, and thus may have excellent light emission efficiency. Even though a connection defect occurs in the process of disposing the light emitting element LDa on the pixel circuit layer PCL, the connection defect described above may be readily repaired using the bridge electrodes BRE1, BRE2-1, and BRE2-2 without need to perform a removal process of removing the light emitting element LDa.

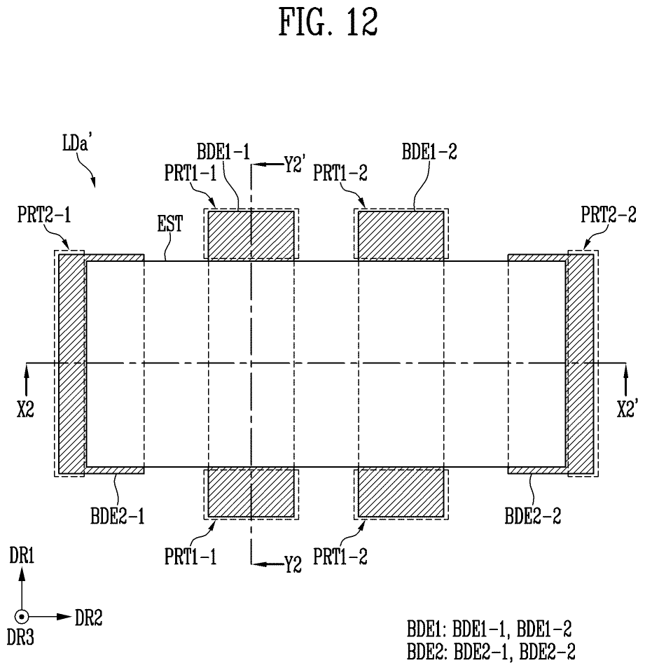

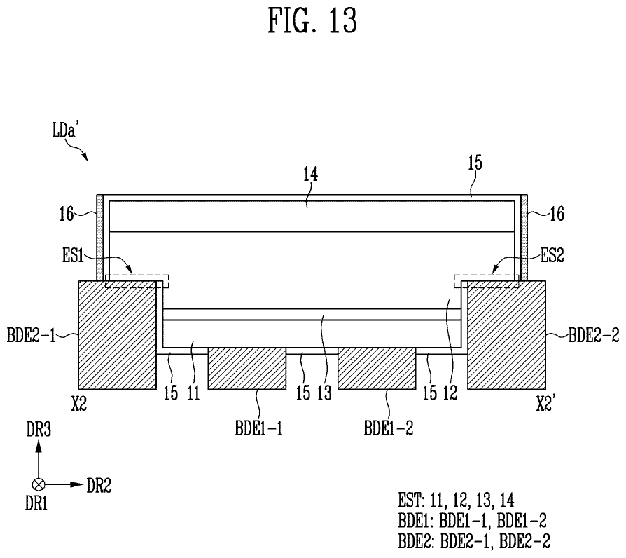

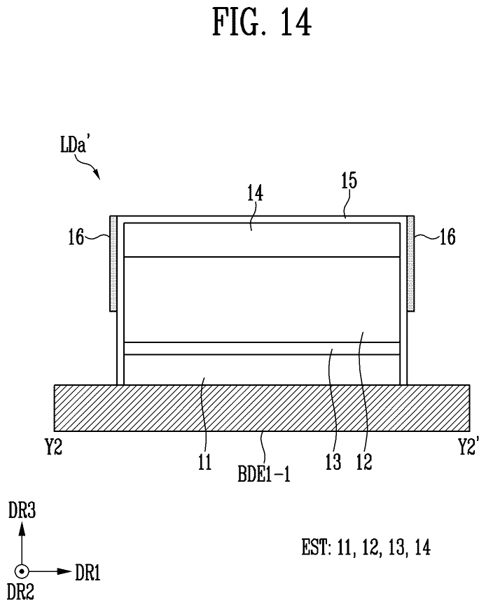

FIGS. 12 to 14 are schematic diagrams illustrating a light emitting element according to a second embodiment of the disclosure. FIG. 12 is a plan view illustrating the light emitting element according to the second embodiment of the disclosure, FIG. 13 is a schematic cross-sectional view taken along line X2-X2′ of FIG. 12, and FIG. 14 is a schematic cross-sectional view taken along line Y2-Y2′ of FIG. 12.

Referring to FIGS. 12 to 14, the light emitting element LDa′ may include a light emitting stack EST, a first bonding electrode BDE1, and a second bonding electrode BDE2.

The light emitting stack EST may be described substantially equally (or similarly) to that described with reference to FIGS. 6 to 8. The light emitting stack EST may include a first semiconductor layer 11, a second semiconductor layer 12 disposed on the first semiconductor layer 11, and an active layer 13 disposed between the first semiconductor layer 11 and the second semiconductor layer 12. In embodiments, the light emitting stack EST may further include an auxiliary layer 14 disposed on the second semiconductor layer 12. Hereinafter, an overlapping description may be omitted.

The first bonding electrode BDE1 may include a (1-1)-th bonding electrode BDE1-1 and a (1-2)-th bonding electrode BDE1-2. The (1-1)-th bonding electrode BDE1-1 may be electrically connected to a lower surface of the first semiconductor layer 11. The (1-2)-th bonding electrode BDE1-2 may be electrically connected to the lower surface of the first semiconductor layer 11. The (1-2)-th bonding electrode BDE1-2 may be spaced apart from the (1-1)-th bonding electrode BDE1-1 in the second direction DR2. Each of the (1-1)-th bonding electrode BDE1-1 and the (1-2)-th bonding electrode BDE1-2 may not physically contact the second semiconductor layer 12 and the active layer 13. In embodiments, the (1-1)-th bonding electrode BDE1-1 and the (1-2)-th bonding electrode BDE1-2 may include a eutectic metal.

The first bonding electrode BDE1 may be electrically connected to the anode electrode AE of FIG. 2. For example, each of the (1-1)-th bonding electrode BDE1-1 and the (1-2)-th bonding electrode BDE1-2 may be electrically connected to the anode electrode AE, or may be electrically connected to at least one electrode (or conductive layer) contacting the anode electrode AE.

The second bonding electrode BDE2 may be described substantially equally (or similarly) to that described with reference to FIGS. 6 to 8. The second bonding electrode BDE2 may include a (2-1)-th bonding electrode BDE2-1 and a (2-2)-th bonding electrode BDE2-2. The (2-1)-th bonding electrode BDE2-1 may be electrically connected to the first exposed surface ES1, and the (2-2)-th bonding electrode BDE2-2 may be electrically connected to the second exposed surface ES2. The (2-1)-th bonding electrode BDE2-1 and the (2-2)-th bonding electrode BDE2-2 may be electrically connected to the cathode electrode CE of FIG. 2. The (2-1)-th bonding electrode BDE2-1 and the (2-2)-th bonding electrode BDE2-2 may not physically contact the (1-1)-th bonding electrode BDE1-1 and the (1-2)-th bonding electrode BDE1-2. In embodiments, the (2-1)-th bonding electrode BDE2-1 and the (2-2)-th bonding electrode BDE2-2 may include a eutectic metal. Hereinafter, an overlapping description may be omitted.

The (1-1)-th bonding electrode BDE1-1 and the (1-2)-th bonding electrode BDE1-2 may be disposed between the (2-1)-th bonding electrode BDE2-1 and the (2-2)-th bonding electrode BDE2-2. Accordingly, a separation distance between the (1-1)-th bonding electrode BDE1-1 and the (2-1)-th bonding electrode BDE2-1, and a separation distance between the (1-2)-th bonding electrode BDE1-2 and the (2-2)-th bonding electrode BDE2-2 may become relatively small. Accordingly, a current distribution in the light emitting element LDa′ may become more uniform, and thus light emission efficiency of the light emitting element LDa′ may be improved.

In an embodiment, the first bonding electrode BDE1 may include a first protrusion protruding in at least one of the first direction DR1 and the direction opposite to the first direction DR1 so as to not overlap the light emitting stack EST in a plan view. For example, the (1-1)-th bonding electrode BDE1-1 and the (1-2)-th bonding electrode BDE1-2 may include the (1-1)-th protrusion PRT1-1 and the (1-2)-th protrusion PRT1-2, respectively protruding in at least one of the first direction DR1 or the direction opposite to the first direction DR1 so as to not overlap the light emitting stack EST in a plan view.

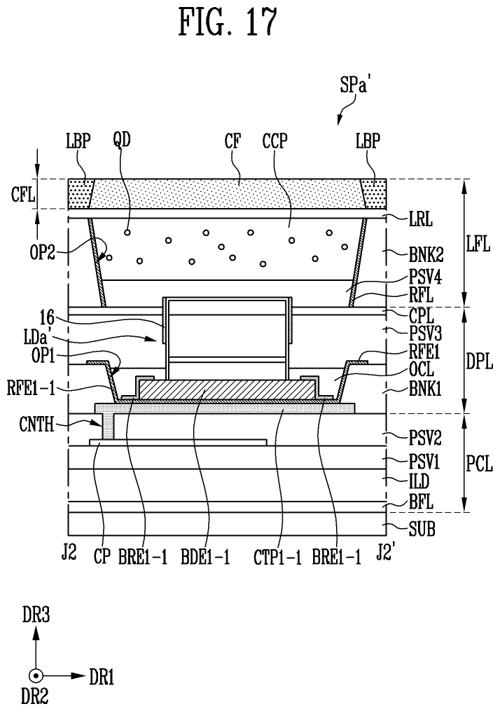

The (1-1)-th protrusion PRT1-1 and the (1-2)-th protrusion PRT1-2 of the (1-1)-th bonding electrode BDE1-1 and the (1-2)-th bonding electrode BDE1-2, respectively may serve to secure a connection path between the first bonding electrode BDE1 and the anode electrode AE in case that a connection defect with the anode electrode AE occurs. This is described in detail later with reference to FIG. 17.

In an embodiment, the light emitting element LDa′ may further include an insulating layer 15 surrounding at least a portion of an outer peripheral surface of the light emitting stack EST. The insulating layer 15 may be described substantially equally (or similarly) to that described with reference to FIGS. 6 to 8. For example, the insulating layer 15 may entirely surround the outer peripheral surface of the light emitting stack EST except for an area where the light emitting stack EST and the first and second bonding electrodes BDE1 and BDE2 are electrically connected. Hereinafter, an overlapping description is omitted.

In an embodiment, the light emitting element LDa′ may further include a reflective layer 16 surrounding at least a portion of a side surface of the light emitting stack EST. The reflective layer 16 may be described substantially equally (or similarly) to that described with reference to FIGS. 6 to 8. For example, the reflective layer 16 may surround a side surface of the auxiliary layer 14 and a portion of a side surface of the second semiconductor layer 12 on the second bonding electrode BDE2. Hereinafter, an overlapping description is omitted.

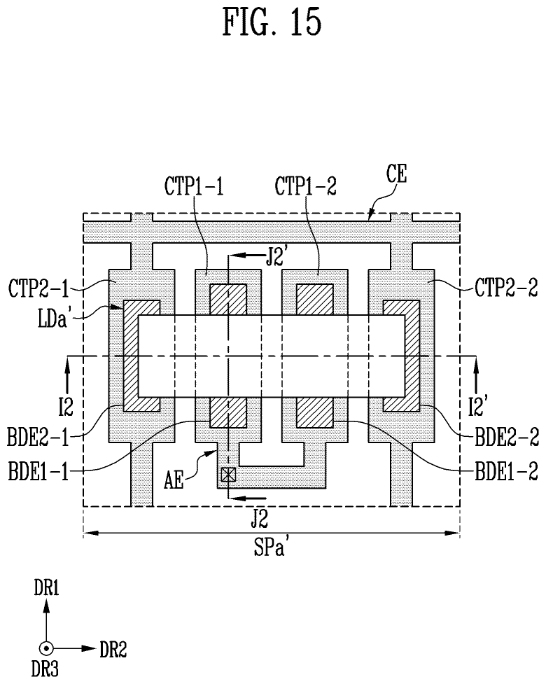

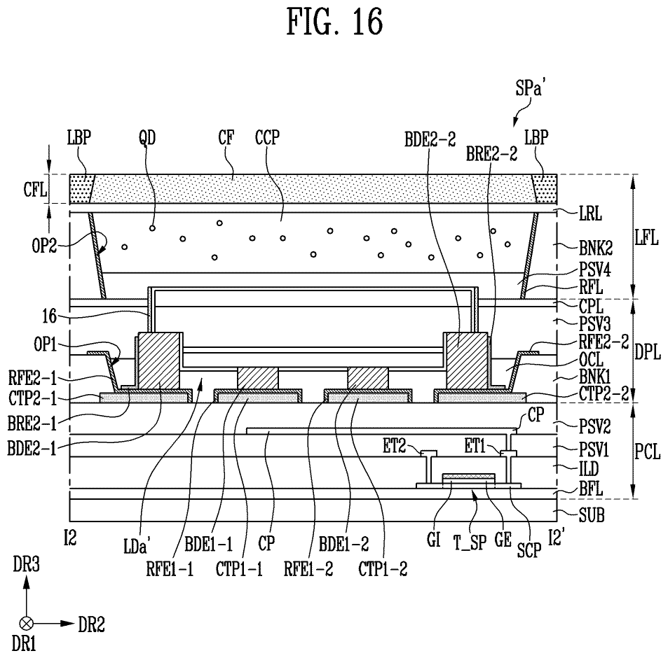

FIGS. 15 to 17 are schematic diagrams illustrating a sub-pixel including the light emitting element according to the second embodiment of the disclosure. FIG. 15 is a plan view illustrating the sub-pixel including the light emitting element according to the second embodiment of the disclosure, FIG. 16 is a schematic cross-sectional view taken along line I2-I2′ of FIG. 15, and FIG. 17 is a schematic cross-sectional view taken along line J2-J2′ of FIG. 15.

Referring to FIG. 15, the sub-pixel SPa′ may be provided. The sub-pixel SPa′ may be one sub-pixel among the first to third sub-pixels SP1, SP2, and SP3 described with reference to FIG. 3.

The sub-pixel SPa′ may include the anode electrode AE and the cathode electrode CE. The anode electrode AE may be electrically connected to the sub-pixel circuit SPC of FIG. 2 of the sub-pixel SPa′. The cathode electrode CE may be spaced apart from the anode electrode AE. The cathode electrode CE may be disposed at the same height as the anode electrode AE. The anode electrode AE and the cathode electrode CE may define an electrode layer, and the anode electrode AE and the cathode electrode CE may be implemented as patterns of the electrode layer. In embodiments, the cathode electrode CE may extend in the first direction DR1 and may be used as a common electrode for the pixel PXL and other pixels adjacent to the pixel PXL. The cathode electrode CE may extend in the second direction DR2 and may be used as a common electrode for all of the sub-pixels SP shown in FIG. 3.

The anode electrode AE may include a (1-1)-th contact portion CTP1-1 and a (1-2)-th contact portion CTP1-2. The (1-1)-th contact portion CTP1-1 and the (1-2)-th contact portion CTP1-2 may be electrically connected to each other. The cathode electrode CE may include a (2-1)-th contact portion CTP2-1 and a (2-2)-th contact portion CTP2-2. The (2-1)-th contact portion CTP2-1 and the (2-2)-th contact portion CTP2-2 may be electrically connected to each other.

The light emitting element LDa′ described with reference to FIGS. 12 to 14 may be disposed on the anode electrode AE and the cathode electrode CE. The (1-1)-th bonding electrode BDE1-1 of the light emitting element LDa′ may be disposed on the (1-1)-th contact portion CTP1-1 of the anode electrode AE. The (1-2)-th bonding electrode BDE1-2 of the light emitting element LDa′ may be disposed on the (1-2)-th contact portion CTP1-2 of the anode electrode AE. The (2-1)-th bonding electrode BDE2-1 of the light emitting element LDa′ may be disposed on the (2-1)-th contact portion CTP2-1 of the cathode electrode CE. The (2-2)-th bonding electrode BDE2-2 of the light emitting element LDa′ may be disposed on the (2-2)-th contact portion CTP2-2 of the cathode electrode CE.

The light emitting element LDa′ may be electrically connected to the anode electrode AE and the cathode electrode CE. The (1-1)-th bonding electrode BDE1-1 and the (1-2)-th bonding electrode BDE1-2 of the light emitting element LDa′ may be electrically connected to the anode electrode AE. The (2-1)-th bonding electrode BDE2-1 and the (2-2)-th bonding electrode BDE2-2 of the light emitting element LDa′ may be electrically connected to the cathode electrode CE.

Referring to FIGS. 15 to 17, the pixel circuit layer PCL, the display element layer DPL, and the light functional layer LFL may be sequentially disposed on the substrate SUB.

The pixel circuit layer PCL may be described substantially equally (or similarly) to that described with reference to FIGS. 9 to 11. Therefore, an overlapping description is omitted.

The display element layer DPL may be disposed on the second passivation layer PSV2. The display element layer DPL may include the anode electrode AE, the cathode electrode CE, the first bank BNK1, a (1-1)-th reflective electrode RFE1-1, a (1-2)-th reflective electrode RFE1-2, a (2-1)-th reflective electrode RFE2-1, a (2-2)-th reflective electrode RFE2-2, the light emitting element LDa′, an overcoat layer OCL, a third passivation layer PSV3, and a capping layer CPL.

The electrode layer including the anode electrode AE and the cathode electrode CE may be disposed on the pixel circuit layer PCL. The anode electrode AE may include a (1-1)-th contact portion CTP1 and a (1-2)-th contact portion CTP1-2, and the cathode electrode CE may include a (2-1)-th contact portion CTP2-1 and a (2-2)-th contact portion CTP2-2.

The anode electrode AE may be electrically connected to the connection electrode CP through a contact hole CNTH passing through the second passivation layer PSV2. As described above, the anode electrode AE may be electrically connected to the transistor T_SP.

The (1-2)-th contact portion CTP1-2 may be spaced apart from the (1-1)-th contact portion CTP1-1 in the second direction DR2. Since the anode electrode AE may be electrically connected to the transistor T_SP, the (1-1)-th contact portion CTP1-1 and the (1-2)-th contact portion CTP1-2 may be electrically connected to the transistor T_SP.

The (2-1)-th contact portion CTP2-1 may be spaced apart from the (1-1)-th contact portion CTP1-1 in the direction opposite to the second direction DR2. The (2-2)-th contact portion CTP2-2 may be spaced apart from the (1-2)-th contact portion CTP1-2 in the second direction DR2. The cathode electrode CE may be electrically connected to the second power voltage node VSSN of FIG. 2. Accordingly, the second power voltage applied to the second power voltage node VSSN may be transmitted to the (2-1)-th contact portion CTP2-1 and the (2-2)-th contact portion CTP2-2.

The first bank BNK1 may be disposed on the anode electrode AE and the cathode electrode CE. The first bank BNK1 may have a first opening OP1 exposing portions of the anode electrode AE and the cathode electrode CE. The light emitting element LDa′ may be disposed in the first opening OP1 of the first bank BNK1. As described above, the first bank BNK1 may be provided as a pixel defining layer that defines an area where the light emitting element LDa′ may be positioned.

The first bank BNK1 may be configured to include a light blocking material and may serve to prevent light mixing between adjacent sub-pixels. In embodiments, the first bank BNK1 may include an organic material. For example, the first bank BNK1 may include an organic insulating material such as acryl resin, epoxy resin, phenol resin, polyamide resin, polyimide resin, or a combination thereof.

The (1-1)-th reflective electrode RFE1-1 may be disposed on an exposed portion of the (1-1)-th contact portion CTP1-1 and a side surface of the first bank BNK1 adjacent thereto. The (1-2)-th reflective electrode RFE1-2 may be disposed on an exposed portion of the (1-2)-th contact portion CTP1-2 and a side surface of the first bank BNK1 adjacent thereto. The (2-1)-th reflective electrode RFE2-1 may be disposed on an exposed portion of the (2-1)-th contact portion CTP2-1 and a side surface of the first bank BNK1 adjacent thereto. The (2-2)-th reflective electrode RFE2-2 may be disposed on an exposed portion of the (2-2)-th contact portion CTP2-2 and a side surface of the first bank BNK1 adjacent thereto. The (1-1)-th reflective electrode RFE1-1, the (1-2)-th reflective electrode REF1-2, the (2-1)-th reflective electrode RFE2-1, and the (2-2)-th reflective electrode RFE2-2 may include conductive materials suitable for reflecting light. Accordingly, light emission efficiency of the light emitting element LDa′ may be improved. In embodiments, the (1-1)-th reflective electrode RFE1-1, the (1-2)-th reflective electrode REF1-2, the (2-1)-th reflective electrode RFE2-1, and the (2-2)-th reflective electrode RFE2-2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them. However, embodiments are not limited thereto.

The light emitting element LDa′ may be electrically connected to the (1-1)-th contact portion CTP1-1 of the anode electrode AE through the (1-1)-th reflective electrode RFE1-1. For example, the (1-1)-th bonding electrode BDE1-1 of the light emitting element LDa′ may be electrically connected to the (1-1)-th reflective electrode RFE1-1, and thus the (1-1)-th bonding electrode BDE1-1 may be electrically connected to the (1-1)-th contact portion CTP1-1 of the anode electrode AE through the (1-1)-th reflective electrode RFE1-1.

The light emitting element LDa′ may be electrically connected to the (1-2)-th contact portion CTP1-2 of the anode electrode AE through the (1-2)-th reflective electrode RFE1-2. For example, the (1-2)-th bonding electrode BDE1-2 of the light emitting element LDa′ may be electrically connected to the (1-2)-th reflective electrode RFE1-2, and thus the (1-2)-th bonding electrode BDE1-2 may be electrically connected to the (1-2)-th contact portion CTP1-2 of the anode electrode AE through the (1-2)-th reflective electrode RFE1-2.

The light emitting element LDa′ may be electrically connected to the (2-1)-th contact portion CTP2-1 of the cathode electrode CE through the (2-1)-th reflective electrode RFE2-1. For example, the (2-1)-th bonding electrode BDE2-1 of the light emitting element LDa′ may be electrically connected to the (2-1)-th reflective electrode RFE2-1, and thus the (2-1)-th bonding electrode BDE2-1 may be electrically connected to the (2-1)-th contact portion CTP2-1 of the cathode electrode CE through the (2-1)-th reflective electrode RFE2-1.

The light emitting element LDa′ may be electrically connected to the (2-2)-th contact portion CTP2-2 of the cathode electrode CE through the (2-2)-th reflective electrode RFE2-2. For example, the (2-2)-th bonding electrode BDE2-2 of the light emitting element LDa′ may be electrically connected to the (2-2)-th reflective electrode RFE2-2, and thus the (2-2)-th bonding electrode BDE2-2 may be electrically connected to the (2-2)-th contact portion CTP2-2 of the cathode electrode CE through the (2-2)-th reflective electrode RFE2-2.

The overcoat layer OCL may be disposed in the first opening OP1 where the (1-1)-th reflective electrode RFE1-1, the (1-2)-th reflective electrode REF1-2, the (2-1)-th reflective electrode RFE2-1, the (2-2)-th reflective electrode RFE2-2, and the light emitting element LDa′ may be disposed. The overcoat layer OCL may fix the light emitting element LDa′ so that the light emitting element LDa′ electrically connected to the (1-1)-th reflective electrode RFE1-1, the (1-2)-th reflective electrode REF1-2, the (2-1)-th reflective electrode RFE2-1, and the (2-2)-th reflective electrode RFE2-2 does not move. The overcoat layer OCL may protect components disposed under the overcoat layer OCL from a foreign material such as dust and moisture. For example, the overcoat layer OCL may include at least one of an inorganic insulating layer and an organic insulating layer. For example, the overcoat layer OCL may include epoxy, but embodiments are not limited thereto.

The third passivation layer PSV3 may be disposed on the first bank BNK1 and the overcoat layer OCL. The capping layer CPL may be disposed on the third passivation layer PSV3. The third passivation layer PSV3 and the capping layer CPL may be described substantially equally (or similarly) to those described with reference to FIGS. 9 to 11. Therefore, an overlapping description is omitted.

The light functional layer LFL may be disposed on the capping layer CPL. The light functional layer LFL may include a second bank BNK2, a light reflective layer RFL, a fourth passivation layer PSV4, a light functional pattern CCP, a low refractive layer LRL, and a color filter layer CFL. The light functional layer LFL may be described substantially equally (or similarly) to that described with reference to FIGS. 9 to 11. Therefore, an overlapping description is omitted.

Referring to FIGS. 12 to 15 and FIG. 17 again, in order to secure reliability of an electrical connection between the (1-1)-th bonding electrode BDE1-1 and the (1-1)-th contact portion CTP1-1, a (1-1)-th bridge electrode BRE1-1 may be further disposed.

In an embodiment, the (1-1)-th bonding electrode BDE1-1 may be normally electrically connected to the (1-1)-th reflective electrode RFE1-1 electrically contacting the (1-1)-th contact portion CTP1-1. For example, in a process of disposing the light emitting element LDa′ on the pixel circuit layer PCL, the (1-1)-th bonding electrode BDE1-1 may be electrically connected to the (1-1)-th contact portion CTP1-1. The (1-1)-th bridge electrode BRE1-1 may be omitted.

In an embodiment, the (1-1)-th bonding electrode BDE1-1 may not be normally electrically connected to the (1-1)-th reflective electrode RFE1-1 electrically contacting the (1-1)-th contact portion CTP1-1. For example, in the process of disposing the light emitting element LDa′ on the pixel circuit layer PCL, the (1-1)-th bonding electrode BDE1-1 may not be electrically connected to the (1-1)-th contact portion CTP1-1. In case that a connection defect is sensed through a light emission inspection process or the like subsequent to the above-described process, the (1-1)-th bridge electrode BRE1-1 for electrically connecting the (1-1)-th bonding electrode BDE1-1 and the (1-1)-th contact portion CTP1-1 may be disposed.

The (1-1)-th bridge electrode BRE1-1 may be disposed along an outer peripheral surface of the first protrusion PRT1 of the (1-1)-th bonding electrode BDE1-1. The (1-1)-th bridge electrode BRE1-1 may extend from the outer peripheral surface of the first protrusion PRT1 and may contact the (1-1)-th reflective electrode RFE1-1 electrically contacting the (1-1)-th contact portion CTP1-1. Accordingly, the (1-1)-th bonding electrode BDE1-1 may be electrically connected to the (1-1)-th contact portion CTP1-1 through the (1-1)-th bridge electrode BRE1-1.

In embodiments, the planar area of the (1-1)-th contact portion CTP1-1 may be sufficiently larger than the planar area of the (1-1)-th bonding electrode BDE1-1, and the (1-1)-th bonding electrode BDE1-1 may completely overlap a portion of the (1-1)-th contact portion CTP1-1 in a plan view. Accordingly, a space in which the (1-1)-th bridge electrode BRE1-1 may be disposed may be sufficiently secured.

In FIG. 17, the (1-1)-th bonding electrode BDE1-1, the (1-1)-th bridge electrode BRE1-1, and the like are shown, but the content described above may also be applied to the (1-2)-th bonding electrode BDE1-2 substantially equally (or similarly). For example, in order to secure reliability of an electrical connection between the (1-2)-th bonding electrode BDE1-2 and the (1-2)-th contact portion CTP1-2, a (1-2)-th bridge electrode (not shown) may be further disposed.

Referring to FIGS. 12 to 16 again, in order to secure reliability of an electrical connection between the (2-1)-th bonding electrode BDE2-1 and the (2-1)-th contact portion CTP2-1, a (2-1)-th bridge electrode BRE2-1 may be further deployed. In order to secure reliability of an electrical connection between the (2-2)-th bonding electrode BDE2-2 and the (2-2)-th contact portion CTP2-2, a (2-2)-th bridge electrode BRE2-2 may be further disposed. Here, the (2-1)-th bridge electrode BRE2-1 and the (2-2)-th bridge electrode BRE2-2 may be described substantially equally (or similarly) to that described with reference to FIGS. 6 to 10. Therefore, an overlapping description is omitted.

As described above with reference to FIGS. 12 to 17, the light emitting element LDa′ of the disclosure may have a relatively small distance between bonding electrodes electrically connected to different semiconductor layers, and thus may have excellent light emission efficiency. Even though a connection defect occurs in the process of disposing the light emitting element LDa′ on the pixel circuit layer PCL, the connection defect described above may be readily repaired using the bridge electrodes BRE1-1, BRE2-1, and BRE2-2 without need to perform a removal process of removing the light emitting element LDa′.

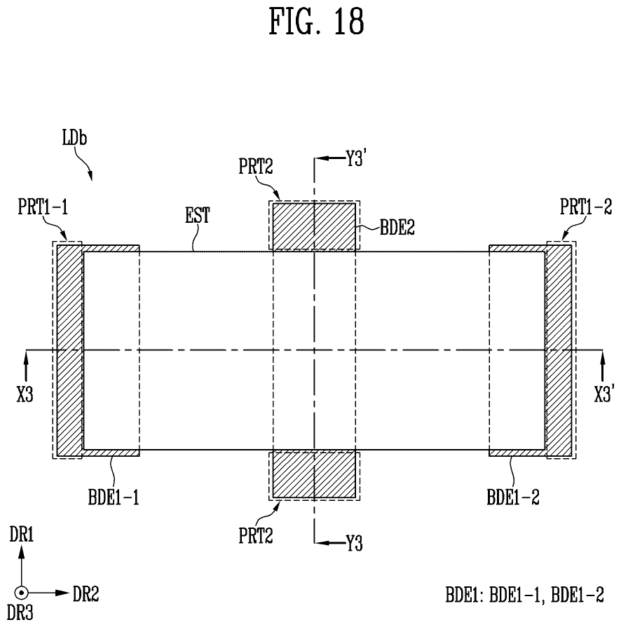

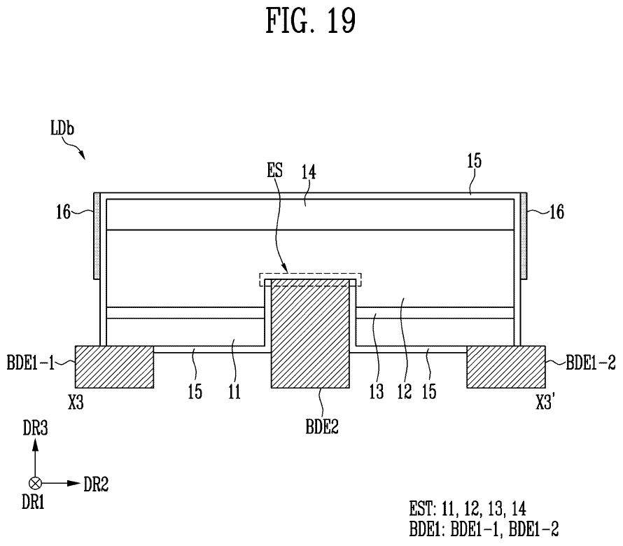

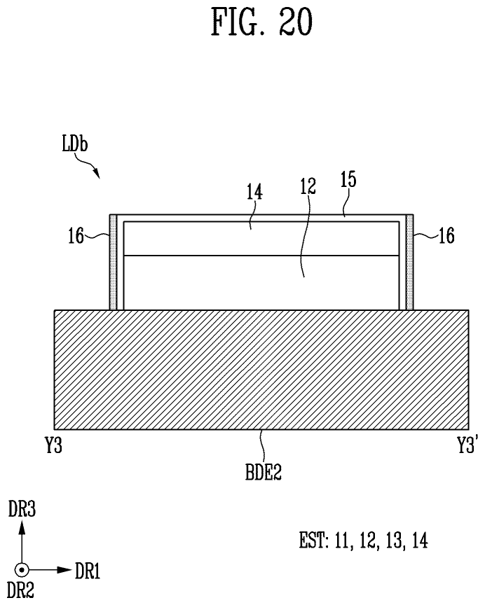

FIGS. 18 to 20 are schematic diagrams illustrating a light emitting element according to a third embodiment of the disclosure. FIG. 18 is a plan view illustrating the light emitting element according to the third embodiment of the disclosure, FIG. 19 is a schematic cross-sectional view taken along line X3-X3′ of FIG. 18, and FIG. 20 is a schematic cross-sectional view taken along line Y3-Y3′ of FIG. 18.

Referring to FIGS. 18 to 20, the light emitting element LDb may include a light emitting stack EST, a first bonding electrode BDE1, and a second bonding electrode BDE2.

The light emitting stack EST may be described substantially equally (or similarly) to that described with reference to FIGS. 6 to 8. The light emitting stack EST may include a first semiconductor layer 11, a second semiconductor layer 12 disposed on the first semiconductor layer 11, and an active layer 13 disposed between the first semiconductor layer 11 and the second semiconductor layer 12. In embodiments, the light emitting stack EST may further include an auxiliary layer 14 disposed on the second semiconductor layer 12. Hereinafter, an overlapping description is omitted.

The first bonding electrode BDE1 may include a (1-1)-th bonding electrode BDE1-1 and a (1-2)-th bonding electrode BDE1-2. The (1-1)-th bonding electrode BDE1-1 may be electrically connected to a lower surface of the first semiconductor layer 11. The (1-2)-th bonding electrode BDE1-2 may be electrically connected to the lower surface of the first semiconductor layer 11. The (1-2)-th bonding electrode BDE1-2 may be spaced apart from the (1-1)-th bonding electrode BDE1-1 in the second direction DR2. For example, the (1-1)-th bonding electrode BDE1-1 may be adjacent to a side surface of the first semiconductor layer 11, and the (1-2)-th bonding electrode BDE1-2 may be adjacent to another side surface opposite to the a side surface of the first semiconductor layer 11 in the second direction DR2. Each of the (1-1)-th bonding electrode BDE1-1 and the (1-2)-th bonding electrode BDE1-2 may not physically contact the second semiconductor layer 12 and the active layer 13. In embodiments, the (1-1)-th bonding electrode BDE1-1 and the (1-2)-th bonding electrode BDE1-2 may include a eutectic metal.

The first bonding electrode BDE1 may be electrically connected to the anode electrode AE of FIG. 2. For example, each of the (1-1)-th bonding electrode BDE1-1 and the (1-2)-th bonding electrode BDE1-2 may be electrically connected to the anode electrode AE, or may be electrically connected to at least one electrode (or conductive layer) contacting the anode electrode AE.

The second bonding electrode BDE2 may be electrically connected to the second semiconductor layer 12. The second bonding electrode BDE2 may not physically contact the first semiconductor layer 11, the active layer 13, the (1-1)-th bonding electrode BDE1-1, and the (1-2)-th bonding electrode BDE1-2. In embodiments, the second bonding electrode BDE2 may include a eutectic metal.

The second bonding electrode BDE2 may be electrically connected to the cathode electrode CE of FIG. 2. For example, the second bonding electrode BDE2 may be electrically connected to the cathode electrode CE, or may be electrically connected to at least one electrode (or conductive layer) contacting the cathode electrode CE.

The second bonding electrode BDE2 may be disposed between the (1-1)-th bonding electrode BDE1-1 and the (1-2)-th bonding electrode BDE1-2. Accordingly, a separation distance between the (1-1)-th bonding electrode BDE1-1 and the second bonding electrode BDE2, and a separation distance between the (1-2)-th bonding electrode BDE1-2 and the second bonding electrode BDE2 may become relatively small. Therefore, light emission efficiency of the light emitting element LDb may be improved.

In an embodiment, on a face surface of the second semiconductor layer 12 facing an outer peripheral surface of the active layer 13, an exposed surface ES that does not overlap the first semiconductor layer 11 and the active layer 13 in a plan view may be defined. For example, the exposed surface ES may be a surface where the second semiconductor layer 12 may be exposed as a portion of the first semiconductor layer 11 and the active layer 13 may be removed. The exposed surface ES may be positioned between the (1-1)-th bonding electrode BDE1-1 and the (1-2)-th bonding electrode BDE1-2 in a plan view. The second bonding electrode BDE2 may be electrically connected to the exposed surface ES.

In an embodiment, the second bonding electrode BDE2 may include a second protrusion PRT2 protruding in at least one of the first direction DR1 and a direction opposite to the first direction DR1 so as to not overlap the light emitting stack EST in a plan view. For example, as shown in FIG. 18, the second bonding electrode BDE2 may include the second protrusion PRT2 protruding in the first direction DR1 and the direction opposite to the first direction DR1 compared to the light emitting stack EST. However, embodiments of the second protrusion PRT2 are not limited to that shown in FIG. 18. For example, the second bonding electrode BDE2 may include a second protrusion protruding only in the first direction DR1 compared to the light emitting stack EST, or may include a second protrusion protruding only in the direction opposite to the first direction DR1 compared to the light emitting stack EST.

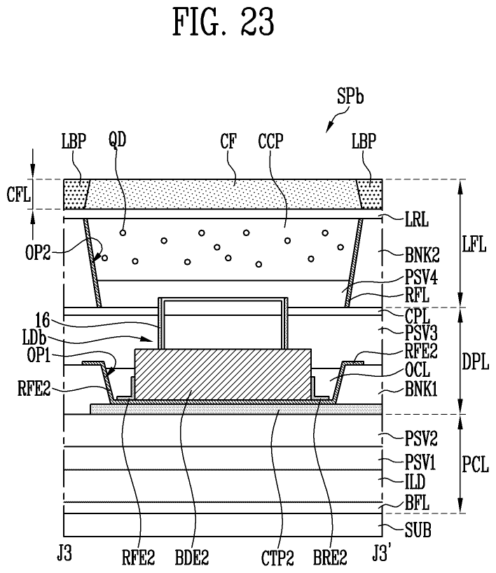

According to embodiments, a connection defect between the second bonding electrode BDE2 and the cathode electrode CE may occur. For example, the second bonding electrode BDE2 and the cathode electrode CE may not be electrically connected to each other due to a foreign material disposed between the second bonding electrode BDE2 and the cathode electrode CE. In the disclosure, the second protrusion PRT2 of the second bonding electrode BDE2 may serve to secure a connection path between the second bonding electrode BDE2 and the cathode electrode CE in case that a connection defect with the cathode electrode CE described above occurs. This is described in detail later with reference to FIG. 23.

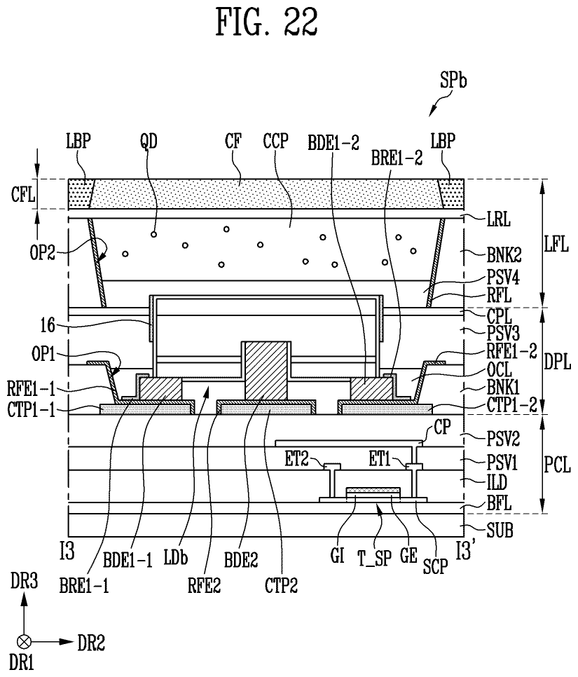

In an embodiment, the (1-1)-th bonding electrode BDE1-1 may include a (1-1)-th protrusion PRT1-1 protruding in a direction opposite to the second direction DR2 so as to not overlap the light emitting stack EST in a plan view. The (1-1)-th protrusion PRT1-1 of the (1-1)-th bonding electrode BDE1-1 may serve to secure a connection path between the (1-1)-th bonding electrode BDE1-1 and the anode electrode AE in case that a connection defect with the anode electrode AE of FIG. 2 occurs. For example, in case that the (1-1)-th bonding electrode BDE1-1 and the anode electrode AE are not electrically connected to each other due to a foreign material disposed between the (1-1)-th bonding electrode BDE1-1 and the anode electrode AE, the connection path between the (1-1)-th bonding electrode BDE1-1 and the anode electrode AE may be secured through the (1-1)-th protrusion PRT1-1. This is described in detail later with reference to FIG. 22.

In an embodiment, the (1-2)-th bonding electrode BDE1-2 may include a (1-2)-th protrusion PRT1-2 protruding in the second direction DR2 so as not to overlap the light emitting stack EST in a plan view. The (1-2)-th protrusion PRT1-2 of the (1-2)-th bonding electrode BDE1-2 may serve to secure a connection path between the (1-2)-th bonding electrode BDE1-2 and the anode electrode AE in case that a connection defect with the anode electrode AE occurs. This is described in detail later with reference to FIG. 22.

In an embodiment, the light emitting element LDb may further include an insulating layer 15 surrounding at least a portion of an outer peripheral surface of the light emitting stack EST. For example, the insulating layer 15 may entirely surround the outer peripheral surface of the light emitting stack EST except for an area where the light emitting stack EST and the first and second bonding electrodes BDE1 and BDE2 may be electrically connected.

The insulating layer 15 may serve to prevent an electrical short circuit that may occur in case that the active layer 13 contacts another conductive material except for the first and second semiconductor layers 11 and 12. The insulating layer 15 may be disposed between the second bonding electrode BDE2 and the first semiconductor layer 11, and between the second bonding electrode BDE2 and the active layer 13, to serve to prevent an electrical short circuit that may occur in case that the second bonding electrode BDE2 contacts the first semiconductor layer 11 and the active layer 13. The insulating layer 15 may include a transparent insulating material. A portion of the first and second bonding electrodes BDE1 and BDE2 may not be covered by the insulating layer 15 and may be exposed.

Even though the light emitting element LDb further includes the insulating layer 15, each of the (1-1)-th protrusion PRT1-1 of the (1-1)-th bonding electrode BDE1-1, the (1-2)-th protrusion PRT1-2 of the (1-2)-th bonding electrode BDE1-2, and the second protrusion PRT2 of the second bonding electrode BDE2 may further protrude compared to the insulating layer 15 in a plan view.

In an embodiment, the light emitting element LDb may further include a reflective layer 16 surrounding at least a portion of a side surface of the light emitting stack EST. For example, the reflective layer 16 may surround a side surface of the auxiliary layer 14 and a portion of a side surface of the second semiconductor layer 12 on the second bonding electrode BDE2.

The reflective layer 16 may serve to improve front surface light emission efficiency of light generated in the active layer 13. For example, the insulating layer 15 may be disposed between the reflective layer 16 and the light emitting stack EST, and the reflective layer 16 may include an insulating material having a refractive index different from that of the insulating layer 15. Accordingly, total reflection of light may be induced at an interface between the reflective layer 16 and the insulating layer 15, and thus the light generated in the active layer 13 may proceed in a front surface direction (for example, the third direction DR3 and a direction intersecting the third direction DR3) of the display panel DP of FIG. 3. As an example, the reflective layer 16 may include a material suitable for reflecting incident light. For example, the reflective layer 16 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them.

In an embodiment, the reflective layer 16 may contact the second bonding electrode BDE2. For example, as shown in FIG. 20, the reflective layer 16 may contact the second protrusion PRT2 of FIG. 18 of the second bonding electrode BDE2. The reflective layer 16 may be configured to include a conductive material.

In the embodiment described above, the reflective layer 16 may be spaced apart from the (1-1)-th bonding electrode BDE1-1 and the (1-2)-th bonding electrode BDE1-2. For example, in case that the reflective layer 16 electrically contacting the second bonding electrode BDE2, the (1-1)-th bonding electrode BDE1-1 and the (1-2)-th bonding electrode BDE1-2 may be spaced apart from the reflective layer 16. Accordingly, an electrical short circuit in which the (1-1)-th bonding electrode BDE1-1 and the (1-2)-th bonding electrode BDE1-2 may be electrically connected through the second bonding electrode BDE2 and the reflective layer 16 may not occur.

Even though the light emitting element LDb further includes the reflective layer 16, each of the (1-1)-th protrusion PRT1-1 of the (1-1)-th bonding electrode BDE1-1, the (1-2)-th protrusion PRT1-2 of the (1-2)-th bonding electrode BDE1-2, and the second protrusion PRT2 of the second bonding electrode BDE2 may further protrude compared to the reflective layer 16 in a plan view.

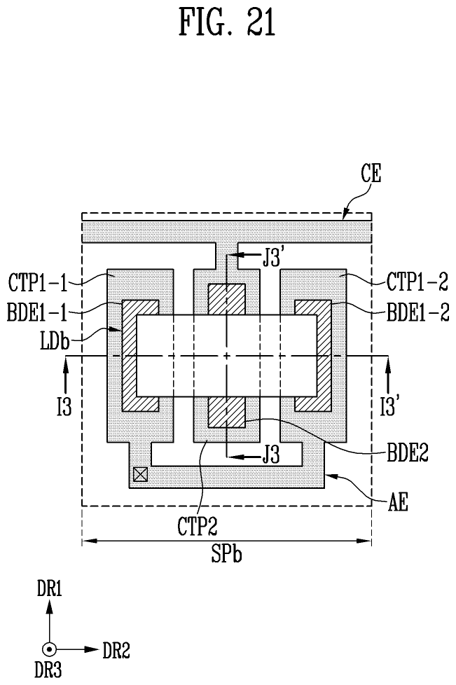

FIGS. 21 to 23 are schematic diagrams illustrating a sub-pixel including the light emitting element according to the third embodiment of the disclosure. FIG. 21 is a plan view illustrating the sub-pixel including the light emitting element according to the third embodiment of the disclosure, FIG. 22 is a schematic cross-sectional view taken along line I3-I3′ of FIG. 21, and FIG. 23 is a schematic cross-sectional view taken along line J3-J3′ of FIG. 21.

Referring to FIG. 21, the sub-pixel SPb may be provided. The sub-pixel SPb may be one sub-pixel among the first to third sub-pixels SP1, SP2, and SP3 described with reference to FIG. 3.

The sub-pixel SPb may include the anode electrode AE and the cathode electrode CE. The anode electrode AE may be electrically connected to the sub-pixel circuit SPC of FIG. 2 of the sub-pixel SPb. The cathode electrode CE may be spaced apart from the anode electrode AE. The cathode electrode CE may be disposed at the same height as the anode electrode AE. The anode electrode AE and the cathode electrode CE may define an electrode layer, and the anode electrode AE and the cathode electrode CE may be implemented as patterns of the electrode layer. In embodiments, the cathode electrode CE may extend in the second direction DR2 and may be used as a common electrode for the pixel PXL and other pixels adjacent to the pixel PXL. The cathode electrode CE may extend in the first direction DR1 in an area which is not shown in FIG. 21, and may be used as a common electrode for all of the sub-pixels SP shown in FIG. 3.

The anode electrode AE may include a (1-1)-th contact portion CTP1-1 and a (1-2)-th contact portion CTP1-2. The (1-1)-th contact portion CTP1-1 and the (1-2)-th contact portion CTP1-2 may be electrically connected to each other. The cathode electrode CE may include a second contact portion CTP2.

The light emitting element LDb described with reference to FIGS. 18 to 20 may be disposed on the anode electrode AE and the cathode electrode CE. The (1-1)-th bonding electrode BDE1-1 of the light emitting element LDb may be disposed on the (1-1)-th contact portion CTP1-1 of the anode electrode AE. The (1-2)-th bonding electrode BDE1-2 of the light emitting element LDb may be disposed on the (1-2)-th contact portion CTP1-2 of the anode electrode AE. The second bonding electrode BDE2 of the light emitting element LDb may be disposed on the second contact portion CTP2 of the cathode electrode CE.

The light emitting element LDb may be electrically connected to the anode electrode AE and the cathode electrode CE. The (1-1)-th bonding electrode BDE1-1 and the (1-2)-th bonding electrode BDE1-2 of the light emitting element LDb may be electrically connected to the anode electrode AE. The second bonding electrode BDE2 of the light emitting element LDb may be electrically connected to the cathode electrode CE.

Referring to FIGS. 21 to 23, the pixel circuit layer PCL, the display element layer DPL, and the light functional layer LFL may be sequentially disposed on the substrate SUB.

The pixel circuit layer PCL may be described substantially equally (or similarly) to that described with reference to FIGS. 9 to 11. Therefore, an overlapping description is omitted.

The display element layer DPL may be disposed on the second passivation layer PSV2. The display element layer DPL may include the anode electrode AE, the cathode electrode CE, the first bank BNK1, a (1-1)-th reflective electrode RFE1-1, a (1-2)-th reflective electrode RFE1-2, a (2-1)-th reflective electrode RFE2-1, a second reflective electrode RFE2, the light emitting element LDb, an overcoat layer OCL, a third passivation layer PSV3, and a capping layer CPL.

The electrode layer including the anode electrode AE and the cathode electrode CE may be disposed on the pixel circuit layer PCL. The anode electrode AE may include a (1-1)-th contact portion CTP1 and a (1-2)-th contact portion CTP1-2, and the cathode electrode CE may include a second contact portion CTP2.

The anode electrode AE may be electrically connected to the connection electrode CP through a contact hole (not shown) passing through the second passivation layer PSV2. As described above, the anode electrode AE may be electrically connected to the transistor T_SP.

The (1-2)-th contact portion CTP1-2 may be spaced apart from the (1-1)-th contact portion CTP1-1 in the second direction DR2. Since the anode electrode AE may be electrically connected to the transistor T_SP, the (1-1)-th contact portion CTP1-1 and the (1-2)-th contact portion CTP1-2 may be electrically connected to the transistor T_SP.

The second contact portion CTP2 may be disposed between the (1-1)-th contact portion CTP1-1 and the (1-2)-th contact portion CTP1-2. The second contact portion CTP2 may be spaced apart from the (1-1)-th contact portion CTP1-1 and the (1-2)-th contact portion CTP1-2. The cathode electrode CE may be electrically connected to the second power voltage node VSSN of FIG. 2. Accordingly, the second power voltage applied to the second power voltage node VSSN may be transmitted to the second contact portion CTP2.

The first bank BNK1 may be disposed on the anode electrode AE and the cathode electrode CE. The first bank BNK1 may have a first opening OP1 exposing portions of the anode electrode AE and the cathode electrode CE. The light emitting element LDb may be disposed in the first opening OP1 of the first bank BNK1. As described above, the first bank BNK1 may be provided as a pixel defining layer that defines an area where the light emitting element LDb may be positioned.

The first bank BNK1 may be configured to include a light blocking material and may serve to prevent light mixing between adjacent sub-pixels. In embodiments, the first bank BNK1 may include an organic material. For example, the first bank BNK1 may include an organic insulating material such as acryl resin, epoxy resin, phenol resin, polyamide resin, and polyimide resin.

The (1-1)-th reflective electrode RFE1-1 may be disposed on an exposed portion of the (1-1)-th contact portion CTP1-1 and a side surface of the first bank BNK1 adjacent thereto. The (1-2)-th reflective electrode RFE1-2 may be disposed on an exposed portion of the (1-2)-th contact portion CTP1-2 and a side surface of the first bank BNK1 adjacent thereto. The second reflective electrode RFE2 may be disposed on an exposed portion of the second contact portion CTP2 and a side surface of the first bank BNK1 adjacent thereto. The (1-1)-th reflective electrode RFE1-1, the (1-2)-th reflective electrode REF1-2, and the second reflective electrode RFE2 may include conductive materials suitable for reflecting light. Accordingly, light emission efficiency of the light emitting element LDb may be improved. In embodiments, the (1-1)-th reflective electrode RFE1-1, the (1-2)-th reflective electrode REF1-2, and the second reflective electrode RFE2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them. However, embodiments are not limited thereto.

The light emitting element LDb may be electrically connected to the (1-1)-th contact portion CTP1-1 of the anode electrode AE through the (1-1)-th reflective electrode RFE1-1. For example, the (1-1)-th bonding electrode BDE1-1 of the light emitting element LDb may be electrically connected to the (1-1)-th reflective electrode RFE1-1, and thus the (1-1)-th bonding electrode BDE1-1 may be electrically connected to the (1-1)-th contact portion CTP1-1 of the anode electrode AE through the (1-1)-th reflective electrode RFE1-1.

The light emitting element LDb may be electrically connected to the (1-2)-th contact portion CTP1-2 of the anode electrode AE through the (1-2)-th reflective electrode RFE1-2. For example, the (1-2)-th bonding electrode BDE1-2 of the light emitting element LDb may be electrically connected to the (1-2)-th reflective electrode RFE1-2, and thus the (1-2)-th bonding electrode BDE1-2 may be electrically connected to the (1-2)-th contact portion CTP1-2 of the anode electrode AE through the (1-2)-th reflective electrode RFE1-2.

The light emitting element LDb may be electrically connected to the second contact portion CTP2 of the cathode electrode CE through the second reflective electrode RFE2. For example, the second bonding electrode BDE2 of the light emitting element LDb may be electrically connected to the second reflective electrode RFE2, and thus the second bonding electrode BDE2 may be electrically connected to the second contact portion CTP2 of the cathode electrode CE through the second reflective electrode RFE2.

The overcoat layer OCL may be disposed in the first opening OP1 where the (1-1)-th reflective electrode RFE1-1, the (1-2)-th reflective electrode REF1-2, the second reflective electrode RFE2, and the light emitting element LDb may be disposed. The overcoat layer OCL may fix the light emitting element LDb so that the light emitting element LDb electrically connected to the (1-1)-th reflective electrode RFE1-1, the (1-2)-th reflective electrode REF1-2, and the second reflective electrode RFE2 does not move. The overcoat layer OCL may protect components disposed under the overcoat layer OCL from a foreign material such as dust and moisture. For example, the overcoat layer OCL may include at least one of an inorganic insulating layer and an organic insulating layer. For example, the overcoat layer OCL may include epoxy, but embodiments are not limited thereto.

The third passivation layer PSV3 may be disposed on the first bank BNK1 and the overcoat layer OCL. The capping layer CPL may be disposed on the third passivation layer PSV3. The third passivation layer PSV3 and the capping layer CPL may be described substantially equally (or similarly) to those described with reference to FIGS. 9 to 11. Therefore, an overlapping description is omitted.

The light functional layer LFL may be disposed on the capping layer CPL. The light functional layer LFL may include a second bank BNK2, a light reflective layer RFL, a fourth passivation layer PSV4, a light functional pattern CCP, a low refractive layer LRL, and a color filter layer CFL. The light functional layer LFL may be described substantially equally (or similarly) to that described with reference to FIGS. 9 to 11. Therefore, an overlapping description is omitted.

Referring to FIGS. 18 to 21 and FIG. 23 again, in order to secure reliability of an electrical connection between the second bonding electrode BDE2 and the second contact portion CTP2, a second bridge electrode BRE2 may be further disposed.

In an embodiment, the second bonding electrode BDE2 may be normally electrically connected to the second reflective electrode RFE2 electrically contacting the second contact portion CTP2. For example, in a process of disposing the light emitting element LDb on the pixel circuit layer PCL, the second bonding electrode BDE2 may be electrically connected to the second contact portion CTP2. The second bridge electrode BRE2 may be omitted.

In an embodiment, the second bonding electrode BDE2 may not be normally electrically connected to the second reflective electrode RFE2 electrically contacting the second contact portion CTP2. For example, in the process of disposing the light emitting element LDb on the pixel circuit layer PCL, the second bonding electrode BDE2 may not be electrically connected to the second contact portion CTP2. In case that a connection defect is sensed through a light emission inspection process or the like subsequent to the above-described process, the second bridge electrode BRE2 for electrically connecting the second bonding electrode BDE2 and the second contact portion CTP2 may be disposed.

The second bridge electrode BRE2 may be disposed along a side surface of the second protrusion PRT2 of the second bonding electrode BDE2. The second bridge electrode BRE2 may extend from the side surface of the second protrusion PRT2 and may contact the second reflective electrode RFE2 electrically contacting the second contact portion CTP2. Accordingly, the second bonding electrode BDE2 may be electrically connected to the second contact portion CTP2 through the second bridge electrode BRE2.

In embodiments, the planar area of the second contact portion CTP2 may be sufficiently larger than the planar area of the second bonding electrode BDE2, and the planar area of the second bonding electrode BDE2 may completely overlap a portion of the second contact portion CTP2 in a plan view. Accordingly, a space in which the second bridge electrode BRE2 may be disposed may be sufficiently secured.

Referring to FIGS. 18 to 22 again, in order to secure reliability of an electrical connection between the (1-1)-th bonding electrode BDE1-1 and the (1-1)-th contact portion CTP1-1, a (1-1)-th bridge electrode BRE1-1 may be further disposed.

In an embodiment, the (1-1)-th bonding electrode BDE1-1 may be normally electrically connected to the (1-1)-th reflective electrode RFE1-1 electrically contacting the (1-1)-th contact portion CTP1-1. For example, in a process of disposing the light emitting element LDb on the pixel circuit layer PCL, the (1-1)-th bonding electrode BDE1-1 may be electrically connected to the (1-1)-th contact portion CTP1-1. The (1-1)-th bridge electrode BRE1-1 may be omitted.

In an embodiment, the (1-1)-th bonding electrode BDE1-1 may not be normally electrically connected to the (1-1)-th reflective electrode RFE1-1 electrically contacting the (1-1)-th contact portion CTP1-1. For example, in the process of disposing the light emitting element LDb on the pixel circuit layer PCL, the (1-1)-th bonding electrode BDE1-1 may not be electrically connected to the (1-1)-th contact portion CTP1-1. In case that a connection defect is sensed through a light emission inspection process or the like subsequent to the above-described process, the (1-1)-th bridge electrode BRE1-1 for electrically connecting the (1-1)-th bonding electrode BDE1-1 and the (1-1)-th contact portion CTP1-1 may be disposed.

The (1-1)-th bridge electrode BRE1-1 may be disposed along an outer peripheral surface of the (1-1)-th protrusion PRT1-1 of the (1-1)-th bonding electrode BDE1-1. The (1-1)-th bridge electrode BRE1-1 may extend from the outer peripheral surface of the (1-1)-th protrusion PRT1-1 and may contact the (1-1)-th reflective electrode RFE1-1 electrically contacting the (1-1)-th contact portion CTP1-1. Accordingly, the (1-1)-th bonding electrode BDE1-1 may be electrically connected to the (1-1)-th contact portion CTP1-1 through the (1-1)-th bridge electrode BRE1-1.

In embodiments, the planar area of the (1-1)-th contact portion CTP1-1 may be sufficiently larger than the planar area of the (1-1)-th bonding electrode BDE1-1, and the (1-1)-th bonding electrode BDE1-1 may completely overlap a portion of the (1-1)-th contact portion CTP1-1 in a plan view. Accordingly, a space in which the (1-1)-th bridge electrode BRE1-1 may be disposed may be sufficiently secured.

Referring to FIGS. 18 to 22 again, in order to secure reliability of an electrical connection between the (1-2)-th bonding electrode BDE1-2 and the (1-2)-th contact portion CTP1-2, a (1-2)-th bridge electrode BRE1-2 may be further disposed.

In an embodiment, the (1-2)-th bonding electrode BDE1-2 may be normally electrically connected to the (1-2)-th reflective electrode RFE1-2 electrically contacting the (1-2)-th contact portion CTP1-2. For example, in the process of disposing the light emitting element LDb on the pixel circuit layer PCL, the (1-2)-th bonding electrode BDE1-2 may be electrically connected to the (1-2)-th contact portion CTP1-2. The (1-2)-th bridge electrode BRE1-2 may be omitted.

In an embodiment, the (1-2)-th bonding electrode BDE1-2 may not be normally electrically connected to the (1-2)-th reflective electrode RFE1-2 electrically contacting the (1-2)-th contact portion CTP1-2. For example, in the process of disposing the light emitting element LDb on the pixel circuit layer PCL, the (1-2)-th bonding electrode BDE1-2 may not be electrically connected to the (1-2)-th contact portion CTP1-2. In case that a connection defect is sensed through a light emission inspection process or the like subsequent to the above-described process, the (1-2)-th bridge electrode BRE1-2 for electrically connecting the (1-2)-th bonding electrode BDE1-2 and the (1-2)-th contact portion CTP1-2 may be disposed.

The (1-2)-th bridge electrode BRE1-2 may be disposed along an outer peripheral surface of the (1-2)-th protrusion PRT1-2 of the (1-2)-th bonding electrode BDE1-2. The (1-2)-th bridge electrode BRE1-2 may extend from the outer peripheral surface of the (1-2)-th protrusion PRT1-2 and may contact the (1-2)-th reflective electrode RFE1-2 electrically contacting the (1-2)-th contact portion CTP1-2. Accordingly, the (1-2)-th bonding electrode BDE1-2 may be electrically connected to the (1-2)-th contact portion CTP1-2 through the (1-2)-th bridge electrode BRE1-2.

In embodiments, the planar area of the (1-2)-th contact portion CTP1-2 may be sufficiently larger than the planar area of the (1-2)-th bonding electrode BDE1-2, and the (1-2)-th bonding electrode BDE1-2 may completely overlap a portion of the (1-2)-th contact portion CTP1-2 in a plan view. Accordingly, a space in which the (1-2)-th bridge electrode BRE1-2 may be disposed may be sufficiently secured.

As described above with reference to FIGS. 18 to 23, the light emitting element LDb of the disclosure may have a relatively small distance between bonding electrodes electrically connected to different semiconductor layers, and thus may have excellent light emission efficiency. Even though a connection defect occurs in the process of disposing the light emitting element LDb on the pixel circuit layer PCL, the connection defect described above may be readily repaired using the bridge electrodes BRE1-1, BRE1-2, and BRE2 without need to perform a removal process of removing the light emitting element LDb.

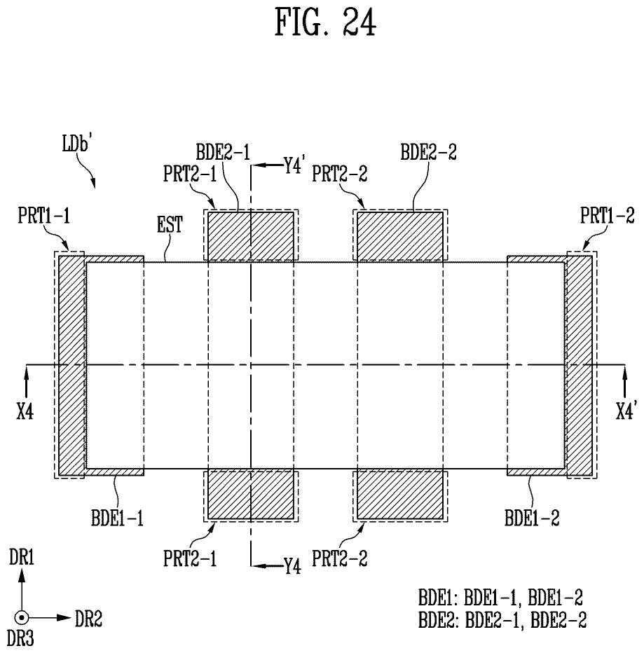

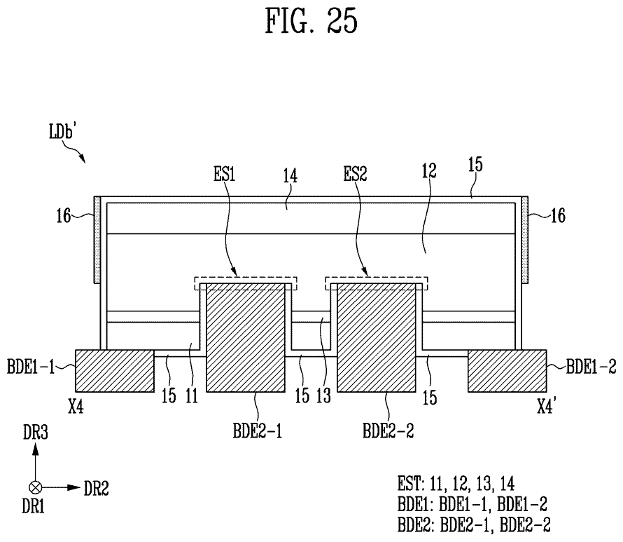

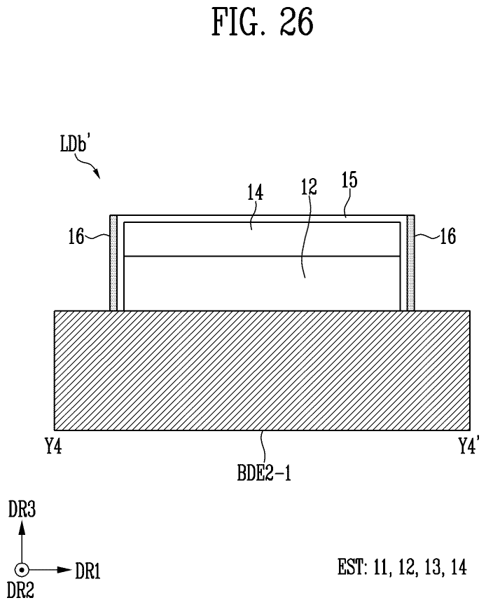

FIGS. 24 to 26 are schematic diagrams illustrating a light emitting element according to a fourth embodiment of the disclosure. FIG. 24 is a plan view illustrating the light emitting element according to the fourth embodiment of the disclosure, FIG. 25 is a schematic cross-sectional view taken along line X4-X4′ of FIG. 24, and FIG. 26 is a schematic cross-sectional view taken along line Y4-Y4′ of FIG. 24.

Referring to FIGS. 24 to 26, the light emitting element LDb′ may include a light emitting stack EST, a first bonding electrode BDE1, and a second bonding electrode BDE2.

The light emitting stack EST may be described substantially equally (or similarly) to that described with reference to FIGS. 6 to 8. The light emitting stack EST may include a first semiconductor layer 11, a second semiconductor layer 12 disposed on the first semiconductor layer 11, and an active layer 13 disposed between the first semiconductor layer 11 and the second semiconductor layer 12. In embodiments, the light emitting stack EST may further include an auxiliary layer 14 disposed on the second semiconductor layer 12. Hereinafter, an overlapping description is omitted.

The first bonding electrode BDE1 may be described substantially equally (or similarly) to that described with reference to FIGS. 18 to 20. The first bonding electrode BDE1 may include a (1-1)-th bonding electrode BDE1-1 and a (1-2)-th bonding electrode BDE1-2. The (1-1)-th bonding electrode BDE1-1 may be electrically connected to a lower surface of the first semiconductor layer 11. The (1-2)-th bonding electrode BDE1-2 may be electrically connected to the lower surface of the first semiconductor layer 11. The (1-2)-th bonding electrode BDE1-2 may be spaced apart from the (1-1)-th bonding electrode BDE1-1 in the second direction DR2. The (1-1)-th bonding electrode BDE1-1 and the (1-2)-th bonding electrode BDE1-2 may be electrically connected to the anode electrode AE of FIG. 2. Each of the (1-1)-th bonding electrode BDE1-1 and the (1-2)-th bonding electrode BDE1-2 may not physically with the second semiconductor layer 12 and the active layer 13. In embodiments, the (1-1)-th bonding electrode BDE1-1 and the (1-2)-th bonding electrode BDE1-2 may include a eutectic metal. Hereinafter, an overlapping description is omitted.

The second bonding electrode BDE2 may include a (2-1)-th bonding electrode BDE2-1 and a (2-2)-th bonding electrode BDE2-2. The (2-1)-th bonding electrode BDE2-1 may be electrically connected to the second semiconductor layer 12. The (2-2)-th bonding electrode BDE2-2 may be electrically connected to the second semiconductor layer 12. The (2-2)-th bonding electrode BDE2-2 may be spaced apart from the (2-1)-th bonding electrode BDE2-1 in the second direction DR2. Each of the (2-1)-th bonding electrode BDE2-1 and the (2-2)-th bonding electrode BDE2 may not physically contact the first semiconductor layer 11, the active layer 13, and the first bonding electrode BDE1. In embodiments, the (2-1)-th bonding electrode BDE2-1 and the (2-2)-th bonding electrode BDE2-2 may include a eutectic metal.

The second bonding electrode BDE2 may be electrically connected to the cathode electrode CE of FIG. 2. For example, each of the (2-1)-th bonding electrode BDE2-1 and the (2-2)-th bonding electrode BDE2-2 may be electrically connected to the cathode electrode CE, or may be electrically connected to at least one electrode (or conductive layer) contacting the cathode electrode CE.

The (2-1)-th bonding electrode BDE2-1 and the (2-2)-th bonding electrode BDE2-2 may be disposed between the (1-1)-th bonding electrode BDE1-1 and the (1-2)-th bonding electrode BDE1-2. Accordingly, a separation distance between the (1-1)-th bonding electrode BDE1-1 and the (2-1)-th bonding electrode BDE2-1, and a separation distance between the (1-2)-th bonding electrode BDE1-2 and the (2-2)-th bonding electrode BDE2-2 may become relatively small. Therefore, a current distribution in the light emitting element LDb′ may become more uniform, and thus light emission efficiency of the light emitting element LDb′ may be improved.

In an embodiment, a first exposed surface ES1 and a second exposed surface ES2 that do not overlap the first semiconductor layer 11 and the active layer 13 in a plan view may be defined on a face surface of the semiconductor layer 12 facing an outer peripheral surface of the active layer 13. For example, the first exposed surface ES1 and the second exposed surface ES2 may be surfaces where the second semiconductor layer 12 may be exposed as a portion of the first semiconductor layer 11 and the active layer 13 may be removed. The first exposed surface ES1 and the second exposed surface ES2 may be disposed between the (1-1)-th bonding electrode BDE1-1 and the (1-2)-th bonding electrode BDE1-2 in a plan view. The (2-1)-th bonding electrode BDE2-1 may be electrically connected to the first exposed surface ES1, and the (2-2)-th bonding electrode BDE2-2 may be electrically connected to the second exposed surface ES2.

In an embodiment, the (2-1)-th and (2-2)-th bonding electrodes BDE2-1 and BDE2-2 may include (2-1)-th and (2-2)-th protrusion electrodes, respectively protruding in at least one of the first direction DR1 and a direction opposite to the first direction DR1 so as to not overlap the light emitting stack EST in a plan view. For example, each of the (2-1)-th bonding electrode BDE2-1 and the (2-2)-th bonding electrode BDE2-2 may independently include (2-1)-th protrusion PRT2-1 and (2-2)-th protrusion PRT2-2, respectively protruding in at least one of the first direction DR1 and the direction opposite to the first direction DR1 so as to not overlap the light emitting stack EST in a plan view.

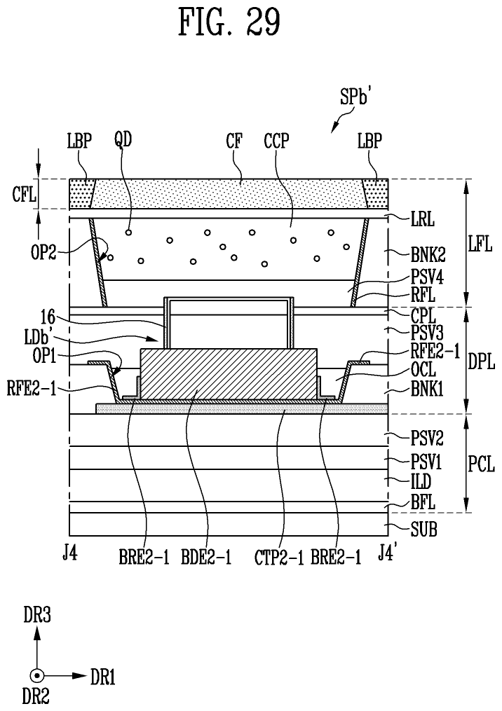

The (2-1)-th protrusion PRT2-1 and (2-2)-th protrusion PRT2-2 of the (2-1)-th and (2-2)-th bonding electrodes BDE2-1 and BDE2-2, respectively may serve to secure a connection path between each of the (2-1)-th and the (2-2)-th bonding electrodes BDE2-1 and BDE2-2 and the cathode electrode CE in case that a connection defect with the cathode electrode CE occurs. This is described in detail later with reference to FIG. 29.

In an embodiment, the light emitting element LDb′ may further include an insulating layer 15 surrounding at least a portion of an outer peripheral surface of the light emitting stack EST. The insulating layer 15 may be described substantially equally (or similarly) to that described with reference to FIGS. 18 to 20. For example, the insulating layer 15 may entirely surround the outer peripheral surface of the light emitting stack EST except for an area where the light emitting stack EST and the first and second bonding electrodes BDE1 and BDE2 may be electrically connected. The insulating layer 15 may be disposed between the (2-1)-th bonding electrode BDE2-1 and the active layer 13, between the (2-1)-th bonding electrode BDE2-1 and the first semiconductor layer 11, between the (2-2)-th bonding electrode BDE2-1 and the active layer 13, and between the (2-2)-th bonding electrode BDE2-2 and the first semiconductor layer 11. Hereinafter, an overlapping description is omitted.

In an embodiment, the light emitting element LDb′ may further include a reflective layer 16 surrounding at least a portion of a side surface of the light emitting stack EST. For example, the reflective layer 16 may surround a side surface of the auxiliary layer 14 and a portion of a side surface of the second semiconductor layer 12 on the second bonding electrode BDE2.

The reflective layer 16 may serve to improve front surface light emission efficiency of light generated in the active layer 13. For example, the insulating layer 15 may be disposed between the reflective layer 16 and the light emitting stack EST, and the reflective layer 16 may include an insulating material having a refractive index different from that of the insulating layer 15. Accordingly, total reflection of light may be induced at an interface between the reflective layer 16 and the insulating layer 15, and thus the light generated in the active layer 13 may proceed in a front surface direction (for example, the third direction DR3 and a direction intersecting the third direction DR3) of the display panel DP of FIG. 3. As an example, the reflective layer 16 may include a material suitable for reflecting incident light. For example, the reflective layer 16 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them.

In an embodiment, the reflective layer 16 may contact each of the (2-1)-th bonding electrode BDE2-1 and the (2-2)-th bonding electrode BDE2-2. For example, the reflective layer 16 may contact each of the second protrusion PRT2 of the (2-1)-th bonding electrode BDE2-1 and the second protrusion PRT2-2 of FIG. 6 of the (2-2)-th bonding electrode BDE2-2. The reflective layer 16 may be configured to include a conductive material. Accordingly, the (2-1)-th bonding electrode BDE2-1 and the (2-2)-th bonding electrode BDE2-2 may be electrically connected to each other by the reflective layer 16. Accordingly, even though a connection defect occurs between one of the (2-1)-th bonding electrode BDE2-1 and the (2-2)-th bonding electrode BDE2-2 and the cathode electrode CE, in case that one of the (2-1)-th bonding electrode BDE2-1 and the (2-2)-th bonding electrode BDE2-2 is normally electrically connected to the cathode electrode CE, both of the (2-1)-th bonding electrode BDE2-1 and the (2-2)-th bonding electrode BDE2-2 may be electrically connected to the cathode electrode CE through the reflective layer 16. For example, the reflective layer 16 may further serve to secure reliability of the (2-1)-th bonding electrode BDE2-1 and the (2-2)-th bonding electrode BDE2-2.

In the embodiment described above, the reflective layer 16 may be spaced apart from the first bonding electrode BDE1. For example, in case that the reflective layer 16 electrically connects the (2-1)-th bonding electrode BDE2-1 and the (2-2)-th bonding electrode BDE2-2 to each other, the first bonding electrode BDE1 may be spaced apart from the reflective layer 16. Accordingly, an electrical short circuit that the first bonding electrode BDE1 may be electrically connected to the (2-1)-th bonding electrode BDE2-1 and the (2-2)-th bonding electrode BDE2-2 through the reflective layer 16 may not occur.

Even though the light emitting element LDb′ further includes the reflective layer 16, each of the (1-1)-th protrusion PRT1-1 of the (1-1)-th bonding electrode BDE1-1, the (1-2)-th protrusion PRT1-2 of the (1-2)-th bonding electrode BDE1-2, the (2-1)-th protrusion PRT2-1 of the (2-1)-th bonding electrode BDE2-1 and the (2-2)-th protrusion PRT2-2 of the (2-2)-th bonding electrode BDE2-2 may further protrude compared to the reflective layer 16 in a plan view.

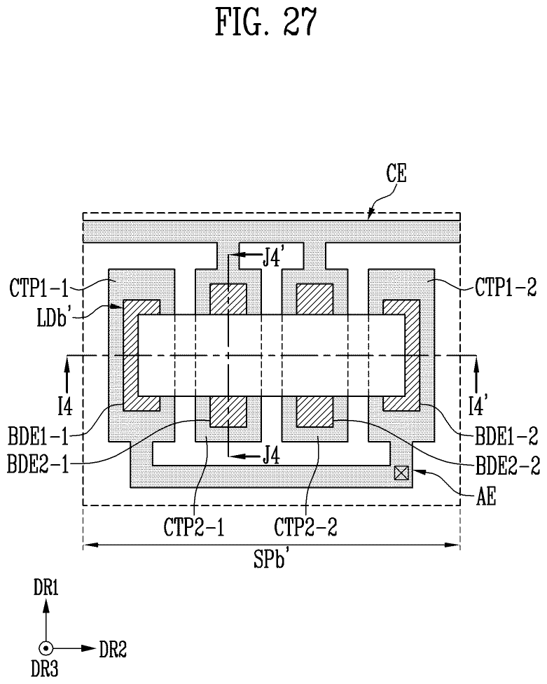

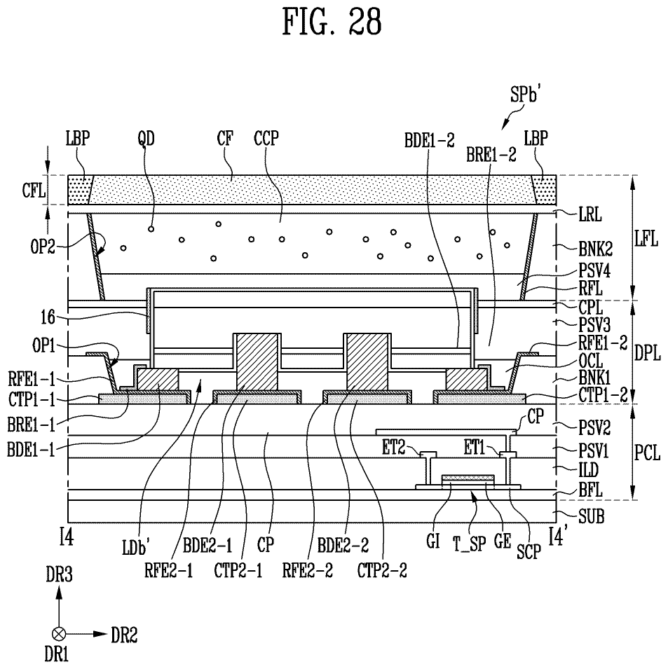

FIGS. 27 to 29 are schematic diagrams illustrating a sub-pixel including the light emitting element according to the fourth embodiment of the disclosure. FIG. 27 is a plan view illustrating the sub-pixel including the light emitting element according to the fourth embodiment of the disclosure, FIG. 28 is a schematic cross-sectional view taken along line I4-I4′ of FIG. 27, and FIG. 29 is a schematic cross-sectional view taken along line J4-J4′ of FIG. 27.

Referring to FIG. 27, the sub-pixel SPb′ may be provided. The sub-pixel SPb′ may be one sub-pixel among the first to third sub-pixels SP1, SP2, and SP3 described with reference to FIG. 3.

The sub-pixel SPb′ may include the anode electrode AE and the cathode electrode CE. The anode electrode AE may be electrically connected to the sub-pixel circuit SPC of FIG. 2 of the sub-pixel SPb′. The cathode electrode CE may be spaced apart from the anode electrode AE. The cathode electrode CE may be disposed at the same height as the anode electrode AE. The anode electrode AE and the cathode electrode CE may define an electrode layer, and the anode electrode AE and the cathode electrode CE may be implemented as patterns of the electrode layer. In embodiments, the cathode electrode CE may extend in the second direction DR2 and may be used as a common electrode for the pixel PXL and other pixels adjacent to the pixel PXL. The cathode electrode CE may extend in the first direction DR1 in an area which is not shown in FIG. 27, and may be used as a common electrode for all of the sub-pixels SP shown in FIG. 3.

The anode electrode AE may include a (1-1)-th contact portion CTP1-1 and a (1-2)-th contact portion CTP1-2. The (1-1)-th contact portion CTP1-1 and the (1-2)-th contact portion CTP1-2 may be electrically connected to each other. The cathode electrode CE may include a (2-1)-th contact portion CTP2-1 and a (2-2)-th contact portion CTP2-2. The (2-1)-th contact portion CTP2-1 and the (2-2)-th contact portion CTP2-2 may be electrically connected to each other.

The light emitting element LDb′ described with reference to FIGS. 24 to 26 may be disposed on the anode electrode AE and the cathode electrode CE. The (1-1)-th bonding electrode BDE1-1 of the light emitting element LDb′ may be disposed on the (1-1)-th contact portion CTP1-1 of the anode electrode AE. The (1-2)-th bonding electrode BDE1-2 of the light emitting element LDb′ may be disposed on the (1-2)-th contact portion CTP1-2 of the anode electrode AE. The (2-1)-th bonding electrode BDE2-1 of the light emitting element LDb′ may be disposed on the (2-1)-th contact portion CTP2-1 of the cathode electrode CE. The (2-2)-th bonding electrode BDE2-2 of the light emitting element LDb′ may be disposed on the (2-2)-th contact portion CTP2-2 of the cathode electrode CE.

The light emitting element LDb′ may be electrically connected to the anode electrode AE and the cathode electrode CE. The (1-1)-th bonding electrode BDE1-1 and the (1-2)-th bonding electrode BDE1-2 of the light emitting element LDb′ may be electrically connected to the anode electrode AE. The (2-1)-th bonding electrode BDE2-1 and the (2-2)-th bonding electrode BDE2-2 of the light emitting element LDb′ may be electrically connected to the cathode electrode CE.

Referring to FIGS. 27 to 29, the pixel circuit layer PCL, the display element layer DPL, and the light functional layer LFL may be sequentially disposed on the substrate SUB.

The pixel circuit layer PCL may be described substantially equally (or similarly) to that described with reference to FIGS. 9 to 11. Therefore, an overlapping description is omitted.

The display element layer DPL may be disposed on the second passivation layer PSV2. The display element layer DPL may include the anode electrode AE, the cathode electrode CE, the first bank BNK1, a (1-1)-th reflective electrode RFE1-1, a (1-2)-th reflective electrode RFE1-2, a (2-1)-th reflective electrode RFE2-1, a (2-2)-th reflective electrode RFE2-2, the light emitting element LDb′, an overcoat layer OCL, a third passivation layer PSV3, and a capping layer CPL.

The electrode layer including the anode electrode AE and the cathode electrode CE may be disposed on the pixel circuit layer PCL. The anode electrode AE may include a (1-1)-th contact portion CTP1 and a (1-2)-th contact portion CTP1-2, and the cathode electrode CE may include a (2-1)-th contact portion CTP2-1 and a (2-2)-th contact portion CTP2-2.

The anode electrode AE may be electrically connected to the connection electrode CP through a contact hole (not shown) passing through the second passivation layer PSV2. As described above, the anode electrode AE may be electrically connected to the transistor T_SP.

The (1-2)-th contact portion CTP1-2 may be spaced apart from the (1-1)-th contact portion CTP1-1 in the second direction DR2. Since the anode electrode AE may be electrically connected to the transistor T_SP, the (1-1)-th contact portion CTP1-1 and the (1-2)-th contact portion CTP1-2 may be electrically connected to the transistor T_SP.

The (2-1)-th contact portion CTP2-1 and the (2-2)-th contact portion CTP2-2 may be disposed between the (1-1)-th contact portion CTP1-1 and the (1-2)-th contact portion CTP1-2. The (2-1)-th contact portion CTP2-1 may be spaced apart from the (1-1)-th contact portion CTP1-1 in the second direction DR2. The (2-2)-th contact portion CTP2-2 may be spaced apart from the (1-2)-th contact portion CTP1-2 in the direction opposite to the second direction DR2. The cathode electrode CE may be electrically connected to the second power voltage node VSSN of FIG. 2. Accordingly, the second power voltage applied to the second power voltage node VSSN may be transmitted to the (2-1)-th contact portion CTP2-1 and the (2-2)-th contact portion CTP2-2.

The first bank BNK1 may be disposed on the anode electrode AE and the cathode electrode CE. The first bank BNK1 may have a first opening OP1 exposing portions of the anode electrode AE and the cathode electrode CE. The light emitting element LDb′ may be disposed in the first opening OP1 of the first bank BNK1. As described above, the first bank BNK1 may be provided as a pixel defining layer that defines an area where the light emitting element LDb′ may be positioned.

The first bank BNK1 may be configured to include a light blocking material and may serve to prevent light mixing between adjacent sub-pixels. In embodiments, the first bank BNK1 may include an organic material. For example, the first bank BNK1 may include an organic insulating material such as acryl resin, epoxy resin, phenol resin, polyamide resin, and polyimide resin.

The (1-1)-th reflective electrode RFE1-1 may be disposed on an exposed portion of the (1-1)-th contact portion CTP1-1 and a side surface of the first bank BNK1 adjacent thereto. The (1-2)-th reflective electrode RFE1-2 may be disposed on an exposed portion of the (1-2)-th contact portion CTP1-2 and a side surface of the first bank BNK1 adjacent thereto. The (2-1)-th reflective electrode RFE2-1 may be disposed on an exposed portion of the (2-1)-th contact portion CTP2-1 and a side surface of the first bank BNK1 adjacent thereto. The (2-2)-th reflective electrode RFE2-2 may be disposed on an exposed portion of the (2-2)-th contact portion CTP2-2 and a side surface of the first bank BNK1 adjacent thereto. The (1-1)-th reflective electrode RFE1-1, the (1-2)-th reflective electrode REF1-2, the (2-1)-th reflective electrode RFE2-1, and the (2-2)-th reflective electrode RFE2-2 may include conductive materials suitable for reflecting light. Accordingly, light emission efficiency of the light emitting element LDb′ may be improved. In embodiments, the (1-1)-th reflective electrode RFE1-1, the (1-2)-th reflective electrode REF1-2, the (2-1)-th reflective electrode RFE2-1, and the (2-2)-th reflective electrode RFE2-2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them. However, embodiments are not limited thereto.

The light emitting element LDb′ may be electrically connected to the (1-1)-th contact portion CTP1-1 of the anode electrode AE through the (1-1)-th reflective electrode RFE1-1. For example, the (1-1)-th bonding electrode BDE1-1 of the light emitting element LDb′ may be electrically connected to the (1-1)-th reflective electrode RFE1-1, and thus the (1-1)-th bonding electrode BDE1-1 may be electrically connected to the (1-1)-th contact portion CTP1-1 of the anode electrode AE through the (1-1)-th reflective electrode RFE1-1.

The light emitting element LDb′ may be electrically connected to the (1-2)-th contact portion CTP1-2 of the anode electrode AE through the (1-2)-th reflective electrode RFE1-2. For example, the (1-2)-th bonding electrode BDE1-2 of the light emitting element LDb′ may be electrically connected to the (1-2)-th reflective electrode RFE1-2, and thus the (1-2)-th bonding electrode BDE1-2 may be electrically connected to the (1-2)-th contact portion CTP1-2 of the anode electrode AE through the (1-2)-th reflective electrode RFE1-2.

The light emitting element LDb′ may be electrically connected to the (2-1)-th contact portion CTP2-1 of the cathode electrode CE through the (2-1)-th reflective electrode RFE2-1. For example, the (2-1)-th bonding electrode BDE2-1 of the light emitting element LDb′ may be electrically connected to the (2-1)-th reflective electrode RFE2-1, and thus the (2-1)-th bonding electrode BDE2-1 may be electrically connected to the (2-1)-th contact portion CTP2-1 of the cathode electrode CE through the (2-1)-th reflective electrode RFE2-1.

The light emitting element LDb′ may be electrically connected to the (2-2)-th contact portion CTP2-2 of the cathode electrode CE through the (2-2)-th reflective electrode RFE2-2. For example, the (2-2)-th bonding electrode BDE2-2 of the light emitting element LDb′ may be electrically connected to the (2-2)-th reflective electrode RFE2-2, and thus the (2-2)-th bonding electrode BDE2-2 may be electrically connected to the (2-2)-th contact portion CTP2-2 of the cathode electrode CE through the (2-2)-th reflective electrode RFE2-2.

The overcoat layer OCL may be disposed in the first opening OP1 where the (1-1)-th reflective electrode RFE1-1, the (1-2)-th reflective electrode REF1-2, the (2-1)-th reflective electrode RFE2-1, the (2-2)-th reflective electrode RFE2-2, and the light emitting element LDb′ may be disposed. The overcoat layer OCL may fix the light emitting element LDb′ so that the light emitting element LDb′ electrically connected to the (1-1)-th reflective electrode RFE1-1, the (1-2)-th reflective electrode REF1-2, the (2-1)-th reflective electrode RFE2-1, and the (2-2)-th reflective electrode RFE2-2 does not move. The overcoat layer OCL may protect components disposed under the overcoat layer OCL from a foreign material such as dust and moisture. For example, the overcoat layer OCL may include at least one of an inorganic insulating layer and an organic insulating layer. For example, the overcoat layer OCL may include epoxy, but embodiments are not limited thereto.

The third passivation layer PSV3 may be disposed on the first bank BNK1 and the overcoat layer OCL. The capping layer CPL may be disposed on the third passivation layer PSV3. The third passivation layer PSV3 and the capping layer CPL may be described substantially equally (or similarly) to those described with reference to FIGS. 9 to 11. Therefore, an overlapping description is omitted.

The light functional layer LFL may be disposed on the capping layer CPL. The light functional layer LFL may include a second bank BNK2, a light reflective layer RFL, a fourth passivation layer PSV4, a light functional pattern CCP, a low refractive layer LRL, and a color filter layer CFL. The light functional layer LFL may be described substantially equally (or similarly) to that described with reference to FIGS. 9 to 11. Therefore, an overlapping description is omitted.

Referring to FIGS. 24 to 27 and 29 again, in order to secure reliability of an electrical connection between the (2-1)-th bonding electrode BDE2-1 and the (2-1)-th contact portion CTP2-1, a (2-1)-th bridge electrode BRE2-1 may be further disposed.

In an embodiment, the (2-1)-th bonding electrode BDE2-1 may be normally electrically connected to the (2-1)-th reflective electrode RFE2-1 electrically contacting the (2-1)-th contact portion CTP2-1. For example, in the process of disposing the light emitting element LDb′ on the pixel circuit layer PCL, the (2-1)-th bonding electrode BDE2-1 may be electrically connected to the (2-1)-th contact portion CTP2-1. The (2-1)-th bridge electrode BRE2-1 may be omitted.

In an embodiment, the (2-1)-th bonding electrode BDE2-1 may not be normally electrically connected to the (2-1)-th reflective electrode RFE2-1 electrically contacting the (2-1)-th contact portion CTP2-1. For example, in the process of disposing the light emitting element LDb′ on the pixel circuit layer PCL, the (2-1)-th bonding electrode BDE2-1 may not be electrically connected to the (2-1)-th contact portion CTP2-1. In case that a connection defect is sensed through a light emission inspection process or the like subsequent to the above-described process, the (2-1)-th bridge electrode BRE2-1 for electrically connecting the (2-1)-th bonding electrode BDE2-1 and the (2-1)-th contact portion CTP2-1 may be disposed.

The (2-1)-th bridge electrode BRE2-1 may be disposed along a side surface of the second protrusion PRT2 of the (2-1)-th bonding electrode BDE2-1. The (2-1)-th bridge electrode BRE2-1 may extend from the side surface of the second protrusion PRT2 and may contact the (2-1)-th reflective electrode RFE2-1 electrically contacting the (2-1)-th contact portion CTP2-1. Accordingly, the (2-1)-th bonding electrode BDE2 may be electrically connected to the (2-1)-th contact portion CTP2-1 through the (2-1)-th bridge electrode BRE2-1.

In embodiments, the planar area of the (2-1)-th contact portion CTP2-1 may be sufficiently larger than the planar area of the (2-1)-th bonding electrode BDE2-1, and the (2-1)-th bonding electrode BDE2-1 may completely overlap a portion of the (2-1)-th contact portion CTP2-1 in a plan view. Accordingly, a space in which the (2-1)-th bridge electrode BRE2-1 may be disposed may be sufficiently secured.

In FIG. 29, the (2-1)-th bonding electrode BDE2-1, the (2-1)-th bridge electrode BRE2-1, and the like are shown, but the content described above may also be applied to the (2-2)-th bonding electrode BDE2-2 substantially equally (or similarly). For example, in order to secure reliability of an electrical connection between the (2-2)-th bonding electrode BDE2-2 and the (2-2)-th contact portion CTP2-2, a (2-2)-th bridge electrode (not shown) may be further disposed.

Referring to FIGS. 24 to 28 again, in order to secure reliability of an electrical connection between the (1-1)-th bonding electrode BDE1-1 and the (1-1)-th contact portion CTP1-1, a (1-1)-th bridge electrode BRE1-1 may be further disposed. In order to secure reliability of an electrical connection between the (1-2)-th bonding electrode BDE1-2 and the (1-2)-th contact portion CTP1-2, a (1-2)-th bridge electrode BRE1-2 may be further disposed. Here, the (1-1)-th bridge electrode BRE1-1 and the (1-2)-th bridge electrode BRE1-2 may be described substantially equally (or similarly) to that described with reference to FIGS. 19 to 22. Therefore, an overlapping description is omitted.

As described above with reference to FIGS. 25 to 29, the light emitting element LDb′ of the disclosure may have a relatively small distance between bonding electrodes electrically connected to different semiconductor layers, and thus may have excellent light emission efficiency. Even though a connection defect occurs in the process of disposing the light emitting element LDb′ on the pixel circuit layer PCL, the connection defect described above may be readily repaired using the bridge electrodes BRE1-1, BRE1-2 and, BRE2-1, and a (2-2)-th bridge electrode (which is not shown) without need to perform a removal process of removing the light emitting element LDb′.

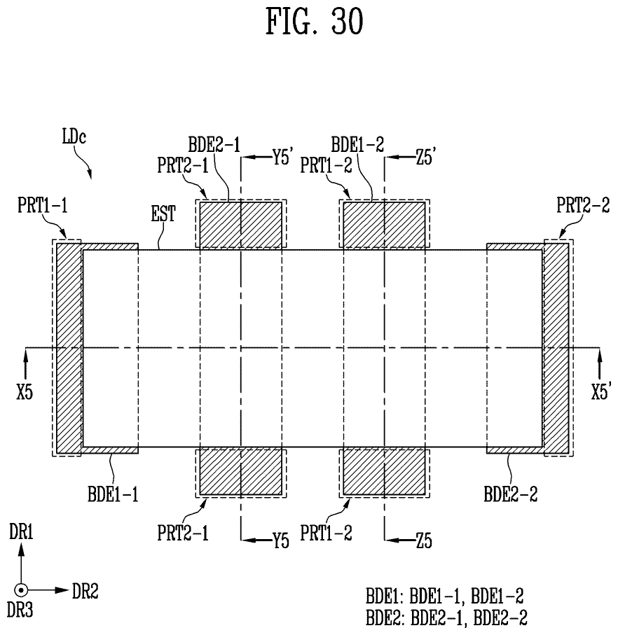

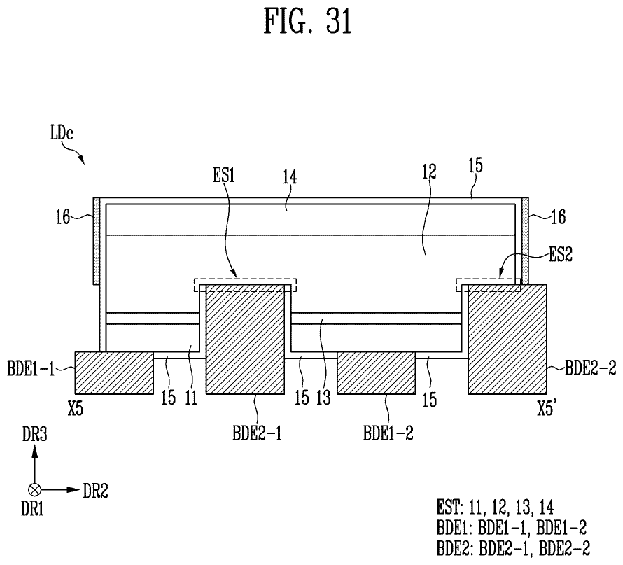

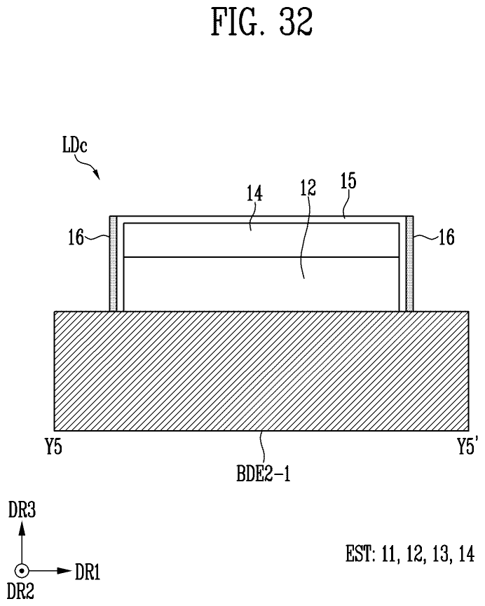

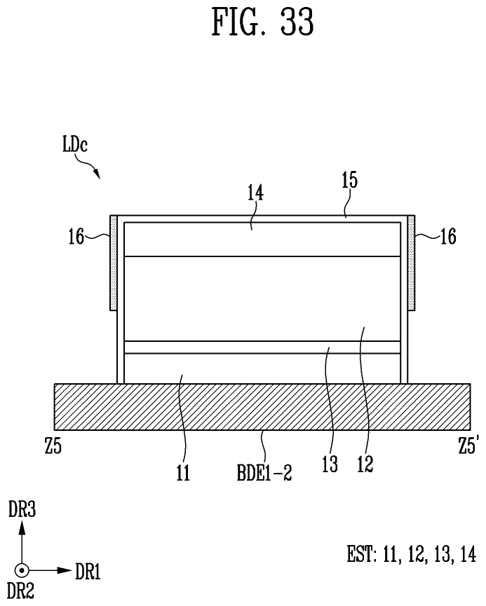

FIGS. 30 to 33 are schematic diagrams illustrating a light emitting element according to a fifth embodiment of the disclosure. FIG. 30 is a plan view illustrating the light emitting element according to the fifth embodiment of the disclosure, FIG. 31 is a schematic cross-sectional view taken along line X5-X5′ of FIG. 30, FIG. 32 is a schematic cross-sectional view taken along line Y5-Y5′ of FIG. 30, and FIG. 33 is a schematic cross-sectional view taken along line Z5-Z5′ of FIG. 30.

Referring to FIGS. 30 to 33, the light emitting element LDc may include a light emitting stack EST, a first bonding electrode BDE1, and a second bonding electrode BDE2.

The light emitting stack EST may be described substantially equally (or similarly) to that described with reference to FIGS. 6 to 8. The light emitting stack EST may include a first semiconductor layer 11, a second semiconductor layer 12 disposed on the first semiconductor layer 11, and an active layer 13 disposed between the first semiconductor layer 11 and the second semiconductor layer 12. In embodiments, the light emitting stack EST may further include an auxiliary layer 14 disposed on the second semiconductor layer 12. Hereinafter, an overlapping description is omitted.

The first bonding electrode BDE1 may include a (1-1)-th bonding electrode BDE1-1 and a (1-2)-th bonding electrode BDE1-2. The (1-1)-th bonding electrode BDE1-1 may be electrically connected to a lower surface of the first semiconductor layer 11. The (1-2)-th bonding electrode BDE1-2 may be electrically connected to the lower surface of the first semiconductor layer 11. The (1-2)-th bonding electrode BDE1-2 may be spaced apart from the (1-1)-th bonding electrode BDE1-1 in the second direction DR2. The (1-1)-th bonding electrode BDE1-1 and the (1-2)-th bonding electrode BDE1-2 may not physically contact the second semiconductor layer 12 and the active layer 13. In embodiments, the (1-1)-th bonding electrode BDE1-1 and the (1-2)-th bonding electrode BDE1-2 may include a eutectic metal.

The (1-1)-th bonding electrode BDE1-1 and the (1-2)-th bonding electrode BDE1-2 may be electrically connected to the anode electrode AE of FIG. 2. For example, each of the (1-1)-th bonding electrode BDE1-1 and the (1-2)-th bonding electrode BDE1-2 may be electrically connected to the anode electrode AE, or may be electrically connected to at least one electrode (or conductive layer) contacting the anode electrode AE.

The second bonding electrode BDE2 may include a (2-1)-th bonding electrode BDE2-1 and a (2-2)-th bonding electrode BDE2-2. The (2-1)-th bonding electrode BDE2-1 may be electrically connected to the second semiconductor layer 12. The (2-2)-th bonding electrode BDE2-2 may be electrically connected to the second semiconductor layer 12. The (2-2)-th bonding electrode BDE2-2 may be spaced apart from the (2-1)-th bonding electrode BDE2-1 in the second direction DR2. The (2-1)-th bonding electrode BDE2-1 and the (2-2)-th bonding electrode BDE2-2 may not physically contact the first semiconductor layer 11, the active layer 13, and the first bonding electrode BDE1. In embodiments, the (2-1)-th bonding electrode BDE2-1 and the (2-2)-th bonding electrode BDE2-2 may include a eutectic metal.

The (2-1)-th bonding electrode BDE2-1 and the (2-2)-th bonding electrode BDE2-2 may be electrically connected to the cathode electrode CE of FIG. 2. For example, each of the (2-1)-th bonding electrode BDE2-1 and the (2-2)-th bonding electrode BDE2-2 may be electrically connected to the cathode electrode CE, or may be electrically connected to at least one electrode (or conductive layer) contacting the cathode electrode CE.

The (2-1)-th bonding electrode BDE2-1 may be disposed between the (1-1)-th bonding electrode BDE1-1 and the (1-2)-th bonding electrode BDE1-2. The (1-2)-th bonding electrode BDE1-2 may be disposed between the (2-1)-th bonding electrode BDE2-1 and the (2-2)-th bonding electrode BDE2-2. Accordingly, a separation distance between the bonding electrodes BDE2-1 and BDE2-2 included in the second bonding electrode BDE2 and the bonding electrodes BDE1-1 and BDE1-2 included in the first bonding electrode BDE1 may become relatively small. Therefore, a current distribution in the light emitting element LDc may become more uniform, and thus light emission efficiency of the light emitting element LDc may be improved.

In an embodiment, a first exposed surface ES1 and a second exposed surface ES2 that do not overlap the first semiconductor layer 11 and the active layer 13 in a plan view may be defined on a face surface of the second semiconductor layer 12 facing an outer peripheral surface of the active layer 13. For example, the first exposed surface ES1 and the second exposed surface ES2 may be surfaces where the second semiconductor layer 12 may be exposed as a portion of the first semiconductor layer 11 and the active layer 13 may be removed. The first exposed surface ES1 may be positioned between the (1-1)-th bonding electrode BDE1-1 and the (1-2)-th bonding electrode BDE1-2 in a plan view, and the second exposed surface ES2 may be spaced apart from the first exposed surface ES1 in the second direction DR2 and may be adjacent to a side surface of the second semiconductor layer 12. The (2-1)-th bonding electrode BDE2-1 may be electrically connected to the first exposed surface ES1, and the (2-2)-th bonding electrode BDE2-2 may be electrically connected to the second exposed surface ES2.

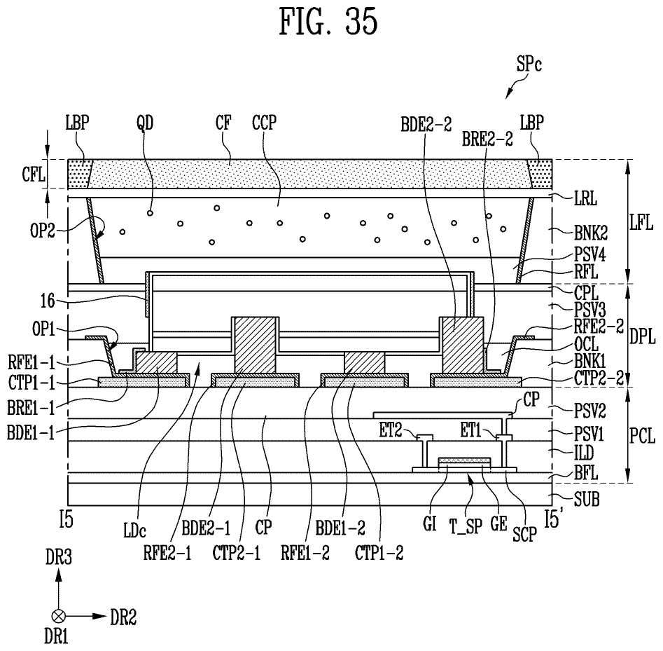

In an embodiment, the (1-1)-th bonding electrode BDE1-1 may include a (1-1)-th protrusion PRT1-1 protruding in a direction opposite to the second direction DR2 so as not to overlap the light emitting stack EST in a plan view. The (1-1)-th protrusion PRT1-1 of the (1-1)-th bonding electrode BDE1-1 may serve to secure a connection path between to the (1-1)-th bonding electrode BDE1-1 and the anode electrode AE in case that a connection defect with the anode electrode AE occurs. This is described in detail later with reference to FIG. 35.

In an embodiment, the (1-2)-th bonding electrode BDE1-2 may include a (1-2)-th protrusion PRT1-2 protruding in at least one of the first direction DR1 and a direction opposite to the first direction DR1 so as to not overlap the light emitting stack EST in a plan view. For example, as shown in FIG. 30, the (1-2)-th bonding electrode BDE1-2 may include the (1-2)-th protrusion PRT1-2 protruding in the first direction DR1 and the direction opposite to the first direction DR1 compared to the light emitting stack EST. However, embodiments of the (1-2)-th protrusion PRT1-2 are not limited to that shown in FIG. 30. For example, the (1-2)-th bonding electrode BDE1-2 may include a (1-2)-th protrusion protruding only in the first direction DR1 compared to the light emitting stack EST, or may include a (1-2)-th protrusion protruding only in the direction opposite to the first direction DR1 compared to the light emitting stack EST.

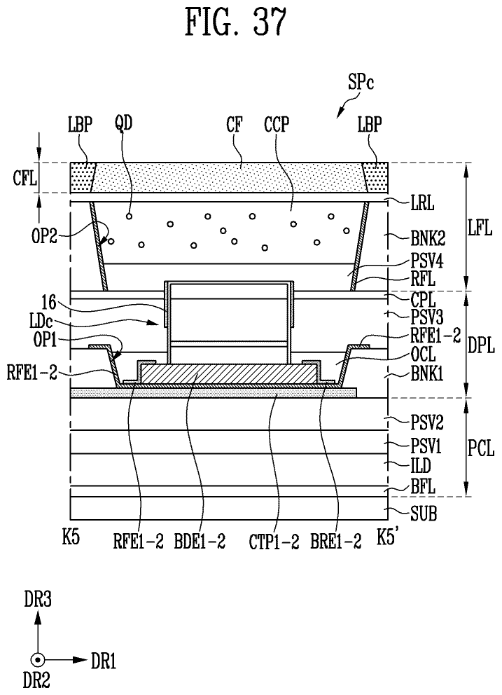

The (1-2)-th protrusion PRT1-2 of the (1-2)-th bonding electrode BDE1-2 may serve to secure a connection path between the (1-2)-th bonding electrode BDE1-2 and the anode electrode AE in case that a connection defect with the anode electrode AE occurs. This is described in detail later with reference to FIG. 37.

In an embodiment, the (2-1)-th bonding electrode BDE2-1 may include a (2-1)-th protrusion PRT2-1 protruding in at least one of the first direction DR1 and the direction opposite to the first direction DR1 so as not to overlap the planar light emitting stack EST in a plan view. For example, as shown in FIG. 30, the (2-1)-th bonding electrode BDE2-1 may include the (2-1)-th protrusion PRT2-1 protruding in at least one of the first direction DR1 and the direction opposite to the first direction DR1 compared to the light emitting stack EST. However, embodiments of the (2-1)-th protrusion PRT2-1 are not limited to that shown in FIG. 30. For example, the (2-1)-th bonding electrode BDE2-1 may include a (2-1)-th protrusion protruding only in the first direction DR1 compared to the light emitting stack EST, or may include a (2-1)-th protrusion protruding only in the direction opposite to the first direction DR1 compared to the light emitting stack EST.

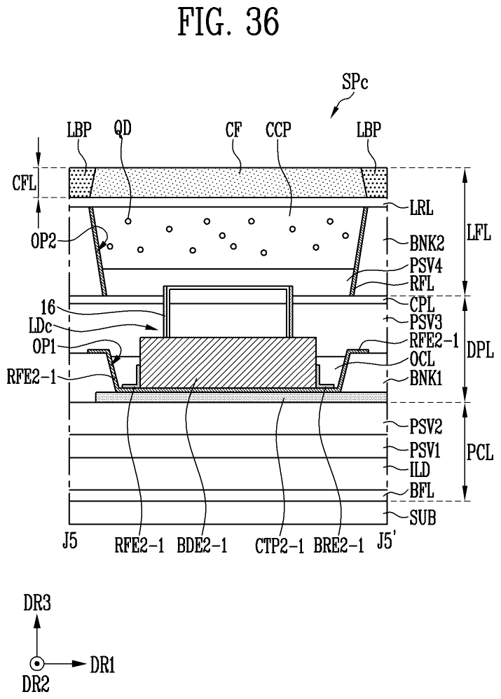

The (2-1)-th protrusion PRT2-1 of the (2-1)-th bonding electrode BDE2-1 may serve to secure a connection path between the (2-1)-th bonding electrode BDE2-1 and the cathode electrode CE in case that a connection defect with the cathode electrode CE occurs. This is described in detail later with reference to FIG. 36.

In an embodiment, the (2-2)-th bonding electrode BDE2-2 may include a (2-2)-th protrusion PRT2-2 protruding in the second direction DR2 so as not to overlap the light emitting stack EST in a plan view. The (2-2)-th protrusion PRT2-2 of the (2-2)-th bonding electrode BDE2-2 may serve to secure a connection path between the (2-2)-th bonding electrode BDE2-2 and the cathode electrode CE in case that a connection defect with the cathode electrode CE occurs. This is described in detail later with reference to FIG. 35.

In an embodiment, the light emitting element LDc may further include an insulating layer 15 surrounding at least a portion of an outer peripheral surface of the light emitting stack EST. For example, the insulating layer 15 may entirely surround the outer peripheral surface of the light emitting stack EST except for an area where the light emitting stack EST and the first and second bonding electrodes BDE1 and BDE2 may be electrically connected.

The insulating layer 15 may serve to prevent an electrical short circuit that may occur in case that the active layer 13 contacts another conductive material except for the first and second semiconductor layers 11 and 12. The insulating layer 15 may be disposed between the (2-1)-th bonding electrode BDE2-1 and the first semiconductor layer 11, and between the (2-1)-th bonding electrode BDE2-1 and the active layer 13, to serve to prevent an electrical short circuit that may occur in case that the (2-1)-th bonding electrode BDE2-1 contacts the first semiconductor layer 11 and the active layer 13. The insulating layer 15 may be disposed between the (2-2)-th bonding electrode BDE2-2 and the first semiconductor layer 11, and between the (2-2)-th bonding electrode BDE2-2 and the active layer 13, to serve to prevent an electrical short circuit that may occur in case that the (2-2)-th bonding electrode BDE2-2 contacts the first semiconductor layer 11 and the active layer 13. The insulating layer 15 may include a transparent insulating material. A portion of the first and second bonding electrodes BDE1 and BDE2 may not be covered by the insulating layer 15 and may be exposed.

Even though the light emitting element LDc further includes the insulating layer 15, each of the (1-1)-th protrusion PRT1-1 of the (1-1)-th bonding electrode BDE1-1, the (1-2)-th protrusion of the (1-2)-th bonding electrode BDE1-2, the (2-1)-th protrusion PRT2-1 of the (2-1)-th bonding electrode BDE2-1, and the (2-2)-th protrusion PRT2-2 of the (2-2)-th bonding electrode BDE2-2 may further protrude compared to the insulating layer 15 in a plan view.

In an embodiment, the light emitting element LDc may further include a reflective layer 16 surrounding at least a portion of a side surface of the light emitting stack EST. For example, the reflective layer 16 may surround a side surface of the auxiliary layer 14 and a portion of a side surface of the second semiconductor layer 12 on the second bonding electrode BDE2.

The reflective layer 16 may serve to improve front surface light emission efficiency of light generated in the active layer 13. For example, the insulating layer 15 may be disposed between the reflective layer 16 and the light emitting stack EST, and the reflective layer 16 may include an insulating material having a refractive index different from that of the insulating layer 15. Accordingly, total reflection of light may be induced at an interface between the reflective layer 16 and the insulating layer 15, and thus the light generated in the active layer 13 may proceed in a front surface direction (for example, the third direction DR3 and a direction intersecting the third direction DR3) of the display panel DP of FIG. 3. As an example, the reflective layer 16 may include a material suitable for reflecting incident light. For example, the reflective layer 16 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them.

In an embodiment, the reflective layer 16 may contact each of the (2-1)-th bonding electrode BDE2-1 and the (2-2)-th bonding electrode BDE2-2. For example, as shown in FIG. 32, the reflective layer 16 may contact the (2-1)-th protrusion PRT2-1 of FIG. 30. As shown in FIG. 31, the reflective layer 16 may contact the (2-2)-th protrusion PRT2-2 of FIG. 30 of the (2-2)-th bonding electrode BDE2-2. The reflective layer 16 may be configured to include a conductive material. Accordingly, the (2-1)-th bonding electrode BDE2-1 and the (2-2)-th bonding electrode BDE2-2 may be electrically connected to each other by the reflective layer 16. Accordingly, even though a connection defect occurs between one of the (2-1)-th bonding electrode BDE2-1 and the (2-2)-th bonding electrode BDE2-2 and the cathode electrode CE, in case that one of the (2-1)-th bonding electrode BDE2-1 and the (2-2)-th bonding electrode BDE2-2 is normally electrically connected to the cathode electrode CE, both of the (2-1)-th bonding electrode BDE2-1 and the (2-2)-th bonding electrode BDE2-2 may be electrically connected to the cathode electrode CE through the reflective layer 16. For example, the reflective layer 16 may further serve to secure reliability of the (2-1)-th bonding electrode BDE2-1 and the (2-2)-th bonding electrode BDE2-2.

In the embodiment described above, the reflective layer 16 may be spaced apart from the first bonding electrode BDE1. For example, in case that the reflective layer 16 electrically connects the (2-1)-th bonding electrode BDE2-1 and the (2-2)-th bonding electrode BDE2-2 to each other, the (1-1)-th bonding electrode BDE1-1 and the (1-2)-th bonding electrode BDE1-2 may be spaced apart from the reflective layer 16. Accordingly, an electrical short circuit that the (1-1)-th bonding electrode BDE1-1 and the (1-2)-th bonding electrode BDE1-2 may be electrically connected to the (2-1)-th bonding electrode BDE2-1 and the (2-2)-th bonding electrode BDE2-2 through the reflective layer 16 may not occur.

Even though the light emitting element LDc further includes the reflective layer 16, each of the (1-1)-th protrusion PRT1-1 of the (1-1)-th bonding electrode BDE1-1, the (1-2)-th protrusion PRT1-2 of the (1-2)-th bonding electrode BDE1-2, the (2-1)-th protrusion PRT2-1 of the (2-1)-th bonding electrode BDE2-1, and the (2-2)-th protrusions PRT2-2 of the (2-2)-th bonding electrode BDE2-2 may further protrude compared to the reflective layer 16 in a plan view.

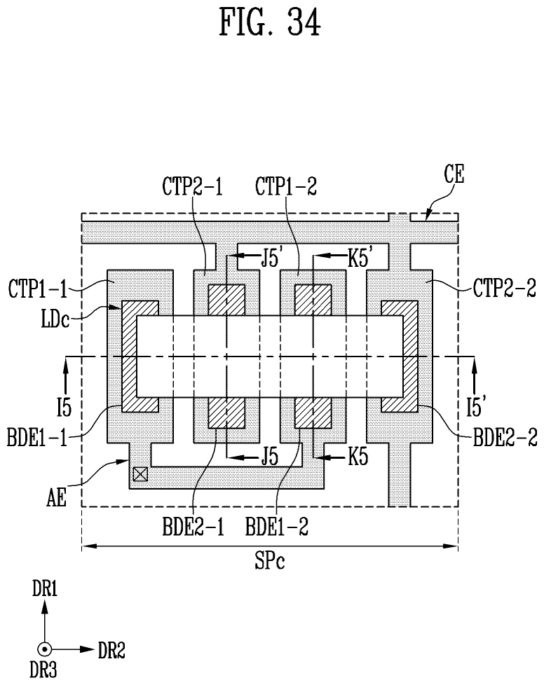

FIGS. 34 to 37 are schematic diagrams illustrating a sub-pixel including the light emitting element according to the fifth embodiment of the disclosure. FIG. 34 is a plan view illustrating the sub-pixel including the light emitting element according to the fifth embodiment of the disclosure, FIG. 35 is a schematic cross-sectional view taken along line I5-I5′ of FIG. 34, FIG. 36 is a schematic cross-sectional view taken along line J5-J5′ of FIG. 34, and FIG. 37 is a schematic cross-sectional view taken along line K5-K5′ of FIG. 34.

Referring to FIG. 34, the sub-pixel SPc may be provided. The sub-pixel SPc may be one sub-pixel among the first to third sub-pixels SP1, SP2, and SP3 described with reference to FIG. 3.

The sub-pixel SPc may include the anode electrode AE and the cathode electrode CE. The anode electrode AE may be electrically connected to the sub-pixel circuit SPC of FIG. 2 of the sub-pixel SPc. The cathode electrode CE may be spaced apart from the anode electrode AE. The cathode electrode CE may be disposed at the same height as the anode electrode AE. The anode electrode AE and the cathode electrode CE may define an electrode layer, and the anode electrode AE and the cathode electrode CE may be implemented as patterns of the electrode layer. In embodiments, the cathode electrode CE may extend in the first direction DR1 and may be used as a common electrode for the pixel PXL and other pixels adjacent to the pixel PXL. The cathode electrode CE may extend in the second direction DR2 and may be used as a common electrode for all of the sub-pixels SP shown in FIG. 3.

The anode electrode AE may include a (1-1)-th contact portion CTP1-1 and a (1-2)-th contact portion CTP1-2. The (1-1)-th contact portion CTP1-1 and the (1-2)-th contact portion CTP1-2 may be electrically connected to each other. The cathode electrode CE may include a (2-1)-th contact portion CTP2-1 and a (2-2)-th contact portion CTP2-2. The (2-1)-th contact portion CTP2-1 and the (2-2)-th contact portion CTP2-2 may be electrically connected to each other.

The light emitting element LDc described with reference to FIGS. 30 to 33 may be disposed on the anode electrode AE and the cathode electrode CE. The (1-1)-th bonding electrode BDE1-1 of the light emitting element LDc may be disposed on the (1-1)-th contact portion CTP1-1 of the anode electrode AE. The (1-2)-th bonding electrode BDE1-2 of the light emitting element LDc may be disposed on the (1-2)-th contact portion CTP1-2 of the anode electrode AE. The (2-1)-th bonding electrode BDE2-1 of the light emitting element LDc may be disposed on the (2-1)-th contact portion CTP2-1 of the cathode electrode CE. The (2-2)-th bonding electrode BDE2-2 of the light emitting element LDc may be disposed on the (2-2)-th contact portion CTP2-2 of the cathode electrode CE.

The light emitting element LDc may be electrically connected to the anode electrode AE and the cathode electrode CE. The (1-1)-th bonding electrode BDE1-1 and the (1-2)-th bonding electrode BDE1-2 of the light emitting element LDc may be electrically connected to the anode electrode AE. The (2-1)-th bonding electrode BDE2-1 and the (2-2)-th bonding electrode BDE2-2 of the light emitting element LDc may be electrically connected to the cathode electrode CE.

Referring to FIGS. 34 to 37, the pixel circuit layer PCL, the display element layer DPL, and the light functional layer LFL may be sequentially disposed on the substrate SUB.

The pixel circuit layer PCL may be described substantially equally (or similarly) to that described with reference to FIGS. 9 to 11. Therefore, an overlapping description is omitted.

The display element layer DPL may be disposed on the second passivation layer PSV2. The display element layer DPL may include the anode electrode AE, the cathode electrode CE, a first bank BNK1, a (1-1)-th reflective electrode REF1-1, a (1-2)-th reflective electrode RFE1-2, a (2-1)-th reflective electrode RFE2-1, a (2-2)-th reflective electrode RFE2-2, the light emitting element LDc, an overcoat layer OCL, a third passivation layer PSV3, and a capping layer CPL.

The electrode layer including the anode electrode AE and the cathode electrode CE may be disposed on the pixel circuit layer PCL. The anode electrode AE may include a (1-1)-th contact portion CTP1-1 and a (1-2)-th contact portion CTP1-2, and the cathode electrode CE may include a (2-1)-th contact portion CTP2-1 and a (2-2)-th contact portion CTP2-2.

The anode electrode AE may be electrically connected to the connection electrode CP through a contact hole (not shown) passing through the second passivation layer PSV2. As described above, the anode electrode AE may be electrically connected to the transistor T_SP.

The (1-2)-th contact portion CTP1-2 may be spaced apart from the (1-1)-th contact portion CTP1-1 in the second direction DR2. Since the anode electrode AE may be electrically connected to the transistor T_SP, the (1-1)-th contact portion CTP1-1 and the (1-2)-th contact portion CTP1-2 may be electrically connected to the transistor T_SP.

The (2-1)-th contact portion CTP2-1 may be disposed between the (1-1)-th contact portion CTP1-1 and the (1-2)-th contact portion CTP1-2. The (2-2)-th contact portion CTP2-2 may be spaced apart from the (1-2)-th contact portion CTP1-2 in the second direction DR2. The cathode electrode CE may be electrically connected to the second power voltage node VSSN of FIG. 2. Accordingly, the second power voltage applied to the second power voltage node VSSN may be transmitted to the (2-1)-th contact portion CTP2-1 and the (2-2)-th contact portion CTP2-2.

The first bank BNK1 may be disposed on the anode electrode AE and the cathode electrode CE. The first bank BNK1 may have a first opening OP1 exposing portions of the anode electrode AE and the cathode electrode CE. The light emitting element LDc may be disposed in the first opening OP1 of the first bank BNK1. As described above, the first bank BNK1 may be provided as a pixel defining layer that defines an area where the light emitting element LDc may be positioned.

The first bank BNK1 may be configured to include a light blocking material and may serve to prevent light mixing between adjacent sub-pixels. In embodiments, the first bank BNK1 may include an organic material. For example, the first bank BNK1 may include an organic insulating material such as acryl resin, epoxy resin, phenol resin, polyamide resin, and polyimide resin.

The (1-1)-th reflective electrode RFE1-1 may be disposed on an exposed portion of the (1-1)-th contact portion CTP1-1 and a side surface of the first bank BNK1 adjacent thereto. The (1-2)-th reflective electrode RFE1-2 may be disposed on an exposed portion of the (1-2)-th contact portion CTP1-2 and a side surface of the first bank BNK1 adjacent thereto. The (2-1)-th reflective electrode RFE2-1 may be disposed on an exposed portion of the (2-1)-th contact portion CTP2-1 and a side surface of the first bank BNK1 adjacent thereto. The (2-2)-th reflective electrode RFE2-2 may be disposed on an exposed portion of the (2-2)-th contact portion CTP2-2 and a side surface of the first bank BNK1 adjacent thereto. The (1-1)-th reflective electrode RFE1-1, the (1-2)-th reflective electrode RFE1-2, the (2-1)-th reflective electrode RFE2-1, and the (2-2)-th reflective electrode RFE2-2 may include conductive materials suitable for reflecting light. Accordingly, light emission efficiency of the light emitting element LDc may be improved. In embodiments, the (1-1)-th reflective electrode RFE1-1, the (1-2)-th reflective electrode RFE1-2, the (2-1)-th reflective electrode RFE2-1, and the (2-2)-th reflective electrode RFE2-2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them. However, embodiments are not limited thereto.

The light emitting element LDc may be electrically connected to the (1-1)-th contact portion CTP1-1 of the anode electrode AE through the (1-1)-th reflective electrode RFE1-1. For example, the (1-1)-th bonding electrode BDE1-1 of the light emitting element LDc may be electrically connected to the (1-1)-th reflective electrode RFE1-1, and thus the (1-1)-th bonding electrode BDE1-1 may be electrically connected to the (1-1)-th contact portion CTP1-1 of the anode electrode AE through the (1-1)-th reflective electrode BDE1-1.

The light emitting element LDc may be electrically connected to the (1-2)-th contact portion CTP1-2 of the anode electrode AE through the (1-2)-th reflective electrode RFE1-2. For example, the (1-2)-th bonding electrode BDE1-2 of the light emitting element LDc may be electrically connected to the (1-2)-th reflective electrode RFE1-2, and thus the (1-2)-th bonding electrode BDE1-2 may be electrically connected to the (1-2)-th contact portion CTP1-2 of the anode electrode AE through the (1-2)-th reflective electrode BDE1-2.

The light emitting element LDc may be electrically connected to the (2-1)-th contact portion CTP2-1 of the cathode electrode CE through the (2-1)-th reflective electrode RFE2-1. For example, the (2-1)-th bonding electrode BDE2-1 of the light emitting element LDc may be electrically connected to the (2-1)-th reflective electrode RFE2-1, and thus the (2-1)-th bonding electrode BDE2-1 may be electrically connected to the (2-1)-th contact portion CTP2-1 of the cathode electrode CE through the (2-1)-th reflective electrode RFE2-1.

The light emitting element LDc may be electrically connected to the (2-2)-th contact portion CTP2-2 of the cathode electrode CE through the (2-2)-th reflective electrode RFE2-2. For example, the (2-2)-th bonding electrode BDE2-2 of the light emitting element LDc may be electrically connected to the (2-2)-th reflective electrode RFE2-2, and thus the (2-2)-th bonding electrode BDE2-2 may be electrically connected to the (2-2)-th contact portion CTP2-2 of the cathode electrode CE through the (2-2)-th reflective electrode RFE2-2.

The overcoat layer OCL may be disposed in the first opening OP1 where the (1-1)-th reflective electrode RFE1-1, the (1-2)-th reflective electrode RFE1-2, the (2-1)-th reflective electrode RFE2-1, the (2-2)-th reflective electrode RFE2-2, and the light emitting element LDc may be disposed. The overcoat layer OCL may fix the light emitting element LDc so that the light emitting element LDc electrically connected to the (1-1)-th reflective electrode RFE1-1, the (1-2)-th reflective electrode RFE1-2, the (2-1)-th reflective electrode RFE2-1, and the (2-2)-th reflective electrode RFE2-2 does not move. The overcoat layer OCL may protect components disposed under the overcoat layer OCL from a foreign material such as dust and moisture. For example, the overcoat layer OCL may include at least one of an inorganic insulating layer and an organic insulating layer. For example, the overcoat layer OCL may include epoxy, but embodiments are not limited thereto.

The third passivation layer PSV3 may be disposed on the first bank BNK1 and the overcoat layer OCL. The capping layer CPL may be disposed on the third passivation layer PSV3. The third passivation layer PSV3 and the capping layer CPL may be described substantially equally (or similarly) to those described with reference to FIGS. 9 to 11. Therefore, an overlapping description is omitted.

The light functional layer LFL may be disposed on the capping layer CPL. The light functional layer LFL may include a second bank BNK2, a light reflective layer RFL, a fourth passivation layer PSV4, a light functional pattern CCP, a low refractive layer LRL, and a color filter layer CFL. The light functional layer LFL may be described substantially equally (or similarly) to that described with reference to FIGS. 9 to 11. Therefore, an overlapping description is omitted.

Referring to FIGS. 30 to 34 and 36 again, in order to secure reliability of an electrical connection between the (2-1)-th bonding electrode BDE2-1 and the (2-1)-th contact portion CTP2-1, a (2-1)-th bridge electrode BRE2-1 may be further disposed.

In an embodiment, the (2-1)-th bonding electrode BDE2-1 may be normally electrically connected to the (2-1)-th reflective electrode RFE2-1 electrically contacting the (2-1)-th contact portion CTP2-1. For example, in the process of disposing the light emitting element LDc on the pixel circuit layer PCL, the (2-1)-th bonding electrode BDE2-1 may be electrically connected to the (2-1)-th contact portion CTP2-1. The (2-1)-th bridge electrode BRE2-1 may be omitted.

In an embodiment, the (2-1)-th bonding electrode BDE2-1 may not be normally electrically connected to the (2-1)-th reflective electrode RFE2-1 electrically contacting the (2-1)-th contact portion CTP2-1. For example, in the process of disposing the light emitting element LDc on the pixel circuit layer PCL, the (2-1)-th bonding electrode BDE2-1 may not be electrically connected to the (2-1)-th contact portion CTP2-1. In case that a connection defect is sensed through a light emission inspection process or the like subsequent to the above-described process, the (2-1)-th bridge electrode BRE2-1 for electrically connecting the (2-1)-th bonding electrode BDE2-1 and the (2-1)-th contact portion CTP2-1 may be disposed.

The (2-1)-th bridge electrode BRE2-1 may be disposed along a side surface of the (2-1)-th protrusion PRT2-1 of the (2-1)-th bonding electrode BDE2-1. The (2-1)-th bridge electrode BRE2-1 may extend from the side surface of the (2-1)-th protrusion PRT2-1 and may contact the (2-1)-th reflective electrode RFE2-1 electrically contacting the (2-1)-th contact portion CTP2-1. Accordingly, the (2-1)-th bonding electrode BDE2 may be electrically connected to the (2-1)-th contact portion CTP2-1 through the (2-1)-th bridge electrode BRE2-1.

In embodiments, the planar area of the (2-1)-th contact portion CTP2-1 may be sufficiently larger than the planar area of the (2-1)-th bonding electrode BDE2-1, and the (2-1)-th bonding electrode BDE2-1 may completely overlap a portion of the (2-1)-th contact portion CTP2-1 in a plan view. Accordingly, a space in which the (2-1)-th bridge electrode BRE2-1 may be disposed may be sufficiently secured.

Referring to FIGS. 30 to 34 and FIG. 37 again, in order to secure reliability of an electrical connection between the (1-2)-th bonding electrode BDE1-2 and the (1-2)-th contact portion CTP1-2, a (1-2)-th bridge electrode BRE1-2 may be further disposed.

In an embodiment, the (1-2)-th bonding electrode BDE1-2 may be normally electrically connected to the (1-2)-th reflective electrode RFE1-2 electrically contacting the (1-2)-th contact portion CTP1-2. For example, in the process of disposing the light emitting element LDc on the pixel circuit layer PCL, the (1-2)-th bonding electrode BDE1-2 may be electrically connected to the (1-2)-th contact portion CTP1-2. The (1-2)-th bridge electrode BRE1-2 may be omitted.

In an embodiment, the (1-2)-th bonding electrode BDE1-2 may not be normally electrically connected to the (1-2)-th reflective electrode RFE1-2 electrically contacting the (1-2)-th contact portion CTP1-2. For example, in the process of disposing the light emitting element LDc on the pixel circuit layer PCL, the (1-2)-th bonding electrode BDE1-2 may not be electrically connected to the (1-2)-th contact portion CTP1-2. In case that a connection defect is sensed through a light emission inspection process or the like subsequent to the above-described process, the (1-2)-th bridge electrode BRE1-2 for electrically connecting the (1-2)-th bonding electrode BDE1-2 and the (1-2)-th contact portion CTP1-2 may be disposed.

The (1-2)-th bridge electrode BRE1-2 may be disposed along an outer peripheral surface of the (1-2)-th protrusion PRT1-2 of the (1-2)-th bonding electrode BDE1-2. The (1-2)-th bridge electrode BRE1-2 may extend from the outer peripheral surface of the (1-2)-th protrusion PRT1-2 and may contact the (1-2)-th reflective electrode RFE1-2 electrically contacting the (1-2)-th contact portion CTP1-2. Accordingly, the (1-2)-th bonding electrode BDE1-2 may be electrically connected to the (1-2)-th contact portion CTP1-2 through the (1-2)-th bridge electrode BRE1-2.

In embodiments, the planar area of the (1-2)-th contact portion CTP1-2 may be sufficiently larger than the planar area of the (1-2)-th bonding electrode BDE1-2, and the (1-2)-th bonding electrode BDE1-2 may completely overlap a portion of the (1-2)-th contact portion CTP1-2 in a plan view. Accordingly, a space in which the (1-2)-th bridge electrode BRE1-2 may be disposed may be sufficiently secured.

Referring to FIGS. 30 to 35, in order to secure reliability of an electrical connection between the (1-1)-th bonding electrode BDE1-1 and the (1-1)-th contact portion CTP1-1, a (1-1)-th bridge electrode BRE1-1 may be further disposed.

In an embodiment, the (1-1)-th bonding electrode BDE1-1 may be normally electrically connected to the (1-1)-th reflective electrode RFE1-1 electrically contacting the (1-1)-th contact portion CTP1-1. For example, in a process of disposing the light emitting element LDc on the pixel circuit layer PCL, the (1-1)-th bonding electrode BDE1-1 may be electrically connected to the (1-1)-th contact portion CTP1-1. The (1-1)-th bridge electrode BRE1-1 may be omitted.

In an embodiment, the (1-1)-th bonding electrode BDE1-1 may not be normally electrically connected to the (1-1)-th reflective electrode RFE1-1 electrically contacting the (1-1)-th contact portion CTP1-1. For example, in the process of disposing the light emitting element LDc on the pixel circuit layer PCL, the (1-1)-th bonding electrode BDE1-1 may not be electrically connected to the (1-1)-th contact portion CTP1-1. In case that a connection defect is sensed through a light emission inspection process or the like subsequent to the above-described process, the (1-1)-th bridge electrode BRE1-1 for electrically connecting the (1-1)-th bonding electrode BDE1-1 and the (1-1)-th contact portion CTP1-1 may be disposed.

The (1-1)-th bridge electrode BRE1-1 may be disposed along an outer peripheral surface of the (1-1)-th protrusion PRT1-1 of the (1-1)-th bonding electrode BDE1-1. The (1-1)-th bridge electrode BRE1-1 may extend from the outer peripheral surface of the (1-1)-th protrusion PRT1-1 and may contact the (1-1)-th reflective electrode RFE1-1 electrically contacting the (1-1)-th contact portion CTP1-1. Accordingly, the (1-1)-th bonding electrode BDE1-1 may be electrically connected to the (1-1)-th contact portion CTP1-1 through the (1-1)-th bridge electrode BRE1-1.

In embodiments, the planar area of the (1-1)-th contact portion CTP1-1 may be sufficiently larger than the planar area of the (1-1)-th bonding electrode BDE1-1, and the (1-1)-th bonding electrode BDE1-1 may completely overlap a portion of the (1-1)-th contact portion CTP1-1 in a plan view. Accordingly, a space in which the (1-1)-th bridge electrode BRE1-1 may be disposed may be sufficiently secured.

Referring to FIGS. 30 to 35, in order to secure reliability of an electrical connection between the (2-2)-th bonding electrode BDE2-2 and the (2-2)-th contact portion CTP2-2, a (2-2)-th bridge electrode BRE2-2 may be further disposed.

In an embodiment, the (2-2)-th bonding electrode BDE2-2 may be normally electrically connected to the (2-2)-th reflective electrode RFE2-2 electrically contacting the (2-2)-th contact portion CTP2-2. For example, in the process of disposing the light emitting element LDc on the pixel circuit layer PCL, the (2-2)-th bonding electrode BDE2-2 may be electrically connected to the (2-2)-th contact portion CTP2-2. The (2-2)-th bridge electrode BRE2-2 may be omitted.

In an embodiment, the (2-2)-th bonding electrode BDE2-2 may not be normally electrically connected to the (2-2)-th reflective electrode RFE2-2 electrically contacting the (2-2)-th contact portion CTP2-2. For example, in the process of disposing the light emitting element LDc on the pixel circuit layer PCL, the (2-2)-th bonding electrode BDE2-2 may not be electrically connected to the (2-2)-th contact portion CTP2-2. In case that a connection defect is sensed through a light emission inspection process or the like subsequent to the above-described process, the (2-2)-th bridge electrode BRE2-2 for electrically connecting the (2-2)-th bonding electrode BDE2-2 and the (2-2)-th contact portion CTP2-2 may be disposed.

The (2-2)-th bridge electrode BRE2-2 may be disposed along a side surface of the (2-2)-th protrusion PRT2-2 of the (2-2)-th bonding electrode BDE2-2. The (2-2)-th bridge electrode BRE2-2 may extend from the side surface of the (2-2)-th protrusion PRT2-2 and may contact the (2-2)-th reflective electrode RFE2-2 electrically contacting the (2-2)-th contact portion CTP2-2. Accordingly, the (2-2)-th bonding electrode BDE2-2 may be electrically connected to the (2-2)-th contact portion CTP2-2 through the (2-2)-th bridge electrode BRE2-2.

In embodiments, the planar area of the (2-2)-th contact portion CTP2-2 may be sufficiently larger than the planar area of the (2-2)-th bonding electrode BDE2-2, and the (2-2)-th bonding electrode BDE2-2 may completely overlap a portion of the (2-2)-th contact portion CTP2-2 in a plan view. Accordingly, a space in which the (2-2)-th bridge electrode BRE2-2 may be disposed may be sufficiently secured.

As described above with reference to FIGS. 30 to 37, the light emitting element LDc of the disclosure may have a relatively small distance between bonding electrodes electrically connected to different semiconductor layers, and thus may have excellent light emission efficiency. Even though a connection defect occurs in the process of disposing the light emitting element LDc on the pixel circuit layer PCL, the connection defect described above may be readily repaired using the bridge electrodes BRE1-1, BRE1-2, BRE2-1, and BRE2-2 without need to perform a removal process of removing the light emitting element LDc.

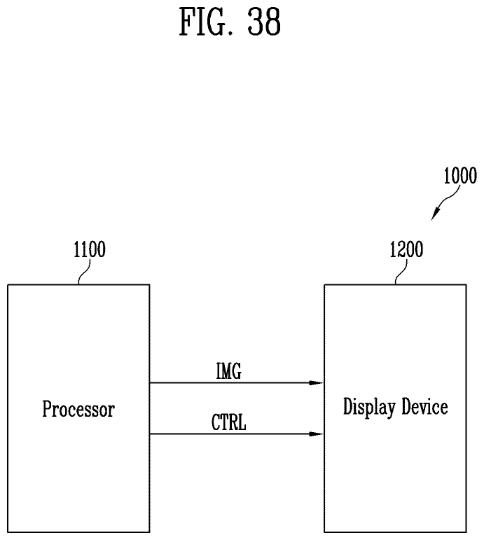

FIG. 38 is a schematic block diagram illustrating a display system according to an embodiment.

Referring to FIG. 38, the display system 1000 may include a processor 1100 and a display device 1200.

The processor 1100 may perform various tasks and calculations. In embodiments, the processor 1100 may include an application processor, a graphics processor, a microprocessor, a central processing unit (CPU), and the like. The processor 1100 may be electrically connected to other components of the display system 1000 through a bus system to control the other components.

The processor 1100 may transmit image data IMG and a control signal CTRL to the display device 1200. The display device 1200 may display an image based on the image data IMG and the control signal CTRL. The display device 1200 may be configured similarly to the display device DD described with reference to FIG. 1. The image data IMG and the control signal CTRL may be provided as the input image data IMG and the control signal CTRL of FIG. 1, respectively.

The display system 1000 may include a computing system providing an image display function, such as a smart watch, a mobile phone, a smart phone, a portable computer, a tablet personal computer (PC), a watch phone, an automotive display, smart glasses, a portable multimedia player (PMP), a navigation device, and an ultra mobile personal computer (UMPC). The display system 1000 may include at least one of a head mounted display (HMD) device, a virtual reality (VR) device, a mixed reality (MR) device, and an augmented reality (AR) device.

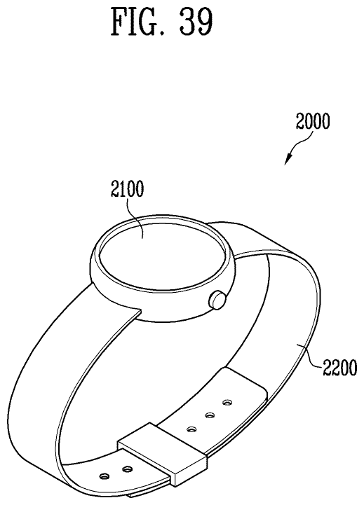

FIGS. 39 to 42 are perspective views illustrating application examples of the display system of FIG. 38.

Referring to FIG. 39, the display system 1000 of FIG. 38 may be applied to a smart watch 2000 including a display part 2100 and a strap part 2200.

The smart watch 2000 may be a wearable electronic device. For example, the smart watch 2000 may have a structure in which the strap part 2200 may be mounted on a user's wrist. Here, the display system 1000 and/or the display device 1200 may be applied to the display part 2100, and image data including time information may be provided to a user.

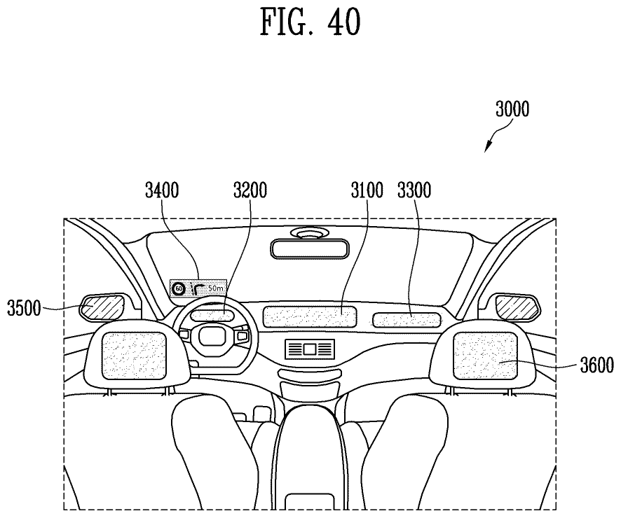

Referring to FIG. 40, the display system 1000 of FIG. 38 may be applied to an automotive display system 3000. Here, the automotive display system 3000 may include a computing system provided inside and/or outside a vehicle to provide image data.

For example, the display system 1000 and/or the display device 1200 may be applied to at least one of an infotainment panel 3100, a cluster 3200, a co-driver display 3300, a head-up display 3400, a side mirror display 3500, and a rear seat displays 3600 provided in a vehicle.

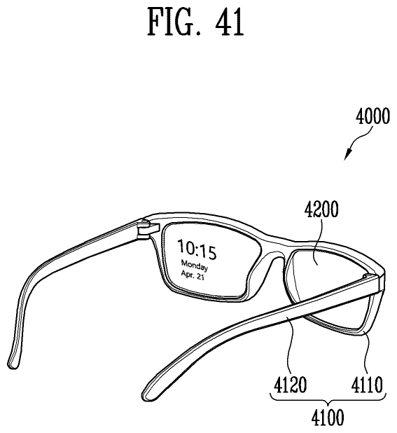

Referring to FIG. 41, the display system 1000 of FIG. 38 may be applied to smart glasses 4000. The smart glasses 4000 may be a wearable electronic device that may be worn on a user's head. For example, the smart glasses 4000 may be a wearable device for augmented reality.

The smart glasses 4000 may include a frame 4100 and a lens part 4200. The frame 4100 may include a housing 4110 that supports the lens part 4200 and a leg part 4120 for the user to wear. The leg part 4120 may be connected to the housing 4110 through a hinge and may be folded or unfolded relative to the housing 4110.

A battery, a touch pad, a microphone, a camera, and the like may be built in the frame 4100. A projector that outputs light, a processor that controls a light signal, and the like may be built in the frame 4100.

The lens part 4200 may include an optical member that transmits or reflects light. For example, the lens part 4200 may include glass, transparent synthetic resin, or the like.

In order for user's eyes to recognize visual information, the lens part 4200 may reflect an image by the light signal transmitted from the projector of the frame 4100 by a rear surface (for example, a surface of a direction facing the user's eyes) of the lens part 4200. For example, the user may recognize visual information such as time and date displayed on the lens part 4200. At this time, the projector and/or the lens part 4200 may be a type of display device. The display device 1200 may be applied to the projector and/or the lens part 4200.

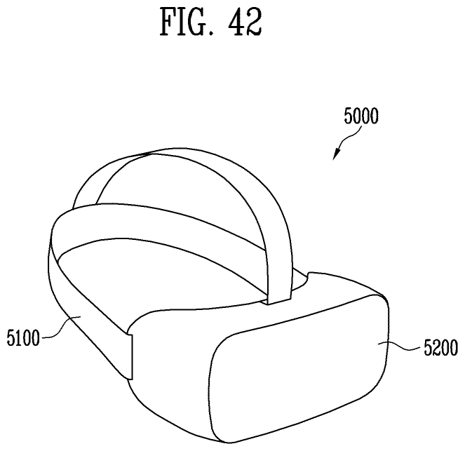

Referring to FIG. 42, the display system 1000 of FIG. 38 may be applied to a head mounted display device 5000.

The head mounted display device 5000 may be a wearable electronic device that may be worn on a user's head. For example, the head mounted display device 5000 may be a wearable device for virtual reality or mixed reality.

The head mounted display device 5000 may include a head mount band 5100 and a display device receiving case 5200. The head mount band 5100 may be connected to the display device receiving case 5200. The head mount band 5100 may include a horizontal band and/or a vertical band for fixing the head mounted display device 5000 to a user's head. The horizontal band may be configured to surround a side portion of the user's head, and the vertical band may be configured to surround an upper portion of the user's head. However, embodiments are not limited thereto. For example, the head mount band 5100 may be implemented in a form of a glasses frame, a helmet, or the like.

The display device receiving case 5200 may receive the display system 1000 and/or the display device 1200.

Although described with reference to the above embodiments, it will be understood that those skilled in the art can variously modify and change the disclosure without departing from the spirit and scope of the disclosure described in the claims below.

What is claimed is:

1. A light emitting element comprising:
a light emitting stack including a first semiconductor layer, a second semiconductor layer disposed on the first semiconductor layer, and an active layer disposed between the first semiconductor layer and the second semiconductor layer;
a first bonding electrode electrically connected to a lower surface of the first semiconductor layer and including a first protrusion protruding in at least one of a first direction and a direction opposite to the first direction so as to not overlap the light emitting stack in a plan view;
a (2-1)-th bonding electrode electrically connected to the second semiconductor layer; and
a (2-2)-th bonding electrode electrically connected to the second semiconductor layer and spaced apart from the (2-1)-th bonding electrode in a second direction intersecting the first direction,
wherein the first bonding electrode is disposed between the (2-1)-th bonding electrode and the (2-2)-th bonding electrode.

2. The light emitting element according to claim 1, wherein
first and second exposed surfaces that do not overlap the first semiconductor layer and the active layer in a plan view are defined on a face surface of the second semiconductor layer facing an outer peripheral surface of the active layer,
the (2-1)-th bonding electrode is electrically connected to the first exposed surface, and
the (2-2)-th bonding electrode is electrically connected to the second exposed surface.

3. The light emitting element according to claim 2, wherein
the first exposed surface is adjacent to a side surface of the second semiconductor layer, and
the second exposed surface is adjacent to another side surface opposite to the side surface of the second semiconductor layer in the second direction.

4. The light emitting element according to claim 1, wherein the (2-1)-th bonding electrode includes a (2-1)-th protrusion protruding in a direction opposite to the second direction so as to not overlap the light emitting stack in a plan view.

5. The light emitting element according to claim 4, wherein the (2-2)-th bonding electrode includes a (2-2)-th protrusion protruding in the second direction so as not to overlap the light emitting stack in a plan view.

6. The light emitting element according to claim 1, further comprising:
a reflective layer surrounding at least a portion of a side surface of the light emitting stack.

7. The light emitting element according to claim 6, wherein the reflective layer contacts each of the (2-1)-th bonding electrode and the (2-2)-th bonding electrode.

8. The light emitting element according to claim 7, wherein the reflective layer includes a conductive material.

9. The light emitting element according to claim 8, wherein the reflective layer and the first bonding electrode are spaced apart from each other.

10. The light emitting element according to claim 1, further comprising:
an insulating layer surrounding at least a portion of an outer peripheral surface of the light emitting stack.

11. The light emitting element according to claim 10, wherein the insulating layer is disposed between the (2-1)-th bonding electrode and the first semiconductor layer, between the (2-1)-th bonding electrode and the active layer, between the (2-2)-th bonding electrode and the first semiconductor layer, and between the (2-2)-th bonding electrode and the active layer.

12. The light emitting element according to claim 1, wherein the first bonding electrode includes a (1-1)-th bonding electrode and a (1-2)-th bonding electrode spaced apart from the (1-1)-th bonding electrode in the second direction.

13. A light emitting element comprising:
a light emitting stack including a first semiconductor layer, a second semiconductor layer disposed on the first semiconductor layer, and an active layer disposed between the first semiconductor layer and the second semiconductor layer;
a (1-1)-th bonding electrode electrically connected to a lower surface of the first semiconductor layer;
a (1-2)-th bonding electrode electrically connected to the lower surface of the first semiconductor layer and spaced apart from the (1-1)-th bonding electrode in a first direction; and
a second bonding electrode electrically connected to the second semiconductor layer and including a protrusion protruding in at least one of a second direction intersecting the first direction and a direction opposite to the second direction so as to not overlap the light emitting stack in a plan view,
wherein the second bonding electrode is disposed between the (1-1)-th bonding electrode and the (1-2)-th bonding electrode.

14. The light emitting element according to claim 13, wherein
the (1-1)-th bonding electrode is adjacent to a side surface of the first semiconductor layer, and
the (1-2)-th bonding electrode is adjacent to another side surface opposite to the side surface of the first semiconductor layer in the first direction.

15. The light emitting element according to claim 13, wherein the (1-1)-th bonding electrode includes a (1-1)-th protrusion protruding in a direction opposite to the first direction so as not to overlap the light emitting stack in a plan view.

16. The light emitting element according to claim 15, wherein the (1-2)-th bonding electrode includes a (1-2)-th protrusion protruding in the first direction so as not to overlap the light emitting stack in a plan view.

17. The light emitting element according to claim 13, wherein the second bonding electrode includes a (2-1)-th bonding electrode and a (2-2)-th bonding electrode spaced apart from the (2-1)-th bonding electrode in the first direction.

18. The light emitting element according to claim 17, wherein
first and second exposed surfaces that do not overlap the first semiconductor layer and the active layer in a plan view are defined on a face surface of the second semiconductor layer facing an outer peripheral surface of the active layer,
the (2-1)-th bonding electrode is electrically connected to the first exposed surface, and
the (2-2)-th bonding electrode is electrically connected to the second exposed surface.

19. The light emitting element according to claim 13, further comprising:
a reflective layer surrounding at least a portion of a side surface of the light emitting stack.

20. The light emitting element according to claim 13, further comprising:
an insulating layer surrounding at least a portion of an outer peripheral surface of the light emitting stack.

21. A display device comprising:
an electrode layer including an anode electrode including a first contact portion, and a cathode electrode including a (2-1)-th contact portion and a (2-2)-th contact portion;
a pixel circuit layer disposed under the electrode layer and including a sub-pixel circuit electrically connected to the anode electrode; and
a light emitting element disposed on the electrode layer,
wherein the light emitting element comprises:
a light emitting stack including a first semiconductor layer, a second semiconductor layer disposed on the first semiconductor layer, and an active layer disposed between the first semiconductor layer and the second semiconductor layer;
a first bonding electrode disposed on the first contact portion and electrically connected to a lower surface of the first semiconductor layer, the first bonding electrode including a first protrusion protruding in at least one of a first direction and a direction opposite to the first direction so as to not overlap the light emitting stack in a plan view;
a (2-1)-th bonding electrode electrically connected to the second semiconductor layer and disposed on the (2-1)-th contact portion; and
a (2-2)-th bonding electrode electrically connected to the second semiconductor layer, spaced apart from the (2-1)-th bonding electrode in a second direction intersecting the first direction, and disposed on the (2-2)-th contact portion,
wherein the first bonding electrode is disposed between the (2-1)-th bonding electrode and the (2-2)-th bonding electrode.

22. The display device according to claim 21, wherein the first bonding electrode is electrically connected to the first contact portion through a first bridge electrode electrically connected to each of the first protrusion and the first contact portion.

23. The display device according to claim 21, wherein
the (2-1)-th bonding electrode includes a (2-1)-th protrusion protruding in a direction opposite to the second direction so as to not overlap the light emitting stack in a plan view, and
the (2-1)-th bonding electrode is electrically connected to the (2-1)-th contact portion through a (2-1)-th bridge electrode electrically connected to each of the (2-1)-th protrusion and the (2-1)-th contact portion.

24. The display device according to claim 23, wherein
the (2-2)-th bonding electrode includes a (2-2)-th protrusion protruding in the second direction so as to not overlap the light emitting stack in a plan view, and
the (2-2)-th bonding electrode is electrically connected to the (2-2)-th contact portion through a (2-2)-th bridge electrode electrically connected to each of the (2-2)-th protrusion and the (2-2)-th contact portion.

25. The display device according to claim 21, wherein
the first bonding electrode overlaps a portion of the first contact portion in a plan view,
the (2-1)-th bonding electrode overlaps a portion of the (2-1)-th contact portion in a plan view, and
the (2-2)-th bonding electrode overlaps a portion of the (2-2)-th contact portion in a plan view.
